(19) United States
(12) Patent Application Publication
(10) Pub. No.: US 2025/0031519 A1
(43) Pub. Date: Jan. 23, 2025

(54) DISPLAY DEVICE

(71) Applicant: Samsung Display Co., LTD., Yongin-si (KR)

(72) Inventors: Sung Chul HONG, Yongin-si (KR); Yong Hee LEE, Yongin-si (KR); Ki Hyun PYO, Yongin-si (KR)

(21) Appl. No.: 18/669,147

(22) Filed: May 20, 2024

(30) Foreign Application Priority Data
Jul. 18, 2023 (KR) 10-2023-0093209

(51) Int. Cl. H10K 59/121; H01L 27/12; H10K 59/131

(52) U.S. Cl. CPC H10K 59/1213; H01L 27/124; H10K 59/131

(57) ABSTRACT

A display device which allows efficient arrangement of transistors within a pixel includes a plurality of pixels arranged adjacently along a first direction, a plurality of transistors disposed in each pixel and a light emitting element disposed in each pixel, and connected to at least one of a plurality of transistors in each pixel, wherein gate electrodes of corresponding transistors of different pixels, which are connected to the same signal line, are disposed so as not to overlap in the first direction.

This application claims priority to Korean Patent Application No. 10-2023-0093209, filed on Jul. 18, 2023, and all the benefits accruing therefrom under 35 U.S.C. 119, the content of which in its entirety are herein incorporated by reference.

### BACKGROUND

### 1. Technical Field

The invention relates to a display device, and more particularly to a display device which allows efficient arrangement of transistors within a pixel.

### 2. Description of the Related Art

An organic light emitting display device includes a display element of which luminance is changed by current, for example, an organic light emitting diode.

### SUMMARY

Embodiments of the invention provide a display device which allows for efficient arrangement of transistors within a pixel.

According to an embodiment, a display device includes a plurality of pixels arranged adjacently along a first direction, a plurality of transistors disposed in each pixel and a light emitting element disposed in each pixel, and connected to at least one of a plurality of transistors in each pixel, wherein gate electrodes of corresponding transistors of different pixels, which are connected to the same signal line, are disposed so as not to overlap in the first direction.

In an embodiment, the plurality of transistors in each pixel includes a first transistor connected to the light emitting element of each pixel, and a channel length of a channel region of the first transistor extends along a second direction intersecting the first direction.

In an embodiment, the first transistor includes a plurality of channel regions disposed along the first direction.

In an embodiment, the plurality of transistors in each pixel includes a second transistor connected between the first transistor and the light emitting element, where a channel length of a channel region of the second transistor extends along the first direction.

In an embodiment, among the transistors disposed in the same pixel, a channel length of a channel region of each of the remaining transistors excluding the second transistor extends along the second direction.

In an embodiment, gate electrodes of all corresponding transistors disposed in different adjacent pixels do not overlap in the first direction.

In an embodiment, the signal line has a curved shape.

In an embodiment, the signal line has a symmetrical shape with respect to a second direction intersecting the first direction.

In an embodiment, the signal line includes a gate line and an emission line.

In an embodiment, the gate line includes a plurality of sub-gate lines connected to each other.

In an embodiment, at least two of the plurality of sub-gate lines are disposed on different layers, where sub-gate lines on different layers are connected through contact holes of an insulating layer.

In an embodiment, the sub-gate line disposed on an upper side extends in a second direction intersecting the first direction.

In an embodiment, the sub-gate line disposed on a lower side extends in the first direction.

In an embodiment, the sub-gate line disposed on the lower side extends further in the second direction than in the first direction.

In an embodiment, each of the plurality of pixels further includes a body electrode.

In an embodiment, the body electrodes of the respective pixels are disposed in the respective pixels so as not to overlap in the first direction.

In an embodiment, a body electrode is included and is disposed in any one of the plurality of pixels.

In an embodiment, a part of the body electrode is disposed between gate electrodes of transistors disposed adjacent to each other in the first direction in any one pixel.

In an embodiment, one side surface of each of the gate electrodes facing the body electrode has a depressed shape directed toward an opposite side surface of each gate electrode.

In an embodiment, an intermediate connection electrode is included and is disposed in each pixel and connected to an anode electrode of the light emitting element of each pixel.

In an embodiment, the intermediate connection electrodes of the respective pixels are disposed in the respective pixels so as not to overlap in the first direction.

In an embodiment, the intermediate connection electrode of at least one pixel is disposed in a capacitor area of the pixel.

The display device of the invention enables efficient arrangement of transistors within a pixel. Therefore, as the area utilization of the pixel is improved, the total size of the channel regions of the transistors within the pixel may increase.

The effects of the invention are not limited to the above-described effects and other effects which are not described herein will become apparent to those skilled in the art from the following description.

### BRIEF DESCRIPTION OF THE DRAWINGS

The above and other aspects and features of the invention will become more apparent from the following description of embodiments thereof with reference to the attached drawings, in which:

FIG. 1 is a perspective view showing a display device, according to an embodiment;

FIG. 2 is a cross-sectional view illustrating a display device, according to an embodiment;

FIG. 3 is a plan view illustrating a display unit of a display device, according to an embodiment;

FIG. 4 is a block diagram illustrating a display panel and a display driver, according to an embodiment;

FIG. 5 is a schematic circuit diagram of one pixel of a display device, according to an embodiment;

FIG. 6 is a cross-sectional view of a display device, according to an embodiment;

FIG. 7 is a plan view of a display device, according to an embodiment;

FIG. 8 is a plan view of a display device, according to an embodiment;

FIG. 9 is a plan view of a display device, according to an embodiment;

FIG. 10 is a plan view of a display device in which a first metal layer is further added to the display device of FIGS. 7 to 9, according to an embodiment;

FIG. 11 is a plan view of a display device in which a first metal layer is further added to the display device of FIGS. 7 to 9, according to an embodiment;

FIG. 12 is a plan view of a display device in which a first metal layer is further added to the display device of FIGS. 7 to 9, according to an embodiment;

FIG. 13 is a plan view of a display device in which a second metal layer is further added onto the first metal layer of the display device of FIGS. 10 to 12, according to an embodiment;

FIG. 14 is a plan view of a display device in which a second metal layer is further added onto the first metal layer of the display device of FIGS. 10 to 12, according to an embodiment;

FIG. 15 is a plan view of a display device in which a second metal layer is further added onto the first metal layer of the display device of FIGS. 10 to 12, according to an embodiment;

FIG. 16 is a plan view of a display device in which a third metal layer is further added onto the second metal layer of the display device of FIGS. 13 to 15, according to an embodiment;

FIG. 17 is a plan view of a display device in which a third metal layer is further added onto the second metal layer of the display device of FIGS. 13 to 15, according to an embodiment;

FIG. 18 is a plan view of a display device in which a third metal layer is further added onto the second metal layer of the display device of FIGS. 13 to 15, according to an embodiment;

FIG. 19 is a plan view of a display device in which a fourth metal layer is further added onto the third metal layer of the display device of FIGS. 16 to 18, according to an embodiment;

FIG. 20 is a plan view of a display device in which a fourth metal layer is further added onto the third metal layer of the display device of FIGS. 16 to 18, according to an embodiment;

FIG. 21 is a plan view of a display device in which a fourth metal layer is further added onto the third metal layer of the display device of FIGS. 16 to 18, according to an embodiment;

FIG. 22 is a cross-sectional view taken along line I-I′ of FIG. 17, according to an embodiment;

FIG. 23 is a plan view of a display device, according to an embodiment;

FIG. 24 is a plan view of a display device, according to an embodiment;

FIG. 25 is a plan view of a display device, according to an embodiment;

FIG. 26 is a plan view of a display device, according to an embodiment;

FIG. 27 is a plan view of a display device, according to an embodiment;

FIG. 28 is an exploded perspective view of a display device, according to an embodiment;

FIG. 29 is a layout view illustrating an example of the display panel shown in FIG. 28, according to an embodiment;

FIG. 30 is a schematic block diagram illustrating a display device, according to an embodiment;

FIG. 31 is an equivalent circuit diagram of a first sub-pixel, according to an embodiment;

FIG. 32 is a layout view illustrating pixels of a display area, according to an embodiment;

FIG. 33 is a cross-sectional view illustrating an example of a display device taken along line A-A′ of FIG. 32, according to an embodiment;

FIG. 34 is a perspective view illustrating a head mounted display device, according to an embodiment;

FIG. 35 is an exploded perspective view illustrating an example of the head mounted display device of FIG. 34, according to an embodiment; and

FIG. 36 is a perspective view illustrating a head mounted display device, according to an embodiment.

### DETAILED DESCRIPTION OF THE EMBODIMENTS

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described in detail with reference to the accompanying drawings.

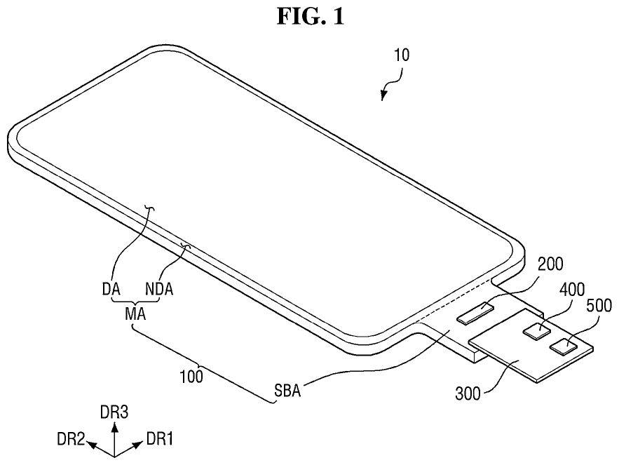

FIG. 1 is a perspective view showing a display device, according to an embodiment.

In an embodiment and referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, or a head mounted display (HMD).

In an embodiment, the display device 10 may have a planar shape similar to a quadrilateral shape. For example, the display device 10 may have a planar shape similar to a quadrilateral shape having a short side in a first direction DR1 and a long side in a second direction DR2. A corner where the short side in the first direction DR1 and the long side in the second direction DR2 meet may be right-angled or rounded with a predetermined curvature. The planar shape of the display device 10 is not limited to a quadrilateral shape, and may be formed in a shape similar to another polygonal shape, a circular shape, or elliptical shape.

In an embodiment, the display device 10 may include a display panel 100, a display driver 200, a circuit board 300, a touch driver 400, and a power supply circuit 500.

In an embodiment, the display panel 100 may include a region MA and a sub-region SBA.

In an embodiment, the region MA may include a display area DA including pixels (or sub-pixels) displaying an image and a non-display area NDA disposed around the display area DA. The display area DA may emit light from a plurality of emission areas or a plurality of opening areas. For example, the display panel 100 may include a pixel circuit PC including switching elements, a pixel defining layer defining an emission area or an opening area, and a self-light emitting element LEL.

In an embodiment, the self-light emitting element LEL may include at least one of an organic light emitting diode (LED) including an organic light emitting layer, a quantum dot LED including a quantum dot light emitting layer, an inorganic LED including an inorganic semiconductor, or a micro LED, but is not limited thereto.

In an embodiment, the non-display area NDA may be an area outside the display area DA. The non-display area NDA may be defined as an edge area of the region MA of the display panel 100. The non-display area NDA may include a gate driver (not illustrated) that supplies gate signals to the gate lines, and fan-out lines (not illustrated) that connect the display driver 200 to the display area DA.

In an embodiment, the sub-region SBA may extend from one side of the region MA. The sub-region SBA may include a flexible material which can be bent, folded or rolled. For example, when the sub-region SBA is bent, the sub-region SBA may overlap the region MA in a thickness direction (e.g., a third direction DR3). The sub-region SBA may include the display driver 200 and a pad portion connected to the circuit board 300. Optionally, the sub-region SBA may be omitted, and the display driver 200 and the pad portion may be arranged in the non-display area NDA.

In an embodiment, the display driver 200 may output signals and voltages for driving the display panel 100. The display driver 200 may supply data voltages to data lines DL. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the region MA in the thickness direction (third direction DR3) by bending of the sub-region SBA. For another example, the display driver 200 may be mounted on the circuit board 300.

In an embodiment, the circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be mounted on the circuit board 300.

The power supply circuit 500 may be disposed on the circuit board 300 to supply a power voltage to the display driver 200 and the display panel 100. The power supply circuit 500 may generate a driving voltage to supply the driving voltage to a driving voltage line VDL, and may generate a common voltage to supply the common voltage to a common electrode that is common to the light emitting elements of a plurality of pixels. For example, the driving voltage may be a high potential voltage for driving the light emitting element, and the common voltage may be a low potential voltage for driving the light emitting element.

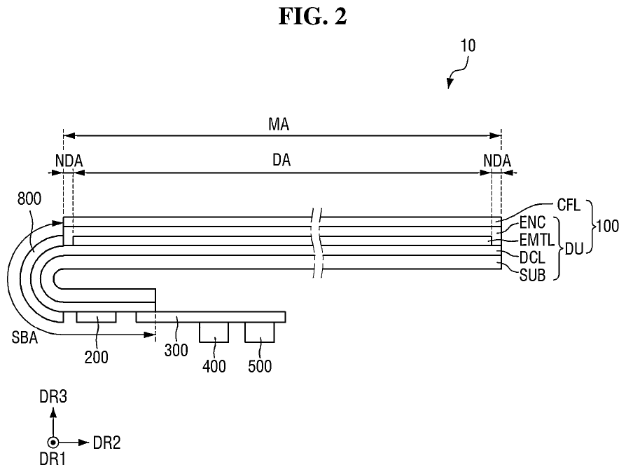

FIG. 2 is a cross-sectional view illustrating a display device, according to an embodiment.

In an embodiment and referring to FIG. 2, the display panel 100 may include a display unit DU and a color filter layer CFL. The display unit DU may include a substrate SUB, a driving circuit layer DCL, a light emitting element layer EMTL, and an encapsulation layer ENC.

In an embodiment, the substrate SUB may be a base substrate SUB or a base member. The substrate SUB may be a flexible substrate SUB which can be bent, folded or rolled. For example, the substrate SUB may include a polymer resin such as polyimide (PI), but is not limited thereto. In another embodiment, the substrate SUB may include a glass material or a metal material.

In an embodiment, the driving circuit layer DCL may be disposed on the substrate SUB. The driving circuit layer DCL may include a plurality of transistors. The driving circuit layer DCL may further include the gate lines, the data lines DL, the power lines, gate control lines, the fan-out lines that connect the display driver 200 to the data lines DL, and the lead lines that connect the display driver 200 to the pad portion. Each of the transistors may include a semiconductor region, a source electrode, a drain electrode, and a gate electrode. For example, when the gate driver is formed on one side of the non-display area NDA of the display panel 100, the gate driver may include transistors.

In an embodiment, the driving circuit layer DCL may be disposed in the display area DA, the non-display area NDA, and the sub-region SBA. Transistors, gate lines, data lines DL, and power lines of the pixels of the driving circuit layer DCL may be disposed in the display area DA. Gate control lines and fan-out lines of the driving circuit layer DCL may be disposed in the non-display area NDA. The lead lines of the driving circuit layer DCL may be disposed in the sub-region SBA.

In an embodiment, the light emitting element layer EMTL may be disposed on the driving circuit layer DCL. The light emitting element layer EMTL may include the plurality of light emitting elements ED in which a pixel electrode, a light emitting layer, and a common electrode are sequentially stacked to emit light, and the pixel defining layer defining the pixels. The plurality of light emitting elements ED of the light emitting element layer EMTL may be disposed in the display area DA.

In an embodiment, the light emitting layer may be an organic light emitting layer including an organic material. The light emitting layer may include a hole transporting layer, an organic light emitting layer, and an electron transporting layer. When the pixel electrode receives a predetermined voltage through the transistor of the driving circuit layer DCL and the common electrode receives the cathode voltage, holes and electrons may be transferred to the organic light emitting layer through the hole transporting layer and the electron transporting layer, respectively and may be combined with each other to emit light in the organic light emitting layer. For example, the pixel electrode may be an anode electrode, and the common electrode may be a cathode electrode, but the present disclosure is not limited thereto.

In another embodiment, each of the plurality of light emitting elements ED may include a quantum dot light emitting diode including a quantum dot light emitting layer, an inorganic light emitting diode including an inorganic semiconductor, or a micro light emitting diode.

In an embodiment, the encapsulation layer ENC may cover the top surface and the side surface of the light emitting element layer EMTL, and may protect the light emitting element layer EMTL. The encapsulation layer ENC may include at least one inorganic layer and at least one organic layer for encapsulating the light emitting element layer EMTL.

In an embodiment, the color filter layer CFL may be disposed on the encapsulation layer ENC. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

In an embodiment, the sub-region SBA of the display panel 100 may extend from one side of the region MA. The sub-region SBA may include a flexible material which can be bent, folded or rolled. For example, when the sub-region SBA is bent, the sub-region SBA may overlap the region MA in the thickness direction (third direction DR3). The sub-region SBA may include the display driver 200 and the pad portion electrically connected to the circuit board 300.

In an embodiment, when the sub-region SBA is bent, as shown in FIG. 2, a protective layer 800 may be further disposed on the bent portion of the sub-region SBA.

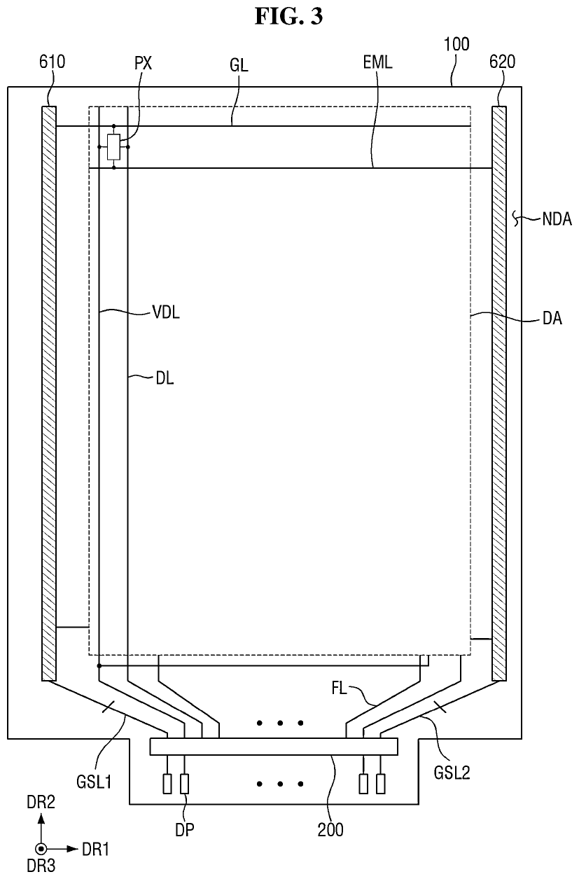

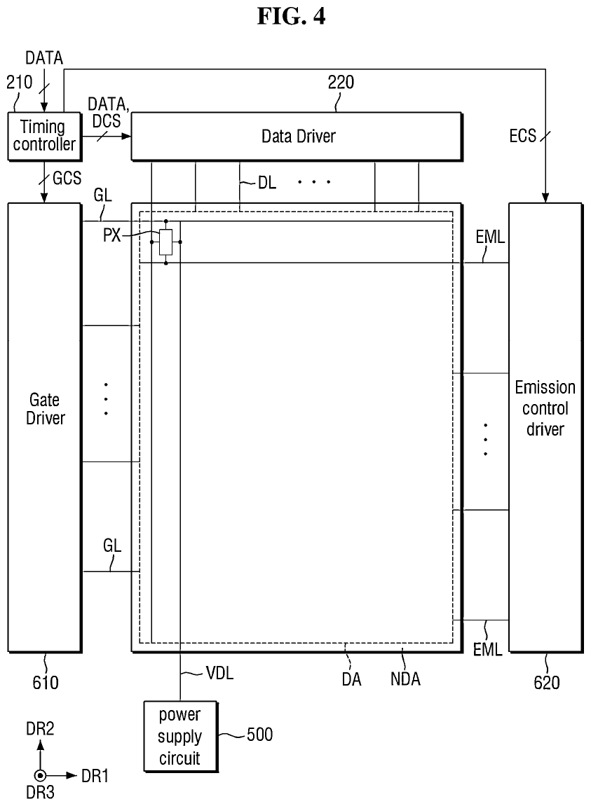

FIG. 3 is a plan view illustrating a display unit of a display device, according to an embodiment. FIG. 4 is a block diagram illustrating a display panel and a display driver, according to an embodiment.

In an embodiment and referring to FIGS. 3 and 4, the display panel 100 may include the display area DA and the non-display area NDA.

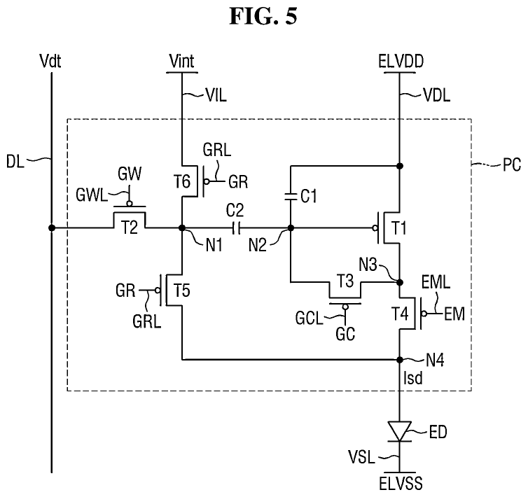

In an embodiment, the display area DA may include a plurality of pixels PX, and a plurality of signal transmission lines connected to the plurality of pixels PX. Here, the plurality of signal transmission lines may include a plurality of gate lines of a plurality of common voltage lines VSL (see FIG. 5), a plurality of emission lines EML and a plurality of data lines DL, and the fan-out lines connected to the aforementioned lines.

In an embodiment, each of the plurality of pixels PX may be connected to the gate line, the data line DL, the emission line EML, the driving voltage line VDL, and the common voltage line VSL. Each of the pixels PX may include at least one transistor, the light emitting element ED and a capacitor.

In an embodiment, each of the gate lines may extend in the first direction DR1 and may be spaced apart from each other in the second direction DR2 intersecting the first direction DR1. The gate lines may be arranged along the second direction DR2. The gate lines may sequentially supply gate signals to the plurality of pixels PX.

In an embodiment, the emission lines EML may each extend in the first direction DR1 and may be spaced apart from each other in the second direction DR2. The emission line EML may be arranged along the second direction DR2. The emission lines EML may sequentially supply an emission signal EM to the plurality of pixels PX.

In an embodiment, the data lines DL may extend in the second direction DR2 and may be spaced apart from each other in the first direction DR1. The data lines DL may be arranged along the first direction DR1. The data lines DL may supply data voltages to the plurality of pixels PX. The data voltage may determine the luminance of each of the pixels PX.

In an embodiment, the driving voltage lines VDL may extend in the second direction DR2 and may be spaced apart from each other in the first direction DR1. The driving voltage lines VDL may be arranged along the first direction DR1. The driving voltage lines VDL may supply a driving voltage to the plurality of pixels PX. The driving voltage may be a high potential voltage for driving the light emitting element ED of the pixels PX.

In an embodiment, the non-display area NDA may surround the display area DA. The non-display area NDA may include a gate driver 610, an emission control driver 620, fan-out lines FL, a first gate control line GSL1, and a second gate control line GSL2.

In an embodiment, the fan-out lines FL may extend from the display driver 200 to the display area DA. The fan-out lines FL may supply the data voltage received from the display driver 200 to the plurality of data lines DL.

In an embodiment, the first gate control line GSL1 may extend from the display driver 200 to the gate driver 610. The first gate control line GSL1 may supply a gate control signal GCS received from the display driver 200 to the gate driver 610.

In an embodiment, the second gate control line GSL2 may extend from the display driver 200 to the emission control driver 620. The second gate control line GSL2 may supply an emission control signal ECS received from the display driver 200 to the emission control driver 620.

In an embodiment, the sub-region SBA may extend from one side of the non-display area NDA. The sub-region SBA may include the display driver 200 and the pad portion DP. The pad portion DP may be disposed closer to one edge of the sub-region SBA than the display driver 200. The pad portion DP may be electrically connected to the circuit board 300 through an anisotropic conductive film ACF.

In an embodiment, the display driver 200 may include a timing controller 210 and a data driver 220.

In an embodiment, the timing controller 210 may receive a digital video data signal DATA and timing signals from the circuit board 300. The timing controller 210 may generate, based on the timing signals, a data control signal DCS to control the operation timing of the data driver 220, the gate control signal GCS to control the operation timing of the gate driver 610, and the emission control signal ECS to control the operation timing of the emission control driver 620. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data signal DATA and the data control signal DCS to the data driver 220.

In an embodiment, the data driver 220 may convert the digital video data signal DATA into analog data voltages and supply them to the data lines DL through the fan-out lines FL. The gate signals of the gate driver 610 may select the pixels PX to which the data voltage is supplied, and the selected pixels PX may receive the data voltage through the data lines DL.

In an embodiment, the power supply circuit 500 may be disposed on the circuit board 300 to supply a power voltage to the display driver 200 and the display panel 100. The power supply unit 500 may generate a driving voltage to supply it to the driving voltage line VDL, and may generate a common voltage to supply it to a common electrode that is common to the light emitting elements ED of a plurality of pixels.

In an embodiment, the gate driver 610 may be disposed at one external side of the display area DA or at one side of the non-display area NDA. The emission control driver 620 may be disposed at the other external side of the display area DA or at the other side of the non-display area NDA. However, the invention is not limited thereto. In another embodiment, the gate driver 610 and the emission control driver 620 may be disposed at any one of one side or the other side of the non-display area NDA.

In an embodiment, the gate driver 610 may include a plurality of transistors for generating gate signals based on the gate control signal GCS. The emission control driver 620 may include a plurality of transistors that generate the emission signals EM based on the emission control signal ECS. For example, the transistors of the gate driver 610 and the transistors of the emission control driver 620 may be formed on the same layer as the transistors of each of the pixels PX. The gate driver 610 may supply the gate signals to the gate lines, and the emission control driver 620 may supply the emission signals EM to the emission lines EML.

FIG. 5 is a circuit diagram of one pixel of a display device 10, according to an embodiment.

In an embodiment and as shown in FIG. 5, the pixel PX may be connected to the first gate line GWL, the second gate line GRL, the third gate line GCL, the emission line EML, the initialization line VIL, the data line DL, the driving voltage line VDL, and the common voltage line VSL. Here, the common voltage line VSL may be connected to the common electrode (e.g., cathode electrode) of the light emitting element ED.

In an embodiment, the pixel PX may include the pixel circuit PC and the light emitting element ED.

In an embodiment, the pixel circuit PC may include a first transistor T1, a second transistor T2, a third transistor T3, a fourth transistor T4, a fifth transistor T5, a sixth transistor T6, a first capacitor C1, and a second capacitor C2.

In an embodiment, the first transistor T1 (for example, a driving transistor) may include a gate electrode, a source electrode, and a drain electrode. The first transistor T1 may control a source-drain current (hereinafter, a driving current) according to the data voltage applied to the gate electrode. The driving current (e.g., Isd) flowing through a channel region of the first transistor T1 may be proportional to the square of a difference between the threshold voltage Vth and the voltage Vsg between the source electrode and the gate electrode of the first transistor T1 (Isd=k×(Vsg−Vth)²). Here, k is a proportional coefficient determined by the structure and physical characteristics of the first transistor T1, Vsg is a source-gate voltage of the first transistor T1, and Vth is a threshold voltage of the first transistor T1. The gate electrode of the first transistor T1 may be connected to a second node N2, the source electrode thereof may be connected to the driving voltage line VDL, and the drain electrode thereof may be connected to a fourth node N4 (e.g., an anode electrode of a light emitting element).

In an embodiment, the light emitting element ED may emit light by receiving the driving current Isd. The emission amount or the luminance of the light emitting element ED may be proportional to the magnitude of the driving current Isd. The light emitting element ED may be an organic light emitting diode including a first electrode, a second electrode, and an organic light emitting layer disposed between the first electrode and the second electrode. In another embodiment, the light emitting element ED may be an inorganic light emitting element including a first electrode, a second electrode, and an inorganic semiconductor disposed between the first electrode and the second electrode. In still another embodiment, the light emitting element ED may be a quantum dot light emitting element including a first electrode, a second electrode, and a quantum dot light emitting layer disposed between the first electrode and the second electrode. In still another embodiment, the light emitting element ED may be a micro light emitting diode. The first electrode of the light emitting element ED may be electrically connected to the fourth node N4. The second electrode of the light emitting element ED may be connected to the common voltage line VSL. The second electrode of the light emitting element ED may receive a common voltage (e.g., low potential voltage) from the common voltage line VSL.

In an embodiment, the second transistor T2 may be turned on by the first gate signal GW of the first gate line GWL to electrically connect the data line DL with a first node N1. The gate electrode of the second transistor T2 may be electrically connected to the first gate line GWL, the source electrode thereof may be electrically connected to the data line DL, and the drain electrode thereof may be electrically connected to the first node N1. The data line DL may transmit the data signal DATA.

In an embodiment, the third transistor T3 may be turned on by the third gate signal GC of the third gate line GCL to electrically connect the first node to the third node. The gate electrode of the third transistor T3 may be electrically connected to the third gate line GCL, the source electrode thereof may be electrically connected to the second node N2, and the drain electrode thereof may be electrically connected to the third node N3.

In an embodiment, the fourth transistor T4 may be turned on by the emission signal EM of the emission line EML to electrically connect the third node N3 to the fourth node N4. The gate electrode of the fourth transistor T4 may be electrically connected to the emission line EML, the source electrode thereof may be electrically connected to the third node N3, and the drain electrode thereof may be electrically connected to the fourth node N4.

In an embodiment, the fifth transistor T5 may be turned on by the second gate signal GR of the second gate line GRL to electrically connect the first node N1 to the fourth node N4. The gate electrode of the fifth transistor T5 may be electrically connected to the second gate line GRL, the source electrode thereof may be electrically connected to the fourth node N4, and the drain electrode thereof may be electrically connected to the first node N1.

In an embodiment, the sixth transistor T6 may be turned on by the second gate signal GR of the second gate line GRL to electrically connect the initialization line VIL to the first node. The gate electrode of the sixth transistor T6 may be electrically connected to the second gate line GRL, the source electrode thereof may be electrically connected to the first node N1, and the drain electrode thereof may be electrically connected to the initialization line VIL. Meanwhile, the initialization line VIL may transmit an initialization voltage Vint. The initialization voltage Vint may be a DC voltage smaller than a driving voltage ELVDD.

In an embodiment, the first capacitor C1 may be electrically connected between the second node N2 and the driving voltage line VDL. For example, the first electrode of the first capacitor C1 may be electrically connected to the second node N2, and the second electrode of the first capacitor C1 may be electrically connected to the driving voltage line VDL.

In an embodiment, the second capacitor C2 may be electrically connected between the second node N2 and the first node N1. For example, the first electrode of the second capacitor C2 may be electrically connected to the second node N2, and the second electrode of the second capacitor C2 may be electrically connected to the first node N1.

In an embodiment, when the first transistor T1 and the fourth transistor T4 are turned on, a driving current may be supplied to the light emitting element ED, so that the light emitting element ED may emit light.

In an embodiment, at least one of the aforementioned first to sixth transistors T1 to T6, respectively, may be a metal-oxide-semiconductor field effect transistor (MOSFET). For example, each of the first to sixth transistors T1 to T6 may, respectively, be a P-type MOSFET. Meanwhile, in another embodiment, each of the first to sixth transistors T1 to T6, respectively, may be an N-type MOSFET. In still another embodiment, some of the first to sixth transistors T1 to T6, respectively, may be P-type MOSFETs, and the other transistors may be N-type MOSFETs.

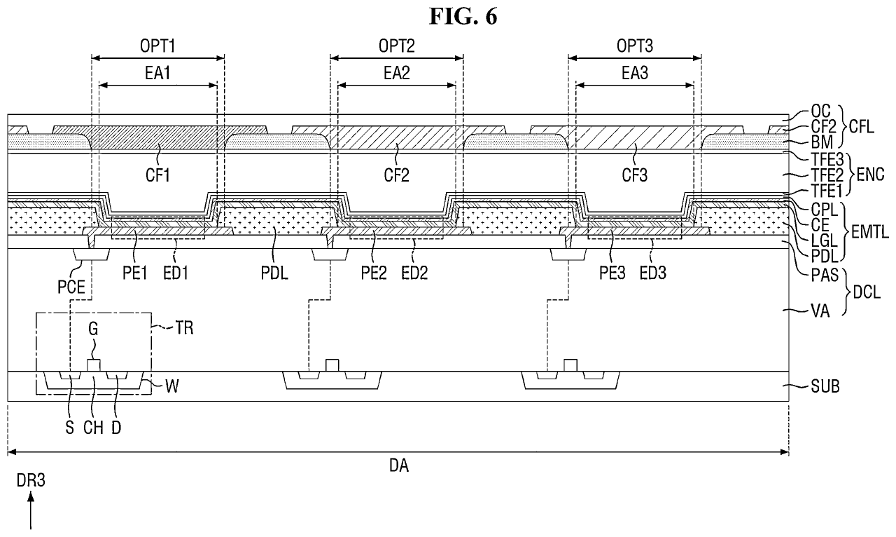

FIG. 6 is a cross-sectional view of a display device, according to an embodiment.

In an embodiment and as shown in FIG. 6, the display device 10 may include the driving circuit layer DCL, the light emitting element layer EMTL, the encapsulation layer ENC, and the color filter layer CFL.

In an embodiment, the substrate SUB may be a silicon substrate SUB, a germanium substrate SUB, or a silicon-germanium substrate SUB. The substrate SUB may be a substrate SUB doped with first type impurities.

In an embodiment, a well region W may be disposed on the substrate SUB (or in the substrate SUB). The well region W may be a region doped with second type impurities. The second type impurity may be different from the aforementioned first type impurity. For example, when the first type impurity is a p-type impurity, the second type impurity may be an n-type impurity. Meanwhile, when the first type impurity is an n-type impurity, the second type impurity may be a p-type impurity.

In an embodiment, a source region S, a drain region D, and a channel region CH of a transistor TR may be disposed in the well region W. For example, the source region S (or source electrode) and the drain region D (or drain electrode) of the transistor TR may be disposed in the well region W. Each of the source region S and the drain region D may be a region doped with the aforementioned first type impurities. The gate electrode G of the transistor TR may intersect and overlap the well region W. In plan view, the well region W intersecting the gate electrode G may be defined as two parts, and the source region S may be disposed in any one of the two parts, and the drain region D may be disposed in the other part thereof. In other words, in the well region W, the source region S and the drain region D may be disposed on both sides of the gate electrode G with the gate electrode G interposed therebetween. The channel region CH of the transistor may be disposed in the region of the well region W that overlaps the gate electrode G. In an embodiment, the transistor TR shown in FIG. 6 may be, for example, the first transistor T1 of FIG. 5.

In an embodiment, the source region S may include a first low-concentration impurity region having an impurity concentration relatively lower than those of other portions of the source region S. In other words, a portion of the source region S may include a lower concentration of impurities than other portions of the source region S. The drain region D may include a second low-concentration impurity region having an impurity concentration relatively lower than those of other portions of the drain region D. In other words, a portion of the drain region D may include a lower concentration of impurities than other portions of the drain region D.

In an embodiment, the first low-concentration impurity region and the second low-concentration impurity region may be disposed close to the channel region CH of the transistor TR. For example, the first low-concentration impurity region may be disposed close to the channel region CH to overlap a first sidewall disposed on one side of the gate electrode G, and the second low-concentration impurity region may be disposed close to the channel region CH to overlap a second sidewall disposed on the other side of the gate electrode G. In this way, the distance between the high-concentration impurity region of the source region S and the high-concentration impurity region of the drain region D may be increased due to the first low-concentration impurity region and the second low-concentration impurity region, and the length of the channel region CH may be increased due to the increase in the distance. Accordingly, punch-through and hot carrier phenomena caused by a short channel may be prevented.

In an embodiment, an interlayer insulating layer VA may be disposed on the substrate SUB.

In an embodiment, a passivation layer PAS may be disposed on the interlayer insulating layer VA.

In an embodiment, the light emitting element layer EMTL may be disposed on the passivation layer PAS. The light emitting element layer EMTL may include, for example, a first light emitting element ED1, a second light emitting element ED2, and a third light emitting element ED3 disposed in different emission areas. For example, the first light emitting element ED1 of the light emitting element layer EMTL may be disposed in a first emission area EA1, the second light emitting element ED2 of the light emitting element layer EMTL may be disposed in a second emission area EA2, and the third light emitting element ED3 of the light emitting element layer EMTL may be disposed in a third emission area EA3.

In an embodiment, each of the first light emitting element ED1, the second light emitting element ED2, and the third light emitting element ED3 may provide white light.

In an embodiment, the first light emitting element ED1 may include a first pixel electrode PE1 (or first anode electrode), a light providing layer LPL, and a common electrode CE stacked in the third direction DR3.

In an embodiment, the second light emitting element ED2 may include a second pixel electrode PE2 (or second anode electrode), the light providing layer LPL, and the common electrode CE stacked in the third direction DR3.

In an embodiment, the third light emitting element ED3 may include a third pixel electrode PE3 (or third anode electrode), the light providing layer LPL, and the common electrode CE stacked in the third direction DR3.

In an embodiment, the light providing layer LPL and the common electrode CE may be common layers commonly used by the light emitting elements ED1 to ED3. In other words, the plurality of light emitting elements ED1 to ED3 of the light emitting element layer EMTL may share the light providing layer LPL and the common electrode CE.

In an embodiment, the light providing layer LPL may include a plurality of light emitting layers providing lights of different colors, and the plurality of light emitting layers may be stacked along the third direction DR3. Different lights from the plurality of light emitting layers may be mixed to generate white light. Meanwhile, the light providing layer LPL may further include a charge generation layer.

In an embodiment, the first pixel electrode PE1, the second pixel electrode PE2, and the third pixel electrode PE3 may each be connected to each source region S of each transistor TR through a pixel connection electrode PCE.

In an embodiment, the first pixel electrode PE1 may be disposed to correspond to the first emission area EA1, the second pixel electrode PE2 may be disposed to correspond to the second emission area EA2, and the third pixel electrode PE3 may be disposed to correspond to the third emission area EA3.

In an embodiment, a bank PDL (or pixel defining layer) may be disposed on the first pixel electrode PE1, the second pixel electrode PE2, and the third pixel electrode PE3.

In an embodiment, the bank PDL may define the emission areas of the pixels (for example, the first emission area EA1 of the first pixel, the second emission area EA2 of the second pixel, and the third emission area EA3 of the third pixel). To this end, the bank PDL may be disposed to expose a partial region of each of the first pixel electrode PE1, the second pixel electrode PE2, and the third pixel electrode PE3 on the passivation layer PAS. The bank PDL may cover the edge of each of the first pixel electrode PE1, the second pixel electrode PE2, and the third pixel electrode PE3. The bank PDL may be formed of an organic layer such as acryl resin, epoxy resin, phenolic resin, polyamide resin, polyimide resin and the like.

In an embodiment, the light providing layer LPL may be disposed on the pixel electrodes PE1, PE2, and PE3 and the bank PDL. For example, the light providing layer LPL may be disposed on the first pixel electrode PE1, the second pixel electrode PE2, the third pixel electrode PE3, and the bank PDL.

In an embodiment, the light providing layer LPL may include a plurality of light emitting units. For example, the light providing layer LPL may include a first light emitting unit, a second light emitting unit, and a third light emitting unit stacked in the third direction DR3. The light emitting units may provide lights of different wavelengths. For example, the first light emitting unit, the second light emitting unit, and the third light emitting unit may emit lights of different colors. For example, the light providing layer LPL may have a tandem structure in which the plurality of light emitting units providing lights of different colors are stacked in a vertical direction (for example, the third direction DR3).

In an embodiment, the first light emitting unit may be disposed on the pixel electrodes PE1, PE2, and PE3. The first light emitting unit may include a first light emitting layer, a hole transporting layer, an organic material layer, and an electron transporting layer.

In an embodiment, a second light emitting unit may be disposed on the first light emitting unit. The second light emitting unit may include a second light emitting layer, a hole transporting layer, an organic material layer, and an electron transporting layer.

In an embodiment, a third light emitting unit may be disposed on the second light emitting unit. The third light emitting unit may include a third light emitting layer, a hole transporting layer, an organic material layer, and an electron transporting layer.

In an embodiment, the light emitting elements ED1, ED2, and ED3 may provide white light by mixing light of a first color (for example, blue) from the first light emitting unit, light of a second color (for example, red) from the second light emitting unit, and light of a third color (for example, green) from the third light emitting unit. For example, each of the first light emitting element ED1, the second light emitting element ED2, the third light emitting element ED3, and a dummy light emitting element DEL may provide white light.

In an embodiment, the light providing layer LPL may further include at least one charge generation layer in addition to the aforementioned light emitting units. The charge generation layer may be disposed between the light emitting units located adjacent in the third direction DR3, for example. The charge generation layer may include a first charge generation layer and a second charge generation layer stacked in the third direction DR3, for example. In this case, the first charge generation layer may be disposed between the first light emitting unit and the second light emitting unit, and the second charge generation layer may be disposed between the second light emitting unit and the third light emitting unit.

In an embodiment, each charge generation layer may include a negative charge generation layer and a positive charge generation layer. For example, the first charge generation layer may include a first negative charge generation layer and a first positive charge generation layer stacked in the third direction DR3, and the second charge generation layer may include a second negative charge generation layer and a second positive charge generation layer stacked in the third direction DR3.

In an embodiment, the common electrode CE may be disposed on the light providing layer LPL. For example, the common electrode CE may be disposed on the light providing layer LPL to overlap the first pixel electrode PE1, the second pixel electrode PE2, the third pixel electrode PE3, the first emission area EA1, the second emission area EA2, the third emission area EA3, and the bank PDL. In the top emission structure, the common electrode CE may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CM is formed of a semi-transmissive conductive material, the light emission efficiency can be increased due to a micro-cavity effect.

In an embodiment, a capping layer CPL may be disposed on the common electrode CE. The capping layer CPL may include an inorganic insulating material. In an exemplary embodiment, the capping layer CPL may include aluminum oxide, titanium oxide, tantalum oxide, hafnium oxide, zinc oxide, silicon oxide, silicon nitride, and/or silicon oxynitride.

In an embodiment, the encapsulation layer ENC may be disposed on the capping layer CPL. The encapsulation layer ENC may cover the top surface and the side surface of the light emitting element layer EMTL, and may protect the light emitting element layer EMTL. The encapsulation layer ENC may include at least one inorganic layer and at least one organic layer for encapsulating the light emitting element layer EMTL. The encapsulation layer ENC may include at least one inorganic layer TFE1 and TFE3 to prevent oxygen or moisture from permeating into the light emitting element layer EMTL. In addition, the encapsulation layer ENC may include at least one organic layer to protect the light emitting element layer EMTL from foreign substances such as dust. For example, the encapsulation layer ENC may include a first encapsulation inorganic layer TFE1, an encapsulation organic layer TFE2, and a second encapsulation inorganic layer TFE3.

In an embodiment, the first encapsulation inorganic layer TFE1 may be disposed on the capping layer CPL, the encapsulation organic layer TFE2 may be disposed on the first encapsulation inorganic layer TFE1, and the second encapsulation inorganic layer TFE3 may be disposed on the encapsulation organic layer TFE2. The first encapsulation inorganic layer TFE1 and the second encapsulation inorganic layer TFE3 may be formed of a multilayer in which one or more inorganic layers of a silicon nitride layer, a silicon oxynitride layer, a silicon oxide layer, a titanium oxide layer and an aluminum oxide layer are alternately stacked. The encapsulation organic layer TFE2 may be an organic layer such as acryl resin, epoxy resin, phenolic resin, polyamide resin, polyimide resin or the like.

In an embodiment, a light blocking layer BM may be disposed on the encapsulation layer ENC. The light blocking layer BM may include a plurality of holes OPT1, OPT2, and OPT3 disposed to overlap the emission areas EA1, EA2, and EA3, respectively. For example, the first hole OPT1 may be disposed to overlap the first emission area EA1. The second hole OPT2 may be disposed to overlap the second emission area EA2, and the third hole OPT3 may be disposed to overlap the third emission area EA3. The areas or sizes of the holes OPT1, OPT2, and OPT3 may be larger than the areas or sizes of the emission areas EA1, EA2, and EA3 defined by the bank PDL, respectively. The holes OPT1, OPT2, and OPT3 of the light blocking layer BM are formed to be larger than the emission areas EA1, EA2, and EA3, so that the light emitted from the emission areas EA1, EA2, and EA3 may be visually recognized by the user not only from the front surface but also from the side surface of the display device 10.

In an embodiment, the light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, or aniline black, but they are not limited thereto. The light blocking layer BM may prevent visible light infiltration and color mixture between the first to third emission areas EA1, EA2, and EA3, respectively, which leads to the improvement of color reproducibility of the display device 10.

In an embodiment, the display device 10 may include a plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. For example, the color filters CF1, CF2, and CF3 may be disposed on the light blocking layer BM including the plurality of holes OPT1, OPT2, and OPT3 disposed to correspond to the emission areas EA1, EA2, and EA3, respectively.

In an embodiment, the color filters CF1, CF2, and CF3 may include a first color filter CF1, a second color filter CF2, and a third color filter CF3, respectively, disposed to correspond to the different emission areas EA1, EA2, and EA3, respectively. The color filters CF1, CF2, and CF3 may include a colorant such as a dye or a pigment that absorbs light in a wavelength band other than light in a specific wavelength band, and may be disposed to correspond to the color of the light emitted from the emission areas EA1, EA2, and EA3, respectively. For example, the first color filter CF1 may be a red color filter that is disposed to overlap the first emission area EA1 and transmits only the first light of the red color. The second color filter CF2 may be a green color filter that is disposed to overlap the second emission area EA2 and transmits only the second light of the green color, and the third color filter CF3 may be a blue color filter that is disposed to overlap the third emission area EA3 and transmits only the third light of the blue color.

In an embodiment, the plurality of color filters CF1, CF2, and CF3 may be spaced apart from other adjacent color filters CF1, CF2, and CF3 on the light blocking layer BM. The color filters CF1, CF2, and CF3 may have areas larger than those of the holes OPT1, OPT2, and OPT3 of the light blocking layer BM, respectively, while covering the holes, and may have areas small enough to be spaced apart from other color filters CF1, CF2, and CF3 on the light blocking layer BM. However, the invention is not limited thereto. The plurality of color filters CF1, CF2, and CF3 may be disposed to partially overlap other adjacent color filters CF1, CF2, and CF3. The different color filters CF1, CF2, and CF3 are areas that do not overlap the emission areas EA1, EA2, and EA3, respectively, and may overlap each other on the light blocking layer BM. In the display device, the color filters CF1, CF2, and CF3 are disposed to overlap each other, so that the intensity of the reflected light by external light may be reduced. Furthermore, the color of the reflected light by the external light may be controlled by adjusting the disposition, shape, and area of the color filters CF1, CF2, and CF3 in a plan view.

In an embodiment, an overcoat layer OC may be disposed on the color filters CF1, CF2, and CF3 to planarize the top ends of the color filters CF1, CF2, and CF3. The overcoat layer OC may be a colorless light transmissive layer that does not have a color in a visible light band. For example, the overcoat layer OC may include a colorless light transmissive organic material such as an acrylic resin.

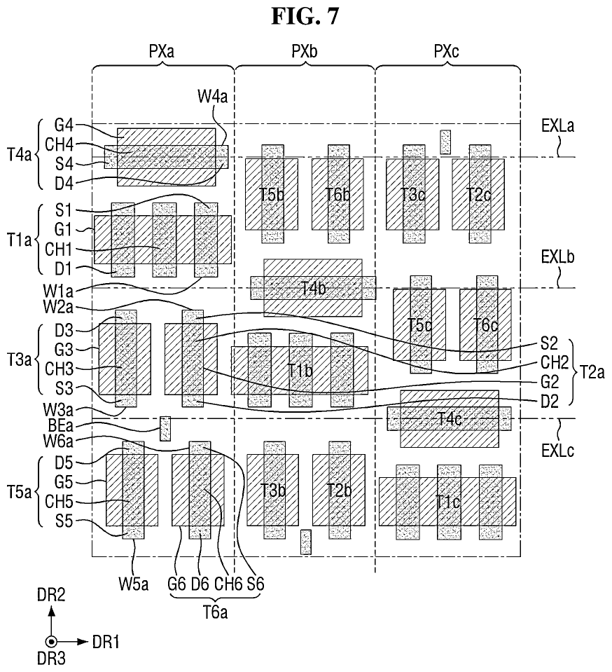

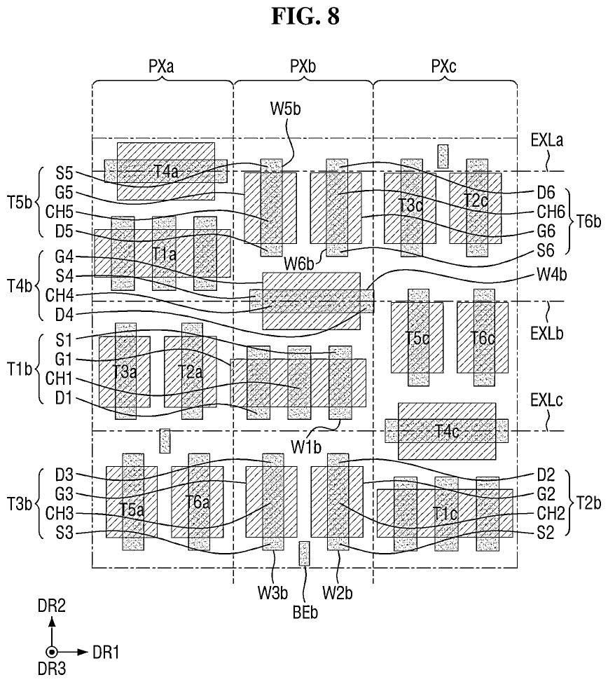

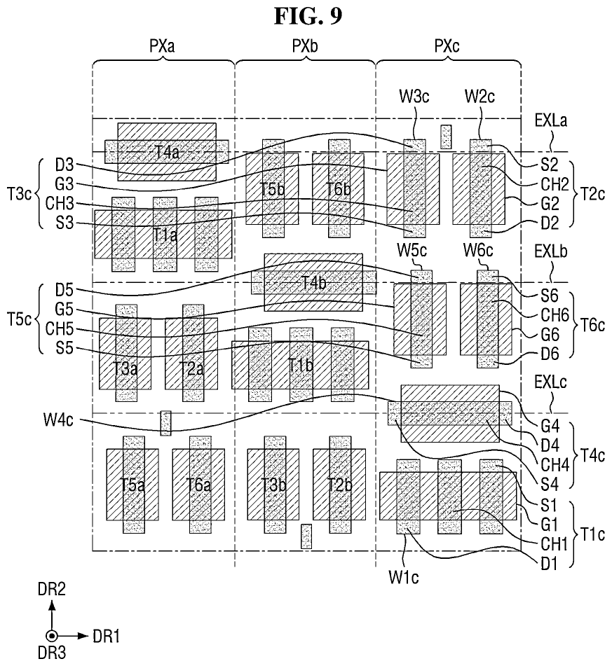

FIGS. 7 to 9 are plan views of a display device, according to an embodiment. Here, FIGS. 7 to 9 are the same drawings. However, in order to secure spaces for displaying reference numerals, FIG. 7 includes reference numerals related to, among first pixel PXa, second pixel PXb and third pixel PXc, the first pixel PXa, FIG. 8 includes reference numerals related to the second pixel PXb among the first pixel PXa, second pixel PXb and third pixel PXc, and FIG. 9 includes reference numerals related to the third pixel PXc among the first pixel PXa, second pixel PXb and third pixel PXc.

In an embodiment and as illustrated in FIGS. 7 to 9, the display device 10 may include the plurality of pixels PXa, PXb, and PXc. The plurality of pixels PXa, PXb, and PXc may be arranged along the first direction DR1. Although not illustrated, a plurality of other pixels may be further disposed along the second direction DR2.

In an embodiment, the arrangement direction (e.g., the first direction DR1) of the first pixel PXa, second pixel PXb and third pixel PXc may be the same as the extension direction of the gate line. For example, the first gate line GWL may extend along the first direction DR1.

In an embodiment, the first to third pixels PXa, PXb, and PXc, respectively, disposed adjacent to each other along the first direction DR1 may be connected to the same gate line and the same emission line EML while being connected to different data lines. For example, the first pixel PXa may be connected to the first gate line GWL, the second gate line GRL, the third gate line GCL, the emission line EML and a first data line DLa, the second pixel PXb may be connected to the first gate line GWL, the second gate line GRL, the third gate line GCL, the emission line EML and a second data line DLb, and the third pixel PXc may be connected to the first gate line GWL, the second gate line GRL, the third gate line GCL, the emission line EML and a third data line DLc.

In an embodiment, the first to third pixels PXa, PXb, and PXc, respectively, disposed adjacent to each other in the first direction DR1 may be pixels that provide light of different colors (or wavelengths). For example, the first pixel PXa may provide light of a first color, the second pixel PXb may provide light of a second color, and the third pixel PXc may provide light of a third color. Here, the first color may be any one of red, green, and blue, the second color may be any one of the above-described red, green, and blue colors different from the first color, and the third color may be any one of the above-described red, green, and blue colors different from the first color and the second color.

In an embodiment, the first to third pixels PXa, PXb, and PXc, respectively, disposed adjacent to each other in the first direction DR1 may constitute a single unit pixel. In other words, the first to third sub-pixels PXa, PXb, and PXc, respectively, disposed adjacent to each other in the first direction DR1 may constitute a single unit pixel.

In an embodiment, the pixels PXa, PXb, and PXc may include first to sixth transistors T1a to T6a, T1b to T6b, and T1c to T6c, respectively. For example, the first pixel PXa may include the first to sixth transistors T1a, T2a, T3a, T4a, T5a, and T6a, respectively, the second pixel PXb may include the first to sixth transistors T1b, T2b, T3b, T4b, T5b, and T6b, respectively, and the third pixel PXc may include the first to sixth transistors T1c, T2c, T3c, T4c, T5c, and T6c, respectively. Here, the first transistors T1a, T1b and T1c of the pixels PXa, PXb and PXc, respectively, may be the same as the first transistor T1 of FIG. 5 described above, the second transistors T2a, T2b and T2c of the pixels PXa, PXb and PXc, respectively, may be the same as the second transistor T2 of FIG. 5 described above, the third transistors T3a, T3b and T3c of the pixels PXa, PXb and PXc, respectively, may be the same as the third transistor T3 of FIG. 5 described above, the fourth transistors T4a, T4b and T4c of the pixels PXa, PXb and PXc, respectively, may be the same as the fourth transistor T4 of FIG. 5 described above, the fifth transistors T5a, T5b and T5c of the pixels PXa, PXb and PXc, respectively, may be the same as the fifth transistor T5 of FIG. 5 described above and the sixth transistors T6a, T6b and T6c of the pixels PXa, PXb and PXc, respectively, may be the same as the sixth transistor T6 of FIG. 5 described above.

In an embodiment, each transistor may include a gate electrode, a source electrode, and a drain electrode. For example, as illustrated in FIG. 7, the first transistor T1a of the first pixel PXa may include a first gate electrode G1, a first source electrode S1, and a first drain electrode D1, the second transistor T2a of the first pixel PXa may include a second gate electrode G2, a second source electrode S2, and a second drain electrode D2, the third transistor T3a of the first pixel PXa may include a third gate electrode G3, a third source electrode S3, and a third drain electrode D3, the fourth transistor T4a of the first pixel PXa may include a fourth gate electrode G4, a fourth source electrode S4, and a fourth drain electrode D4, the fifth transistor T5a of the first pixel PXa may include a fifth gate electrode G5, a fifth source electrode S5, and a fifth drain electrode D5 and the sixth transistor T6 of the first pixel PXa may include a sixth gate electrode G6, a sixth source electrode S6, and a sixth drain electrode D6. In addition, as illustrated in FIG. 8, the first transistor T1b of the second pixel PXb may include a first gate electrode G1, a first source electrode S1, and a first drain electrode D1, the second transistor T2b of the second pixel PXb may include a second gate electrode G2, a second source electrode S2, and a second drain electrode D2, the third transistor T3b of the second pixel PXb may include a third gate electrode G3, a third source electrode S3, and a third drain electrode D3, the fourth transistor T4b of the second pixel PXb may include a fourth gate electrode G4, a fourth source electrode S4, and a fourth drain electrode D4, the fifth transistor T5b of the second pixel PXb may include a fifth gate electrode G5, a fifth source electrode S5, and a fifth drain electrode D5 and the sixth transistor T6b of the second pixel PXb may include a sixth gate electrode G6, a sixth source electrode S6, and a sixth drain electrode D6. In addition, as shown in FIG. 9, the first transistor T1c of the third pixel PXc may include a first gate electrode G1, a first source electrode S1, and a first drain electrode D1, the second transistor T2c of the third pixel PXc may include a second gate electrode G2, a second source electrode S2, and a second drain electrode D2, the third transistor T3c of the third pixel PXc may include a third gate electrode G3, a third source electrode S3, and a third drain electrode D3, the fourth transistor T4c of the third pixel PXc may include a fourth gate electrode G4, a fourth source electrode S4, and a fourth drain electrode D4, the fifth transistor T5c of the third pixel PXc may include a fifth gate electrode G5, a fifth source electrode S5, and a fifth drain electrode D5 and the sixth transistor T6c of the third pixel PXc may include a sixth gate electrode G6, a sixth source electrode S6, and a sixth drain electrode D6.

In an embodiment, a channel region of each transistor may be defined as an overlapping region between a gate electrode and a well region of the corresponding transistor. For example, as illustrated in FIG. 7, a plurality of first channel regions CH1 of the first transistor T1a of the first pixel PXa may be defined as overlapping regions between the first gate electrode G1 and a plurality of first well regions W1a, a second channel region CH2 of the second transistor T2a of the first pixel PXa may be defined as an overlapping region between the second gate electrode G2 and a second well region W2a, a third channel region CH3 of the third transistor T3a of the first pixel PXa may be defined as an overlapping region between the third gate electrode G3 and a third well region W3a, a fourth channel region CH4 of the fourth transistor T4a of the first pixel PXa may be defined as an overlapping region between the fourth gate electrode G4 and a fourth well region W4a, a fifth channel region CH5 of the fifth transistor T5a of the first pixel PXa may be defined as an overlapping region between the fifth gate electrode G5 and a fifth well region W5a and a sixth channel region CH6 of the sixth transistor Toa of the first pixel PXa may be defined as an overlapping region between the sixth gate electrode G6 and a sixth well region W6a. Further, as illustrated in FIG. 8, the plurality of first channel regions CH1 of the first transistor T1b of the second pixel PXb may be defined as overlapping regions between the first gate electrode G1 and a plurality of first well regions W1b, the second channel region CH2 of the second transistor T2b of the second pixel PXb may be defined as an overlapping region between the second gate electrode G2 and a second well region W2b, the third channel region CH3 of the third transistor T3b of the second pixel PXb may be defined as an overlapping region between the third gate electrode G3 and a third well region W3b, the fourth channel region CH4 of the fourth transistor T4b of the second pixel PXb may be defined as an overlapping region between the fourth gate electrode G4 and a fourth well region W4b, the fifth channel region CH5 of the fifth transistor T5b of the second pixel PXb may be defined as an overlapping region between the fifth gate electrode G5 and a fifth well region W5b and the sixth channel region CH6 of the sixth transistor T6b of the second pixel PXb may be defined as an overlapping region between the sixth gate electrode G6 and a sixth well region W6b. Furthermore, as illustrated in FIG. 9, the plurality of first channel regions CH1 of the first transistor T1c of the third pixel PXc may be defined as overlapping regions between the first gate electrode G1 and a plurality of first well regions W1c, the second channel region CH2 of the second transistor T2c of the third pixel PXc may be defined as an overlapping region between the second gate electrode G2 and a second well region W2c, the third channel region CH3 of the third transistor T3c of the third pixel PXc may be defined as an overlapping region between the third gate electrode G3 and a third well region W3c, the fourth channel region CH4 of the fourth transistor T4c of the third pixel PXc may be defined as an overlapping region between the fourth gate electrode G4 and a fourth well region W4c, the fifth channel region CH5 of the fifth transistor T5c of the third pixel PXc may be defined as an overlapping region between the fifth gate electrode G5 and a fifth well region W5c and the sixth channel region CH6 of the sixth transistor T6c of the third pixel PXc may be defined as an overlapping region between the sixth gate electrode G6 and a sixth well region W6c.

In an embodiment, the size of a channel region may be defined by a channel length and a channel width. The channel length may be defined as the length of the channel region corresponding to a distance between the source electrode and the drain electrode of a corresponding transistor, and the channel width may be defined as the width of the channel region in a direction intersecting the channel length described above. For example, the channel length of the fourth channel region CH4 of the fourth transistor T4a of the first pixel PX1 may be the size of the fourth channel region CH4 in the first direction DR1, and the channel width of the fourth channel region CH4 of the fourth transistor T4a may be the size of the fourth channel region CH4 in the second direction DR2.

In an embodiment, at least two transistors disposed in one pixel may have channel regions extending along different directions. For example, the fourth transistor T4a of the first pixel PXa may have a channel length extending along the first direction DR1, and each of the first transistor T1a, the second transistor T2a, the third transistor T3a, and the fifth transistor T5a of the first pixel PXa may have a channel length extending along the second direction DR2. Also, the fourth transistor T4b of the second pixel PXb may have a channel length extending along the first direction DR1, and each of the first transistor T1b, the second transistor T2b, the third transistor T3b, and the fifth transistor T5b of the second pixel PXb may have a channel length extending along the second direction DR2. In addition, the fourth transistor T4c of the third pixel PXc may have a channel length extending along the first direction DR1, and each of the first transistor T1c, the second transistor T2c, the third transistor T3c, and the fifth transistor T5c of the first pixel PXa may have a channel length extending along the second direction DR2.

In an embodiment, since the extension directions of the channel lengths of the at least two transistors in the single pixel are different, it is possible to efficiently arrange the transistors within the single pixel. Accordingly, as the area utilization of the pixel is improved, the total size of the channel regions of the transistors in the pixel may increase. For example, the sum of the channel lengths of all the transistors belonging to the single pixel may increase. As a specific example, the first transistor T1a of the first pixel PXa is disposed adjacent to the fourth transistor T4a of the first pixel PXa in the second direction DR2, and the channel length of the fourth transistor T4a extends in the first direction DR1 intersecting the second direction DR2. Therefore, the first transistor T1a may include the plurality of first channel regions CH1 disposed along the first direction DR1 without interfering with the extension direction (e.g., the first direction DR1) of the channel length of the fourth transistor T4a. In other words, since the first channel regions CH1 of the first transistor T1a are disposed in another row that does not overlap the extension direction of the fourth channel region CH4 of the fourth transistor T4a, a larger number of first channel regions CH1 may be disposed along the first direction DR1. Besides, the channel length of each of the plurality of first channel regions CH1 extends along the second direction DR2 and since this channel length is in a direction different from the first direction DR1, interference between the first channel regions CH1 and the fourth channel region CH4 may be minimized. Accordingly, the total channel length, which is the sum of the respective channel lengths of all the transistors (e.g., the first to sixth transistors) disposed in the same pixel, may increase.

In an embodiment, the transistors may be disposed in different layouts in the first to third pixels PXa, PXb, and PXc, respectively, that are disposed adjacent to each other in the first direction DR1 (or that are connected to the same emission line EML). For example, the arrangement positions of the first to sixth transistors T1a to T6a, respectively, in the first pixel PXa, the arrangement positions of the first to sixth transistors T1b to T6b, respectively, in the second pixel PXb, and the arrangement positions of the first to sixth transistors T1c to T6c, respectively, in the third pixel PXc may be different. For example, the fourth transistor T4a of the first pixel PXa may be disposed at the uppermost side with respect to the second direction DR2, the fourth transistor T4b of the second pixel PXb may be disposed lower than the fourth transistor T4b of the first pixel PXa, and the fourth transistor T4c of the third pixel PXc may be disposed lower than the fourth transistor T4b of the second pixel PXb.

In an embodiment, between the pixels PXa, PXb, and PXc, the first transistors T1a, T1b, and T1c corresponding to each other, the second transistors T2a, T2b, and T2c corresponding to each other, the third transistors T3a, T3b, and T3c corresponding to each other, the fifth transistors T5a, T5b, and T5c corresponding to each other, and the sixth transistors T6a, T6b, and T6c corresponding each other may be disposed at different positions in the respective pixels. Here, with respect to the fourth transistors T4a, T4b and T4c of the respective pixels PXa, PXb and PXc, respectively, the positions of the remaining transistors are defined as follows. First, when a virtual line extending along the center of the fourth well region W4a defining the fourth channel region CH4 of the fourth transistor T4a belonging to the first pixel PXa is defined as a first extension line EXLa, a virtual line extending along the center of the fourth well region W4b defining the fourth channel region CH4 of the fourth transistor T4b belonging to the second pixel PXb is defined as a second extension line EXLb, and a virtual line extending along the center of the fourth well region W4c defining the fourth channel region CH4 of the fourth transistor T4c provided in the third pixel PXc is defined as a third extension line EXLe, wherein the first to third extension lines EXLa, EXLb, and EXLc, respectively, may be disposed parallel to each other without overlapping each other. For example, the first to third extension lines EXLa, EXLb, and EXLc, respectively, may be arranged in different rows to be parallel to each other.

In an embodiment, the first transistor T1a of the first pixel PXa may be disposed between the first extension line EXLa and the second extension line EXLb, the first transistor T1b of the second pixel PXb may be disposed between the second extension line EXLb and the third extension line EXLc and the first transistor T1c of the third pixel PXc may be disposed below the third extension line EXLc.

In an embodiment, the second transistor T2a and the third transistor T3a of the first pixel PXa may be disposed between the second extension line EXLb and the third extension line EXLc, the second transistor T2b and the third transistor T3b of the second pixel PXb may be disposed below the third extension line EXLc and a portion of each of the second transistor T2c and the third transistor T3c of the third pixel PXc may be disposed between the first extension line EXLa and the second extension line EXLb. For example, the second gate electrode G2, the second drain electrode D2, and the second channel region CH2 of the second transistor T2c provided in the third pixel PXc, and the third gate electrode G3, the third source electrode S3, and the third channel region CH3 of the third transistor T3c provided in the third pixel PXc may be disposed between the first extension line EXLa and the second extension line EXLb. Meanwhile, the second source electrode S2 of the second transistor T2c and the third drain electrode D3 of the third transistor T3c provided in the third pixel PXc may be disposed above the first extension line EXLa.

In an embodiment, the fifth transistor T5a and the sixth transistor Toa of the first pixel PXa may be disposed below the third extension line EXLc, a portion of each of the fifth transistor T5b and the sixth transistor T6b of the second pixel PXb may be disposed between the first extension line EXLa and the second extension line EXLb, a portion of each of the fifth transistor T5b and the sixth transistor T6b of the second pixel PXb may be disposed between the first extension line EXLa and the second extension line EXLb and a portion of each of the fifth transistor T5c and the sixth transistor T6c of the third pixel PXc may be disposed between the second extension line EXLb and the third extension line EXLc. For example, the fifth gate electrode G5, the fifth drain electrode D5, and the fifth channel region CH5 of the fifth transistor T5b provided in the second pixel PXb, and the sixth gate electrode G6, the sixth source electrode S6, and the sixth channel region CH6 of the sixth transistor T6b provided in the second pixel PXb may be disposed between the first extension line EXLa and the second extension line EXLb. Meanwhile, the fifth source electrode S5 of the fifth transistor T5b and the sixth drain electrode D6 of the sixth transistor T6b provided in the second pixel PXb may be disposed above the first extension line EXLa. Further, the fifth gate electrode G5, the fifth drain electrode D5, and the fifth channel region CH5 of the fifth transistor T5c provided in the third pixel PXc, and the sixth gate electrode G6, the sixth source electrode S6, and the sixth channel region CH6 of the sixth transistor T6c provided in the third pixel PXc may be disposed between the second extension line EXLb and the third extension line EXLc. Additionally, the fifth source electrode S5 of the fifth transistor T5c and the sixth drain electrode D6 of the sixth transistor T6c provided in the third pixel PXc may be disposed between the first extension line EXLa and the second extension line EXLb.

In an embodiment, a portion of a first body electrode BEa of the first pixel PXa may be disposed below the third extension line EXLc. Additionally, another portion of the first body electrode BEa of the first pixel PXa may be disposed between the second extension line EXLb and the third extension line EXLc.

In an embodiment, a second body electrode BEb of the second pixel PXb may be disposed below the third extension line EXLc.

In an embodiment, a third body electrode BEc of the third pixel PXc may be disposed above the first extension line EXLa.

In an embodiment, the first to third body electrodes BEa, BEb, and Bec, respectively, may be body electrodes of the first to sixth transistors T1a to T6a, T1b to T6b, and T1c to T6c, respectively. For example, each of the first to sixth transistors T1a to T6a, T1b to T6b, and T1c to T6c, respectively, may be a four-terminal element further including a body electrode in addition to a gate electrode, a source electrode, and a drain electrode. The first to third body electrodes BEa, BEb, and Bec, respectively, may be connected to the driving voltage line VDL through a body connection electrode to be described later.

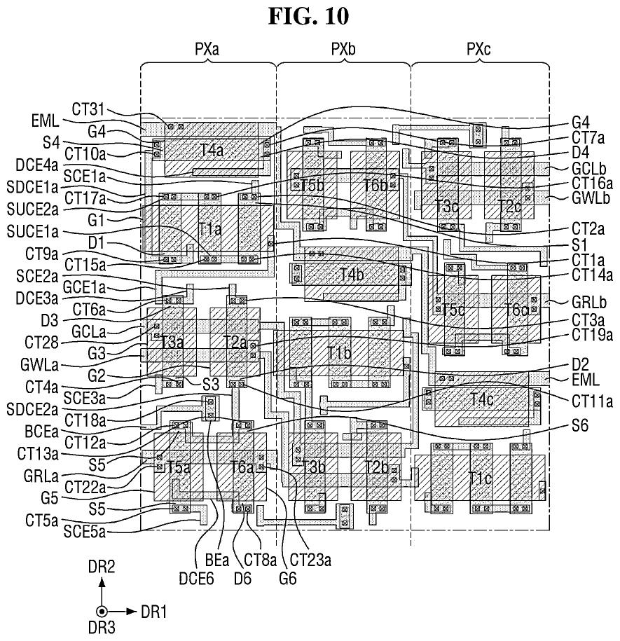

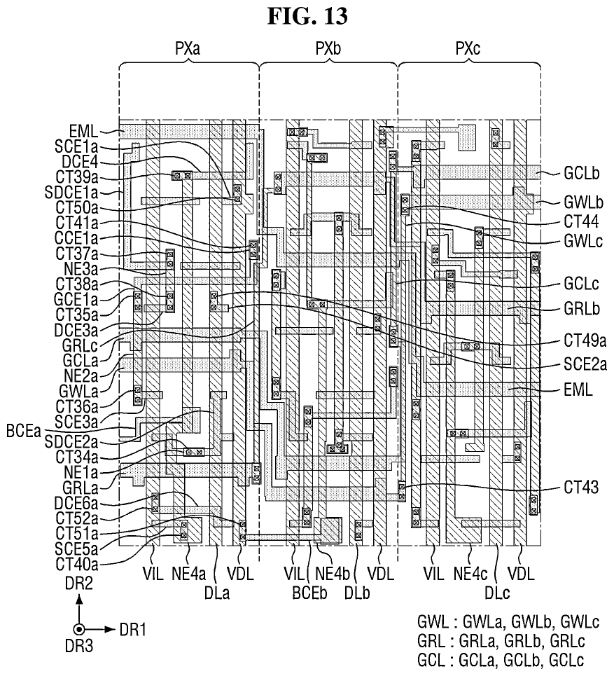

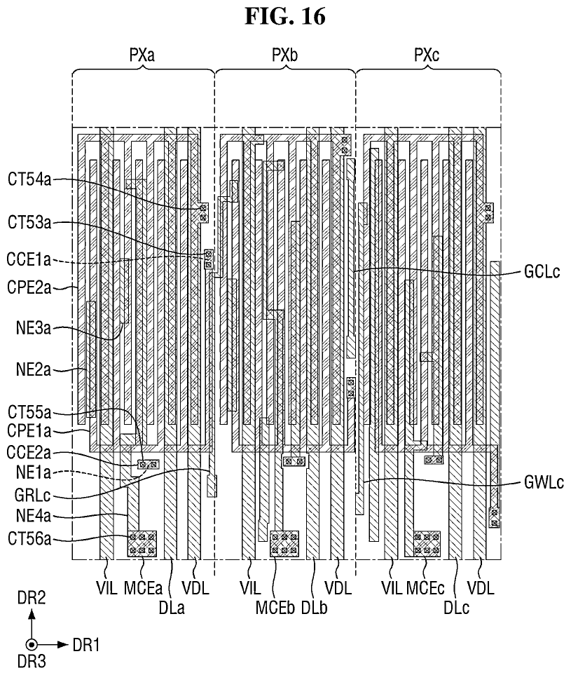

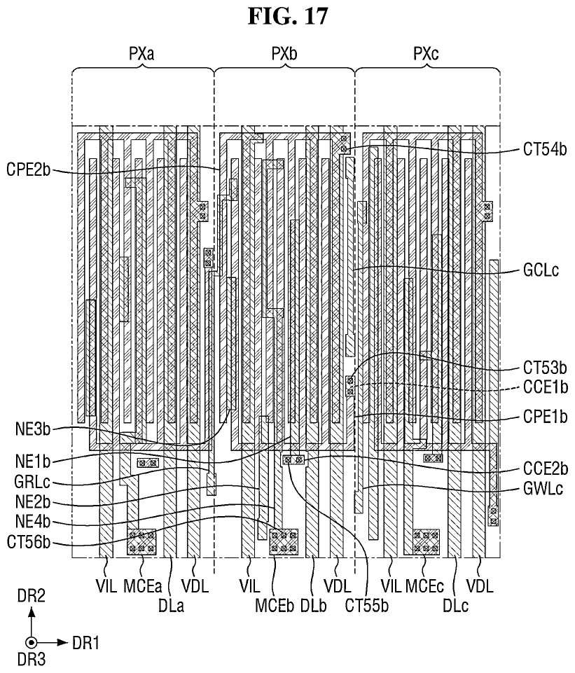

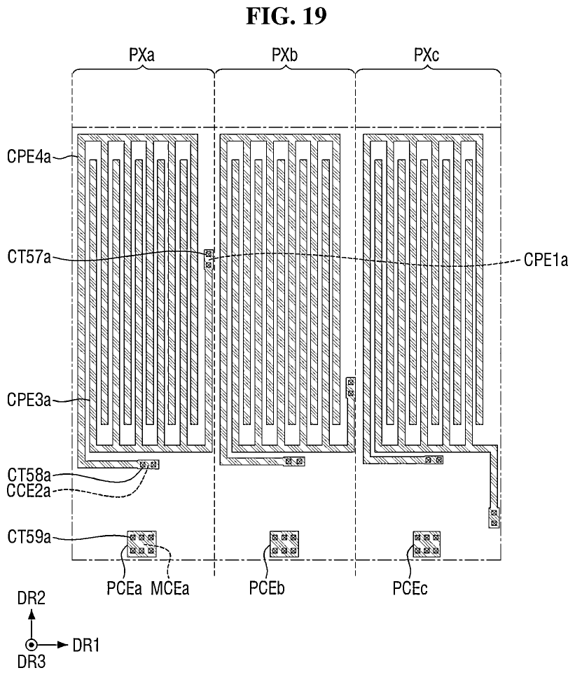

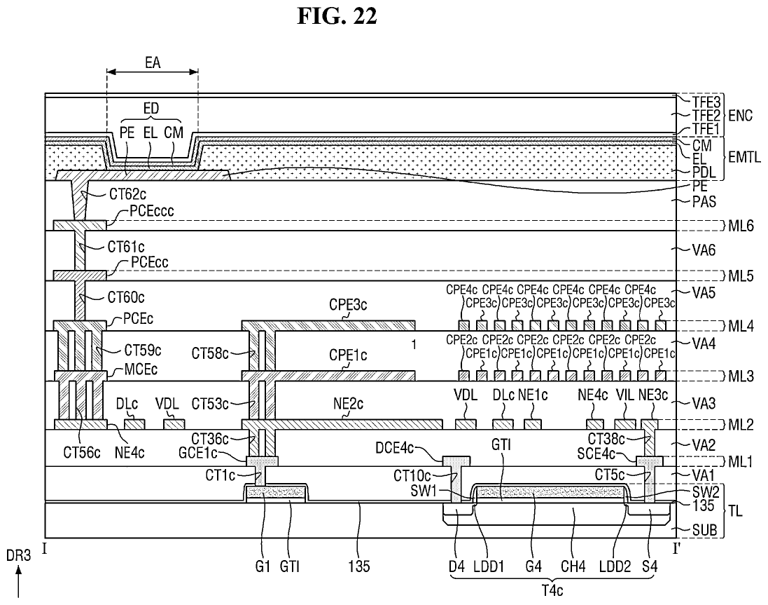

FIGS. 10 to 12 are plan views of a display device in which a first metal layer ML1 is further added to FIGS. 7 to 9, according to an embodiment. FIGS. 13 to 15 are plan views of a display device in which a second metal layer ML2 is further added onto the first metal layer ML1 of FIGS. 10 to 12, according to an embodiment. FIGS. 16 to 18 are plan views of a display device in which a third metal layer ML3 is further added onto the second metal layer ML2 of FIGS. 13 to 15, according to an embodiment. FIGS. 19 to 21 are plan views of a display device in which a fourth metal layer ML4 is further added onto the third metal layer ML3 of FIGS. 16 to 18, according to an embodiment and FIG. 22 is a cross-sectional view taken along line I-I′ of FIG. 17, according to an embodiment.

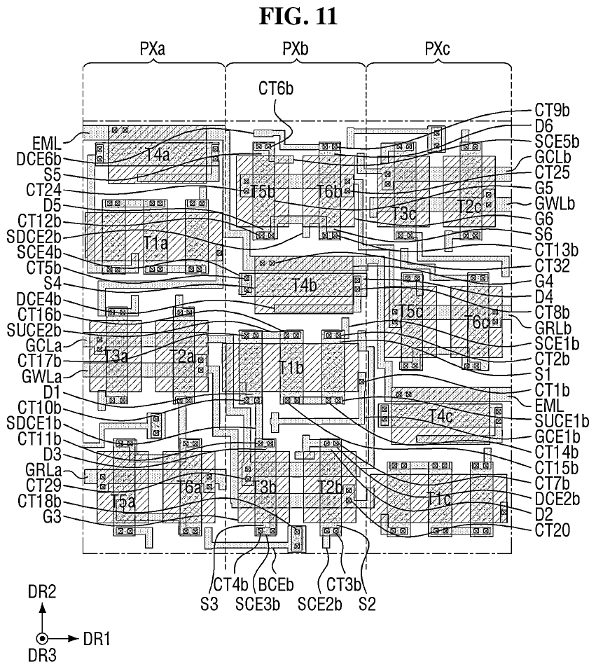

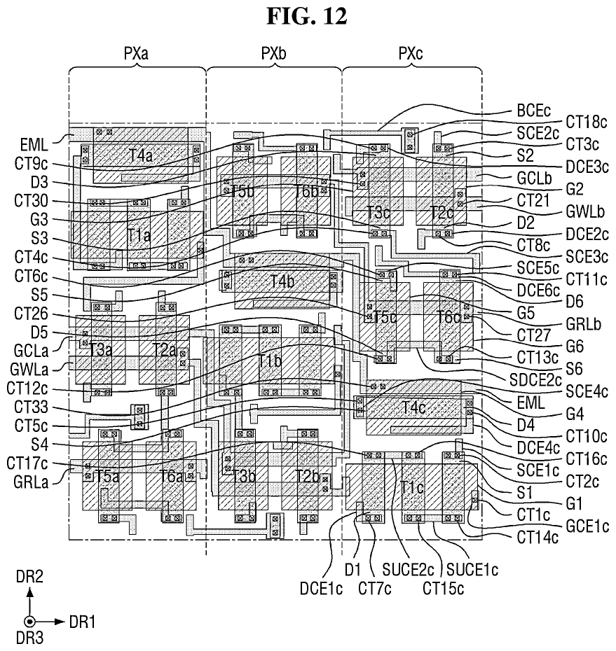

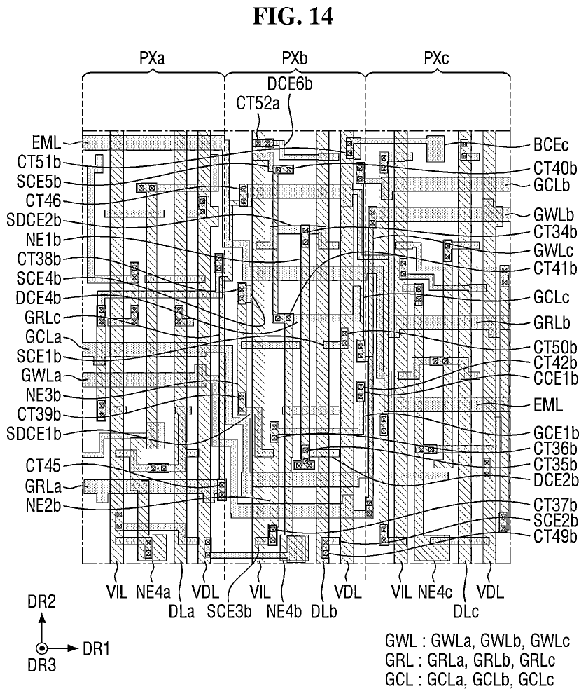

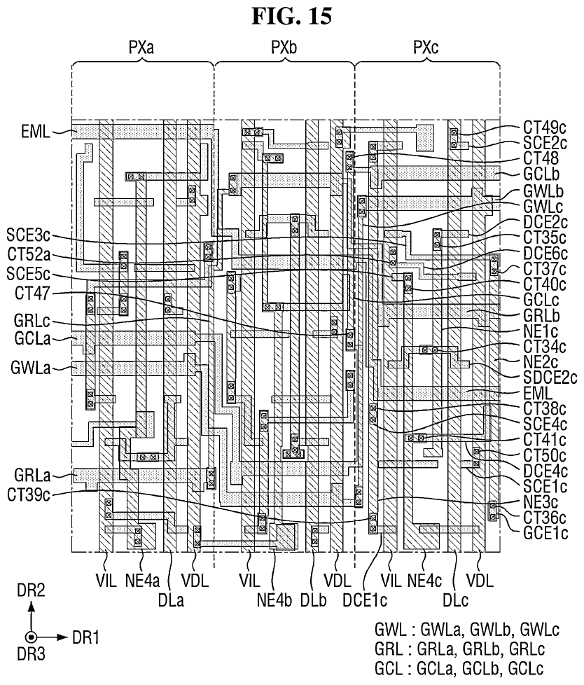

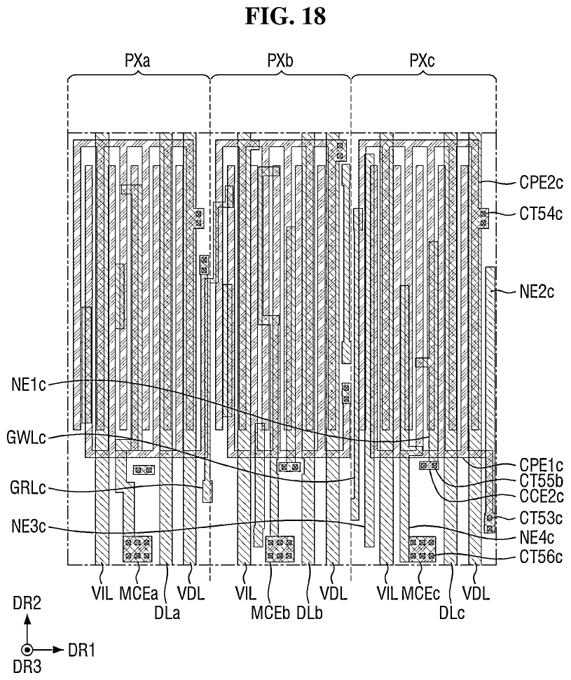

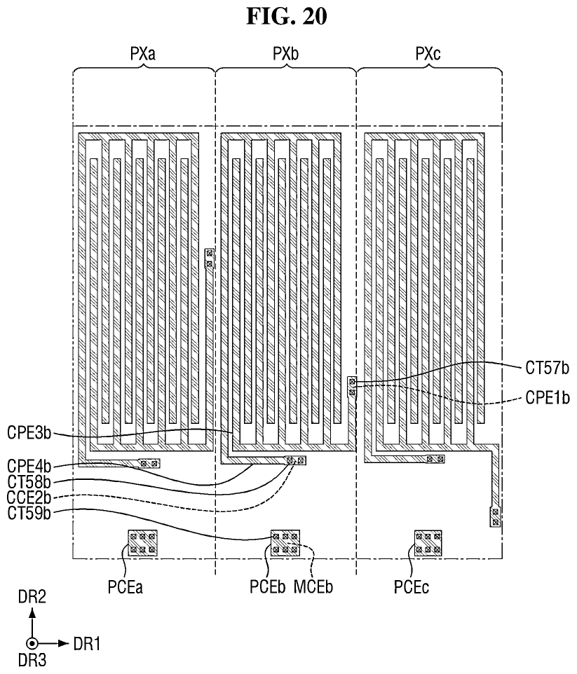

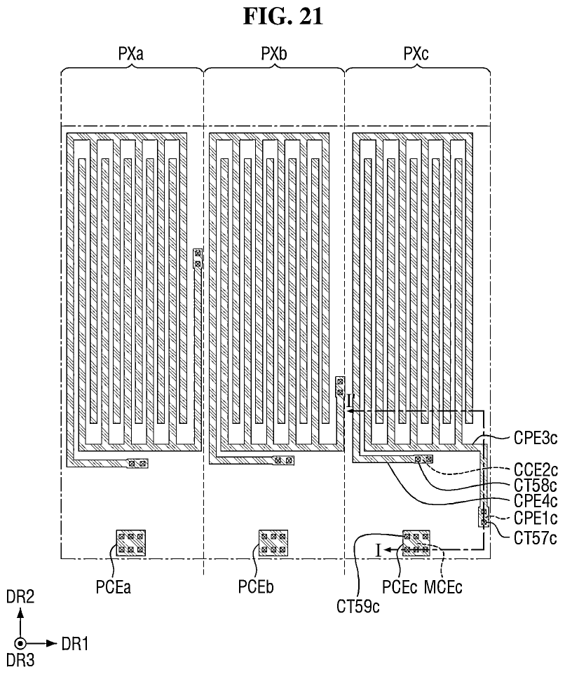

Furthermore, FIGS. 10 to 12 are the same drawings. However, in order to secure spaces for displaying reference numerals, FIG. 10 includes reference numerals related to the first pixel PXa among the first to third pixels PXa, PXb, and PXc, respectively, FIG. 11 includes reference numerals related to the second pixel PXb among the first to third pixels PXa, PXb, and PXc, respectively, and FIG. 12 includes reference numerals related to the third pixel PXc among the first to third pixels PXa, PXb, and PXc, respectively. Further, FIGS. 13 to 15 are the same drawings. However, in order to secure spaces for displaying reference numerals, FIG. 13 includes reference numerals related to the first pixel PXa among the first to third pixels PXa, PXb, and PXc, respectively, FIG. 14 includes reference numerals related to the second pixel PXb among the first to third pixels PXa, PXb, and PXc, respectively, and FIG. 15 includes reference numerals related to the third pixel PXc among the first to third pixels PXa, PXb, and PXc, respectively. Furthermore, FIGS. 16 to 18 are the same drawings. However, in order to secure spaces for displaying reference numerals, FIG. 16 includes reference numerals related to the first pixel PXa among the first to third pixels PXa, PXb, and PXc, respectively, FIG. 17 includes reference numerals related to the second pixel PXb among the first to third pixels PXa, PXb, and PXc, respectively, and FIG. 18 includes reference numerals related to the third pixel PXc among the first to third pixels PXa, PXb, and PXc, respectively. In addition, FIGS. 19 to 21 are the same drawings. However, in order to secure spaces for displaying reference numerals, FIG. 19 includes reference numerals related to the first pixel PXa among the first to third pixels PXa, PXb, and PXc, respectively, FIG. 20 includes reference numerals related to the second pixel PXb among the first to third pixels PXa, PXb, and PXc, respectively, and FIG. 21 includes reference numerals related to the third pixel PXc among the first to third pixels PXa, PXb, and PXc, respectively.

In an embodiment, the first metal layer ML1 may be disposed on a first interlayer insulating layer VI1, as shown in FIG. 22.

In an embodiment, the first metal layer ML1 may be formed of, for example, tungsten.

In an embodiment, the first metal layer ML1 may include, as illustrated in FIG. 10, a first gate connection electrode GCE1a, a first source connection electrode SCE1a, a second source connection electrode SCE2a, a third source connection electrode SCE3a, a fifth source connection electrode SCE5a, a third drain connection electrode DCE3a, a fourth drain connection electrode DCE4a, a sixth drain connection electrode DCE6a, a first source/drain connection electrode SDCE1a, a second source/drain connection electrode SDCE2a, a first sub-connection electrode SUCE1a, a second sub-connection electrode SUCE2a, and a first body connection electrode BCEa, which are disposed in the first pixel PXa.

In an embodiment, the first gate connection electrode GCE1a may be connected to the first gate electrode G1 of the first transistor T1a through a first contact hole CT1a penetrating the first interlayer insulating layer VI1.

In an embodiment, the first source connection electrode SCE1a may be connected to the first source electrode S1 of the first transistor T1a through a second contact hole CT2a penetrating the first interlayer insulating layer VI1.

In an embodiment, the second source connection electrode SCE2a may be connected to the second source electrode S2 of the second transistor T2a through a third contact hole CT3a penetrating the first interlayer insulating layer VI1.

In an embodiment, the third source connection electrode SCE3a may be connected to the third source electrode S3 of the third transistor T3a through a fourth contact hole CT4a penetrating the first interlayer insulating layer VI1.

In an embodiment, the fifth source connection electrode SCE5a may be connected to the fifth source electrode S5 of the fifth transistor T5a through a fifth contact hole CT5a penetrating the first interlayer insulating layer VI1.

In an embodiment, the third drain connection electrode DCE3a may be connected to the third drain electrode D3 of the third transistor T3a through a sixth contact hole CT6a penetrating the first interlayer insulating layer VI1.

In an embodiment, the fourth drain connection electrode DCE4a may be connected to the fourth drain electrode D4 of the fourth transistor T4a through a seventh contact hole CT7a penetrating the first interlayer insulating layer VI1.

In an embodiment, the sixth drain connection electrode DCE6a may be connected to the sixth drain electrode D6 of the sixth transistor Toa through an eighth contact hole CT8a penetrating the first interlayer insulating layer VI1.

In an embodiment, the first source/drain connection electrode SDCE1a may be connected to the first drain electrode D1 of the first transistor T1a through a ninth contact hole CT9a penetrating the first interlayer insulating layer VI1. In addition, the first source/drain connection electrode SDCE1a may be connected to the fourth source electrode S4 of the fourth transistor T4a through a tenth contact hole CT10a penetrating the first interlayer insulating layer VI1.

In an embodiment, the second source/drain connection electrode SDCE2a may be connected to the second drain electrode D2 of the second transistor T2a through an eleventh contact hole CT11a penetrating the first interlayer insulating layer VI1. In addition, the second source/drain connection electrode SDCE2a may be connected to the fifth source electrode S5 of the fifth transistor T5a through a twelfth contact hole CT12a penetrating the first interlayer insulating layer VI1. Also, the second source/drain connection electrode SDCE2a may be connected to the sixth source electrode S6 of the sixth transistor T6a through a thirteenth contact hole CT13a penetrating the first interlayer insulating layer VI1.

In an embodiment, the first sub-connection electrode SUCE1a may be connected to the drain electrode of the first well region W1a on the right through a fourteenth contact hole CT14a penetrating the first interlayer insulating layer VI1. In addition, the first sub-connection electrode SUCE1a may be connected to the source electrode of the first well region W1a at the center through a fifteenth contact hole CT15a penetrating the first interlayer insulating layer VI1.

In an embodiment, the second sub-connection electrode SUCE2a may be connected to the drain electrode of the first well region W1a at the center through a sixteenth contact hole CT16a penetrating the first interlayer insulating layer VI1. In addition, the second sub-connection electrode SUCE2a may be connected to the source electrode of the first well region W1a on the left through a seventeenth contact hole CT17a penetrating the first interlayer insulating layer VI1.

In an embodiment, the first body connection electrode BCEa may be connected to the first body electrode BEa through an eighteenth contact hole CT18a penetrating the first interlayer insulating layer VI1.

In addition, in an embodiment, the first metal layer ML1 may include, as shown in FIG. 11, a first gate connection electrode GCE1b, a first source connection electrode SCE1b, a second source connection electrode SCE2b, a third source connection electrode SCE3b, a fourth source connection electrode SCE4b, a fifth source connection electrode SCE5b, a second drain connection electrode DCE2b, a fourth drain connection electrode DCE4b, a sixth drain connection electrode DCE6b, a first source/drain connection electrode SDCE1b, a second source/drain connection electrode SDCE2b, a first sub-connection electrode SUCE1b, a second sub-connection electrode SUCE2b, and a second body connection electrode BCEb, which are disposed in the second pixel PXb.

In an embodiment, the first gate connection electrode GCE1b may be connected to the first gate electrode G1 of the first transistor T1b through a first contact hole CT1b penetrating the first interlayer insulating layer VI1.

In an embodiment, the first source connection electrode SCE1b may be connected to the first source electrode S1 of the first transistor T1b through a second contact hole CT2b penetrating the first interlayer insulating layer VI1.

In an embodiment, the second source connection electrode SCE2b may be connected to the second source electrode S2 of the second transistor T2b through a third contact hole CT3b penetrating the first interlayer insulating layer VI1.

In an embodiment, the third source connection electrode SCE3b may be connected to the third source electrode S3 of the third transistor T3b through a fourth contact hole CT4b penetrating the first interlayer insulating layer VI1.

In an embodiment, the fourth source connection electrode SCE4b may be connected to the fourth source electrode S4 of the fourth transistor T4b through a fifth contact hole CT5b penetrating the first interlayer insulating layer VI1.

In an embodiment, the fifth source connection electrode SCE5b may be connected to the fifth source electrode S5 of the fifth transistor T5b through a sixth contact hole CT6b penetrating the first interlayer insulating layer VI1.

In an embodiment, the second drain connection electrode DCE2b may be connected to the second drain electrode D2 of the second transistor T2b through a seventh contact hole CT7b penetrating the first interlayer insulating layer VI1.

In an embodiment, the fourth drain connection electrode DCE4b may be connected to the fourth drain electrode D4 of the fourth transistor T4b through an eighth contact hole CT8b penetrating the first interlayer insulating layer VI1.

In an embodiment, the sixth drain connection electrode DCE6b may be connected to the sixth drain electrode D6 of the sixth transistor T6b through a ninth contact hole CT9b penetrating the first interlayer insulating layer VI1.

In an embodiment, the first source/drain connection electrode SDCE1b may be connected to the first drain electrode D1 of the first transistor T1b through a tenth contact hole CT10b penetrating the first interlayer insulating layer VI1. In addition, the first source/drain connection electrode SDCE1b may be connected to the third drain electrode D3 of the third transistor T3b through an eleventh contact hole CT11b penetrating the first interlayer insulating layer VI1.

In an embodiment, the second source/drain connection electrode SDCE2b may be connected to the fifth drain electrode D5 of the fifth transistor T5b through a twelfth contact hole CT12b penetrating the first interlayer insulating layer VI1. Also, the second source/drain connection electrode SDCE2b may be connected to the sixth source electrode S6 of the sixth transistor T6b through a thirteenth contact hole CT13b penetrating the first interlayer insulating layer VI1.

In an embodiment, the first sub-connection electrode SUCE1b may be connected to the drain electrode of the first well region W1b on the right through a fourteenth contact hole CT14b penetrating the first interlayer insulating layer VI1. Also, the first sub-connection electrode SUCE1b may be connected to the source electrode of the first well region W1b at the center through a fifteenth contact hole CT15b penetrating the first interlayer insulating layer VI1.

In an embodiment, the second sub-connection electrode SUCE2b may be connected to the drain electrode of the first well region W1b at the center through a sixteenth contact hole CT16b penetrating the first interlayer insulating layer VI1. Also, the second sub-connect electrode SUCE2b may be connected to the source electrode of the first well region W1b on the left through a seventeenth contact hole CT17b penetrating the first interlayer insulating layer VI1.

In an embodiment, the second body connection electrode BCEb may be connected to the second body electrode BEb through an eighteenth contact hole CT18b penetrating the first interlayer insulating layer VI1.

In an embodiment, the first metal layer ML1 may include, as shown in FIG. 12, a first gate connection electrode GCE1c, a first source connection electrode SCE1c, a second source connection electrode SCE2c, a third source connection electrode SCE3c, a fourth source connection electrode SCE4c, a fifth source connection electrode SCE5c, a first drain connection electrode DCE1c, a second drain connection electrode DCE2c, a third drain connection electrode DCE3c, a fourth drain connection electrode DCE4c, a sixth drain connection electrode DCE6c, a second source/drain connection electrode SDCE2c, a first sub-connection electrode SUCE1c, a second sub-connection electrode SUCE2c, and a third body connection electrode BCEc, which are disposed in the third pixel PXc.

In an embodiment, the first gate connection electrode GCE1c may be connected to the first gate electrode G1 of the first transistor T1c through a first contact hole CT1c penetrating the first interlayer insulating layer VI1.

In an embodiment, the first source connection electrode SCE1c may be connected to the first source electrode S1 of the first transistor T1c through a second contact hole CT2c penetrating the first interlayer insulating layer VI1.

In an embodiment, the second source connection electrode SCE2c may be connected to the second source electrode S2 of the second transistor T2c through a third contact hole CT3c penetrating the first interlayer insulating layer VI1.

In an embodiment, the third source connection electrode SCE3c may be connected to the third source electrode S3 of the third transistor T3c through a fourth contact hole CT4c penetrating the first interlayer insulating layer VI1.

In an embodiment, the fourth source connection electrode SCE4c may be connected to the fourth source electrode S4 of the fourth transistor T4c through a fifth contact hole CT5c penetrating the first interlayer insulating layer VI1.

In an embodiment, the fifth source connection electrode SCE5c may be connected to the fifth source electrode S5 of the fifth transistor T5c through a sixth contact hole CT6c penetrating the first interlayer insulating layer VI1.

In an embodiment, the first drain connection electrode DCE1c may be connected to the first drain electrode D1 of the first transistor T1c through a seventh contact hole CT7c penetrating the first interlayer insulating layer VI1.

In an embodiment, the second drain connection electrode DCE2c may be connected to the second drain electrode D2 of the second transistor T2c through an eighth contact hole CT8c penetrating the first interlayer insulating layer VI1.

In an embodiment, the third drain connection electrode DCE3c may be connected to the third drain electrode D3 of the third transistor T3c through a ninth contact hole CT9c penetrating the first interlayer insulating layer VI1.

In an embodiment, the fourth drain connection electrode DCE4c may be connected to the fourth drain electrode D4 of the fourth transistor T4c through a tenth contact hole CT10c penetrating the first interlayer insulating layer VI1.

In an embodiment, the sixth drain connection electrode DCE6c may be connected to the sixth drain electrode D6 of the sixth transistor T6c through an eleventh contact hole CT11c penetrating the first interlayer insulating layer VI1.

In an embodiment, the second source/drain connection electrode SDCE2c may be connected to the fifth drain electrode D5 of the fifth transistor T5c through a twelfth contact hole CT12c penetrating the first interlayer insulating layer VI1. Also, the second source/drain connection electrode SDCE2c may be connected to the sixth source electrode S6 of the sixth transistor T6c through a thirteenth contact hole CT13c penetrating the first interlayer insulating layer VI1.

In an embodiment, the first sub-connection electrode SUCE1c may be connected to the drain electrode of the first well region W1c on the right through a fourteenth contact hole CT14c penetrating the first interlayer insulating layer VI1. Also, the first sub-connection electrode SUCE1c may be connected to the source electrode of the first well region W1c at the center through a fifteenth contact hole CT15c penetrating the first interlayer insulating layer VI1.

In an embodiment, the second sub-connection electrode SUCE2c may be connected to the drain electrode of the first well region W1c at the center through a sixteenth contact hole CT16c penetrating the first interlayer insulating layer VI1. Also, the second sub-connection electrode SUCE2c may be connected to the source electrode of the first well region W1c on the left through a seventeenth contact hole CT17c penetrating the first interlayer insulating layer VI1.

In an embodiment, the third body connection electrode BCEc may be connected to the third body electrode BEc through an eighteenth contact hole CT18c penetrating the first interlayer insulating layer VI1.

Further, in an embodiment, the first metal layer ML1 may include, as shown in FIGS. 10 to 12, a first-first sub-gate line GWLa, a first-second sub-gate line GWLb, a second-first sub-gate line GRLa, a second-second sub-gate line GRLb, a third-first sub-gate line GCLa, a third-second sub-gate line GCLb, and the emission line EML.

In an embodiment, the first-first sub-gate line GWLa and the first-second sub-gate line GWLb may be portions of the first gate line GWL.

In an embodiment and as illustrated in FIG. 10, the first-first sub-gate line GWLa may be connected to the second gate electrode G2 of the second transistor T2a through a nineteenth contact hole CT19a penetrating the first interlayer insulating layer VI1. Also, as illustrated in FIG. 11, the first-first sub-gate line GWLa may be connected to the second gate electrode G2 of the second transistor T2b through a twentieth contact hole CT20b penetrating the first interlayer insulating layer VI1.

In an embodiment and as illustrated in FIG. 12, the first-second sub-gate line GWLb may be connected to the second gate electrode G2 of the second transistor T2c through a twenty-first contact hole CT21c penetrating the first interlayer insulating layer VI1.

In an embodiment, the second-first sub-gate line GRLa and the second-second sub-gate line GRLb may be portions of the second gate line GRL.

In an embodiment and as shown in FIG. 10, the second-first sub-gate line GRLa may be connected to the fifth gate electrode G5 of the fifth transistor T5a through a twenty-second contact hole CT22a penetrating the first interlayer insulating layer VI1. Also, as illustrated in FIG. 10, the second-first sub-gate line GRLa may be connected to the sixth gate electrode G6 of the sixth transistor Toa through a twenty-third contact hole CT23a penetrating the first interlayer insulating layer VI1.

In addition, in an embodiment and as illustrated in FIG. 11, the second-second sub-gate line GRLb may be connected to the fifth gate electrode G5b of the fifth transistor T5b through a twenty-fourth contact hole CT24 penetrating the first interlayer insulating layer VI1. Also, as illustrated in FIG. 11, the second-second sub-gate line GRLb may be connected to the sixth gate electrode G6 of the sixth transistor T6b through a twenty-fifth contact hole CT25 penetrating the first interlayer insulating layer VI1. Also, as illustrated in FIG. 12, the second-second sub-gate line GRLb may be connected to the fifth gate electrode G5 of the fifth transistor T5c through a twenty-sixth contact hole CT26 penetrating the first interlayer insulating layer VI1. In addition, as illustrated in FIG. 12, the second-second sub-gate line GRLb may be connected to the sixth gate electrode G6 of the sixth transistor T6c through a twenty-seventh contact hole CT27 penetrating the first interlayer insulating layer VI1.

In an embodiment, the third-first sub-gate line GCLa and the third-second sub-gate line GCLb may be portions of the third gate line GCL.

In an embodiment and as illustrated in FIG. 10, the third-first sub-gate line GCLa may be connected to the third gate electrode G3 of the third transistor T3a through a twenty-eighth contact hole CT28 penetrating the first interlayer insulating layer VI1. Also, as illustrated in FIG. 11, the third-first sub-gate line GCLa may be connected to the third gate electrode G3 of the third transistor T3b through a twenty-ninth contact hole CT29 penetrating the first interlayer insulating layer VI1.

In addition, in an embodiment and as illustrated in FIG. 12, the third-second sub-gate line GCLb may be connected to the third gate electrode G3 of the third transistor T3c through a thirtieth contact hole CT30 penetrating the first interlayer insulating layer VI1.

In an embodiment and as illustrated in FIG. 10, the emission line EML may be connected to the fourth gate electrode G4 of the fourth transistor T4a through a thirty-first contact hole CT31 penetrating the first interlayer insulating layer VI1. Also, as illustrated in FIG. 11, the emission line EML may be connected to the fourth gate electrode G4 of the fourth transistor T4b through a thirty-second contact hole CT32 penetrating the first interlayer insulating layer VI1. In addition, as illustrated in FIG. 12, the emission line EML may be connected to the fourth gate electrode G4 of the fourth transistor T4c through a thirty-third contact hole CT33 penetrating the first interlayer insulating layer VI1.

In an embodiment and as shown in FIG. 22, a second interlayer insulating layer VA2 may be disposed on the above-described first metal layer ML1.

In an embodiment and as shown in FIG. 22, the second metal layer ML2 may be disposed on the second interlayer insulating layer VA2.

In an embodiment, the second metal layer ML2 may be formed of, for example, tungsten.

In an embodiment, the second metal layer ML2 may include, as illustrated in FIG. 13, a first node electrode NE1a, a second node electrode NE2a, a third node electrode NE3a, a fourth node electrode NE4a, and a first capacitor connection electrode CCE1a, which are disposed in the first pixel PXa.

In an embodiment, the first node electrode NE1a may be connected to the second source/drain connection electrode SDCE2a through a thirty-fourth contact hole CT34a penetrating the second interlayer insulating layer VA2.

In an embodiment, the second node electrode NE2a may be connected to the first gate connection electrode GCE1a through a thirty-fifth contact hole CT35a penetrating the second interlayer insulating layer VA2. Also, the second node electrode NE2 may be connected to the third source connection electrode SCE3a through a thirty-sixth contact hole CT36a penetrating the second interlayer insulating layer VA2.

In an embodiment, the third node electrode NE3a may be connected to the first source/drain connection electrode SDCE1a through a thirty-seventh contact hole CT37a penetrating the second interlayer insulating layer VA2. Further, the third node electrode NE3a may be connected to the third drain connection electrode DCE3a through a thirty-eighth contact hole CT38a penetrating the second interlayer insulating layer VA2.

In an embodiment, the fourth node electrode NE4a may be connected to the fourth drain connection electrode DCE4a through a thirty-ninth contact hole CT39a penetrating the second interlayer insulating layer VA2. Also, the fourth node electrode NE4a may be connected to the fifth source connection electrode SCE5a through a fortieth contact hole CT40a penetrating the second interlayer insulating layer VA2.

In an embodiment, the first capacitor connection electrode CCE1a may be connected to the first gate connection electrode GCE1a through a forty-first contact hole CT41a penetrating the second interlayer insulating layer VA2.

In addition, in an embodiment, the second metal layer ML2b may include, as shown in FIG. 14, a first node electrode NE1b, a second node electrode NE2b, a third node electrode NE3b, a fourth node electrode NE4b, and a first capacitor connection electrode CCE1b, which are disposed in the second pixel PXb.

In an embodiment, the first node electrode NE1b may be connected to the second source/drain connection electrode SDCE2b through a thirty-fourth contact hole CT34b penetrating the second interlayer insulating layer VA2. Also, the first node electrode NE1b may be connected to the second drain connection electrode DCE2b through a thirty-fifth contact hole CT35b penetrating the second interlayer insulating layer VA2.

In an embodiment, the second node electrode NE2b may be connected to the first gate connection electrode GCE1b through a thirty-sixth contact hole CT36b penetrating the second interlayer insulating layer VA2. Also, the second node electrode NE2b may be connected to the third source connection electrode SCE3b through a thirty-seventh contact hole CT37b penetrating the second interlayer insulating layer VA2.

In an embodiment, the third node electrode NE3b may be connected to the fourth source connection electrode SCE4b through a thirty-eighth contact hole CT38b penetrating the second interlayer insulating layer VA2. Also, the third node electrode NE3b may be connected to the first source/drain connection electrode SDCE1b through a thirty-ninth contact hole CT39b penetrating the second interlayer insulating layer VA2.

In an embodiment, the fourth node electrode NE4b may be connected to the fifth source connection electrode SCE5b through a fortieth contact hole CT40b penetrating the second interlayer insulating layer VA2. Also, the fourth node electrode NE4b may be connected to the fourth drain connection electrode DCE4b through a forty-first contact hole CT41b penetrating the second interlayer insulating layer VA2.

In an embodiment, the first capacitor connection electrode CCE1 may be connected to the first gate connection electrode GCE1b through a forty-second contact hole CT42b penetrating the second interlayer insulating layer VA2.

In addition, in an embodiment, the second metal layer ML2 may include, as shown in FIG. 15, a first node electrode NE1c, a second node electrode NE2c, a third node electrode NE3c, and a fourth node electrode NE4c, which are disposed in the third pixel PXc.

In an embodiment, the first node electrode NE1c may be connected to the second source/drain connection electrode SDCE2c through a thirty-fourth contact hole CT34c penetrating the second interlayer insulating layer VA2. Also, the first node electrode NE1c may be connected to the second drain connection electrode DCE2c through a thirty-fifth contact hole CT35c penetrating the second interlayer insulating layer VA2.

In an embodiment, the second node electrode NE2c may be connected to the first gate connection electrode GCE1c through a thirty-sixth contact hole CT36c penetrating the second interlayer insulating layer VA2. Also, the second node electrode NE2c may be connected to the third source connection electrode SCE3c through a thirty-seventh contact hole CT37c penetrating the second interlayer insulating layer VA2.

In an embodiment, the third node electrode NE3c may be connected to the fourth source connection electrode SCE4c through a thirty-eighth contact hole CT38c penetrating the second interlayer insulating layer VA2. Also, the third node electrode NE3c may be connected to the first drain connection electrode DCE1c through a thirty-ninth contact hole CT39c penetrating the second interlayer insulating layer VA2.

In an embodiment, the fourth node electrode NE4c may be connected to the fifth source connection electrode SCE5c through a fortieth contact hole CT40c penetrating the second interlayer insulating layer VA2. Also, the fourth node electrode NE4c may be connected to the fourth drain connection electrode DCE4c through a forty-first contact hole CT41c penetrating the second interlayer insulating layer VI2.

In addition, in an embodiment and as shown in FIGS. 13 to 15, the second metal layer ML2 may include a first-third sub-gate line GWLc, a second-third sub-gate line GRLc, a third-third sub-gate line GCLc, the first data line DLa, the second data line DLb, the third data line DLc, the driving voltage line VDL, and the initialization line VIL.

In an embodiment, the first-third sub-gate line GWLc may be a part of the first gate line GWL.

In an embodiment and as shown in FIG. 13, the first-third sub-gate line GWLc may be connected to the first-first sub-gate line GWLa through a forty-third contact hole CT43 penetrating the second interlayer insulating layer VI2. In addition, as shown in FIG. 13, the first-third sub-gate line GWLc may be connected to the first-second sub-gate line GWLb through a forty-fourth contact hole CT44 penetrating the second interlayer insulating layer VI2.

In an embodiment, the second-third sub-gate line GRLc may be a part of the second gate line GRL.

In an embodiment and as shown in FIG. 14, the second-third sub-gate line GRLc may be connected to the second-first sub-gate line GRLa through a forty-fifth contact hole CT45 penetrating the second interlayer insulating layer VI2. In addition, as shown in FIG. 14, the second-third sub-gate line GRLc may be connected to the second-second sub-gate line GRLb through a forty-sixth contact hole CT46 penetrating the second interlayer insulating layer VI2.

In an embodiment, the third-third sub-gate line GCLc may be a part of the third gate line GCL.

In an embodiment and as shown in FIG. 15, the third-third sub-gate line GCLc may be connected to the third-first sub-gate line GCLa through a forty-seventh contact hole CT47 penetrating the second interlayer insulating layer VI2. In addition, as shown in FIG. 15, the third-third sub-gate line GCLc may be connected to the third-second sub-gate line GCLb through a forty-eighth contact hole CT48 penetrating the second interlayer insulating layer VI2.

In an embodiment and as shown in FIG. 13, the first data line DLa may be connected to the second source connection electrode SCE2a through a forty-ninth contact hole CT49a penetrating the second interlayer insulating layer VI2.

In an embodiment and as shown in FIG. 14, the second data line DLb may be connected to the second source connection electrode SCE2b through a forty-ninth contact hole CT49b penetrating the second interlayer insulating layer VI2.

In an embodiment and as shown in FIG. 15, the third data line DLc may be connected to the second source connection electrode SCE2c through a forty-ninth contact hole CT49c penetrating the second interlayer insulating layer VI2.

In an embodiment and as shown in FIG. 13, the driving voltage line VDL may be connected to the first source connection electrode SCE1a through a fiftieth contact hole CT50a penetrating the second interlayer insulating layer VI2. In addition, as shown in FIG. 13, the driving voltage line VDL may be connected to the second body connection electrode BCEb through a fifty-first contact hole CT51a penetrating the second interlayer insulating layer VI2.

In addition, in an embodiment and as shown in FIG. 14, the driving voltage line VDL may be connected to the first source connection electrode SCE1b through a fiftieth contact hole CT50b penetrating the second interlayer insulating layer VI2. Further, as shown in FIG. 14, the driving voltage line VDL may be connected to the third body connection electrode BCEc through a fifty-first contact hole CT51b penetrating the second interlayer insulating layer VI2.

Furthermore, in an embodiment and as shown in FIG. 15, the driving voltage line VDL may be connected to the first source connection electrode SCE1c through a fiftieth contact hole CT50c penetrating the second interlayer insulating layer VI2.

In an embodiment, although not shown in the drawings, the driving voltage line VDL may be connected to the first body connection electrode BCEa through a contact hole penetrating the second interlayer insulating layer VI2.

In an embodiment and as shown in FIG. 13, the initialization line VIL may be connected to the sixth drain connection electrode DCE6a through a fifty-second contact hole CT52a penetrating the second interlayer insulating layer VI2.

In addition, in an embodiment and as shown in FIG. 14, the initialization line VIL may be connected to the sixth drain connection electrode DCE6b through a fifty-second contact hole CT52b penetrating the second interlayer insulating layer VI2.

In addition, in an embodiment and as shown in FIG. 15, the initialization line VIL may be connected to the sixth drain connection electrode DCE6c through a fifty-second contact hole CT52c penetrating the second interlayer insulating layer VI2.

In an embodiment and as shown in FIG. 22, a third interlayer insulating layer VI3 may be disposed on the above-described second metal layer ML2.

In an embodiment and as shown in FIG. 22, the third metal layer ML3 may be disposed on the third interlayer insulating layer VI3.

In an embodiment, the third metal layer ML3 may be formed of, for example, tungsten.

In an embodiment and as shown in FIG. 16, the third metal layer ML3 may include a first capacitor electrode CPE1a, a second capacitor electrode CPE2a, a second capacitor connection electrode CCE2a, and a first intermediate connection electrode MCEa disposed in the first pixel PXa.

In an embodiment, the first capacitor electrode CPE1a may be connected to the first capacitor connection electrode CCE1a through a fifty-third contact hole CT53a penetrating the third interlayer insulating layer VI3. The first capacitor electrode CPE1a may be the first electrode of the first capacitor C1 provided in the first pixel PXa.

In an embodiment, the second capacitor electrode CPE2a may be connected to the driving voltage line VDL through a fifty-fourth contact hole CT54a penetrating the third interlayer insulating layer VI3. The second capacitor electrode CPE2a may be the second electrode of the first capacitor C1 provided in the first pixel PXa. The aforementioned first capacitor C1 of the first pixel PXa may be formed between the first capacitor electrode CPE1a and the second capacitor electrode CPE2a. The first capacitor C1 of the first pixel PXa may be a metal-insulator-metal (MOM) capacitor.

In an embodiment, the second capacitor connection electrode CCE2a may be connected to the first node electrode NE1a through a fifty-fifth contact hole CT55a penetrating the third interlayer insulating layer VI3.

In an embodiment, the first intermediate connection electrode MCEa may be connected to the fourth node electrode NE4a through a fifty-sixth contact hole CT56a penetrating the third interlayer insulating layer VI3.

In addition, in an embodiment and as shown in FIG. 17, the third metal layer ML3 may include a first capacitor electrode CPE1b, a second capacitor electrode CPE2b, a second capacitor connection electrode CCE2b, and a second intermediate connection electrode MCEb disposed in the second pixel PXb.

In an embodiment, the first capacitor electrode CPE1b may be connected to the first capacitor connection electrode CCE1b through a fifty-third contact hole CT53b penetrating the third interlayer insulating layer VI3. The first capacitor electrode CPE1b may be the first electrode of the first capacitor C1 provided in the second pixel PXb.

In an embodiment, the second capacitor electrode CPE2b may be connected to the driving voltage line VDL through a fifty-fourth contact hole CT54b penetrating the third interlayer insulating layer VI3. The second capacitor electrode CPE2b may be the second electrode of the first capacitor C1 provided in the second pixel PXb. The aforementioned first capacitor C1 of the second pixel PXb may be formed between the first capacitor electrode CPE1b and the second capacitor electrode CPE2b. The first capacitor C1 of the second pixel PXb may be a metal-insulator-metal (MOM) capacitor.

In an embodiment, the second capacitor connection electrode CCE2b may be connected to the first node electrode NE1b through a fifty-fifth contact hole CT55b penetrating the third interlayer insulating layer VI3.

In an embodiment, the second intermediate connection electrode MCEb may be connected to the fourth node electrode NE4b through a fifty-sixth contact hole CT56b penetrating the third interlayer insulating layer VI3.

In addition, in an embodiment and as shown in FIG. 18, the third metal layer ML3 may include a first capacitor electrode CPE1c, a second capacitor electrode CPE2c, a second capacitor connection electrode CCE2c, and a third intermediate connection electrode MCEc disposed in the third pixel PXc.

In an embodiment, the first capacitor electrode CPE1c may be connected to the second node electrode NE2c through a fifty-third contact hole CT53c penetrating the third interlayer insulating layer VI3. The first capacitor electrode CPE1c may be the first electrode of the first capacitor C1 provided in the third pixel PXc.

In an embodiment, the second capacitor electrode CPE2c may be connected to the driving voltage line VDL through a fifty-fourth contact hole CT54c penetrating the third interlayer insulating layer VI3. The second capacitor electrode CPE2c may be the second electrode of the first capacitor C1 provided in the third pixel PXc. The aforementioned first capacitor C1 of the third pixel PXc may be formed between the first capacitor electrode CPE1c and the second capacitor electrode CPE2c. The first capacitor C1 of the third pixel PXc may be a metal-insulator-metal (MOM) capacitor.

In an embodiment, the second capacitor connection electrode CCE2c may be connected to the first node electrode NE1c through a fifty-fifth contact hole CT55c penetrating the third interlayer insulating layer VI3.

In an embodiment, the third intermediate connection electrode MCEc may be connected to the fourth node electrode NE4c through a fifty-sixth contact hole CT56c penetrating the third interlayer insulating layer VI3.

In an embodiment and as shown in FIG. 22, a fourth interlayer insulating layer VI4 may be disposed on the above-described third metal layer ML3.

In an embodiment and as shown in FIG. 22, the fourth metal layer ML4 may be disposed on the fourth interlayer insulating layer VI4.

In an embodiment, the fourth metal layer ML4 may be formed of, for example, tungsten.

In an embodiment and as shown in FIG. 19, the fourth metal layer ML4 may include a third capacitor electrode CPE3a, a fourth capacitor electrode CPE4a, and a first lower pixel connection electrode PCEa disposed in the first pixel PXa.

In an embodiment, the third capacitor electrode CPE3a may be connected to the first capacitor electrode CPE1a through a fifty-seventh contact hole CT57a penetrating the fourth interlayer insulating layer VI4. The third capacitor electrode CPE3a may have the same shape as that of the aforementioned first capacitor electrode CPE1a. The third capacitor electrode CPE3a may be the first electrode of the second capacitor C2 provided in the first pixel PXa.

In an embodiment, the fourth capacitor electrode CPE4a may be connected to the second capacitor connection electrode CCE2a through a fifty-eighth contact hole CT58a penetrating the fourth interlayer insulating layer VI4. The fourth capacitor electrode CPE4a may have the same shape as that of the aforementioned second capacitor electrode CPE2a. The fourth capacitor electrode CPE4a may be the second electrode of the second capacitor C2 provided in the first pixel PXa. The aforementioned second capacitor C2 of the first pixel PXa may be formed between the third capacitor electrode CPE3a and the fourth capacitor electrode CPE4a. The second capacitor C2 of the first pixel PXa may be a metal-insulator-metal (MOM) capacitor.

In an embodiment, the first lower pixel connection electrode PCEa may be connected to the first intermediate connection electrode MCEa through a fifty-ninth contact hole CT59a penetrating the fourth interlayer insulating layer VI4.

In addition, in an embodiment and as shown in FIG. 20, the fourth metal layer ML4 may include a third capacitor electrode CPE3b, a fourth capacitor electrode CPE4b, and a second lower pixel connection electrode PCEb disposed in the second pixel PXb.

In an embodiment, the third capacitor electrode CPE3b may be connected to the first capacitor electrode CPE1b through a fifty-seventh contact hole CT57b penetrating the fourth interlayer insulating layer VI4. The third capacitor electrode CPE3b may have the same shape as that of the aforementioned first capacitor electrode CPE1b. The third capacitor electrode CPE3b may be the first electrode of the second capacitor C2 provided in the second pixel PXb.

In an embodiment, the fourth capacitor electrode CPE4b may be connected to the second capacitor connection electrode CCE2b through a fifty-eighth contact hole CT58b penetrating the fourth interlayer insulating layer VI4. The fourth capacitor electrode CPE4b may have the same shape as that of the aforementioned second capacitor electrode CPE2b. The fourth capacitor electrode CPE4b may be the second electrode of the second capacitor C2 provided in the second pixel PXb. The aforementioned second capacitor C2 of the second pixel PXb may be formed between the third capacitor electrode CPE3b and the fourth capacitor electrode CPE4b. The second capacitor C2 of the second pixel PXb may be a metal-insulator-metal (MOM) capacitor.

In an embodiment, the second lower pixel connection electrode PCEb may be connected to the second intermediate connection electrode MCEb through a fifty-ninth contact hole CT59b penetrating the fourth interlayer insulating layer VI4.

In addition, in an embodiment and as shown in FIG. 21, the fourth metal layer ML4 may include a third capacitor electrode CPE3c, a fourth capacitor electrode CPE4c, and a third lower pixel connection electrode PCEc disposed in the third pixel PXc.

In an embodiment, the third capacitor electrode CPE3c may be connected to the first capacitor electrode CPE1c through a fifty-seventh contact hole CT57c penetrating the fourth interlayer insulating layer VI4. The third capacitor electrode CPE3c may have the same shape as that of the aforementioned first capacitor electrode CPE1c. The third capacitor electrode CPE3c may be the first electrode of the second capacitor C2 provided in the third pixel PXc.

In an embodiment, the fourth capacitor electrode CPE4c may be connected to the second capacitor connection electrode CCE2c through a fifty-eighth contact hole CT58c penetrating the fourth interlayer insulating layer VI4. The fourth capacitor electrode CPE4c may have the same shape as that of the aforementioned second capacitor electrode CPE2c. The fourth capacitor electrode CPE4c may be the second electrode of the second capacitor C2 provided in the third pixel PXc. The aforementioned second capacitor C2 of the third pixel PXc may be formed between the third capacitor electrode CPE3c and the fourth capacitor electrode CPE4c. The second capacitor C2 of the third pixel PXc may be a metal-insulator-metal (MOM) capacitor.

In an embodiment, the third lower pixel connection electrode PCEc may be connected to the third intermediate connection electrode MCEc through a fifty-ninth contact hole CT59c penetrating the fourth interlayer insulating layer VI4.

In an embodiment and as shown in FIG. 22, a fifth interlayer insulating layer VI5 may be disposed on the above-described fourth metal layer ML4.

In an embodiment and as shown in FIG. 22, the fifth metal layer ML5 may be disposed on the fifth interlayer insulating layer VI5.

In an embodiment, the fifth metal layer ML5 may be formed of, for example, tungsten.

In an embodiment, the fifth metal layer ML5 may include a third middle pixel connection electrode PCEcc disposed in the third pixel PXc as shown in FIG. 22.

In an embodiment, the third middle pixel connection electrode PCEcc may be connected to the third lower pixel connection electrode PCEc through a sixtieth contact hole CT60c penetrating the fifth interlayer insulating layer VI5.

In an embodiment, although not shown in the drawings, the aforementioned fifth metal layer ML5 may further include a first middle pixel connection electrode disposed in the first pixel PXa and a second middle pixel connection electrode disposed in the second pixel PXb.

In an embodiment, the first middle pixel connection electrode may be connected to the first lower pixel connection electrode PCEa through a contact hole penetrating the fifth interlayer insulating layer VI5, and the second middle pixel connection electrode may be connected to the second lower pixel connection electrode PCEb through a contact hole penetrating the fifth interlayer insulating layer VI5.

In an embodiment and as shown in FIG. 22, a sixth interlayer insulating layer VI6 may be disposed on the above-described fifth metal layer ML5.

In an embodiment and as shown in FIG. 22, the sixth metal layer ML6 may be disposed on the sixth interlayer insulating layer VI6.

In an embodiment, the sixth metal layer ML6 may be formed of, for example, tungsten.

In an embodiment and as shown in FIG. 22, the sixth metal layer ML6 may include a third upper pixel connection electrode PCEccc disposed in the third pixel PXc.

In an embodiment, the third upper pixel connection electrode PCEccc may be connected to the third middle pixel connection electrode PCEcc through a sixty-first contact hole CT61c penetrating the sixth interlayer insulating layer VI6.

In an embodiment, although not shown in the drawings, the aforementioned sixth metal layer ML6 may further include a first upper pixel connection electrode disposed in the first pixel PXa and a second upper pixel connection electrode disposed in the second pixel PXb.

In an embodiment, the first upper pixel connection electrode may be connected to the first middle pixel connection electrode through a contact hole penetrating the sixth interlayer insulating layer VI6, and the second upper pixel connection electrode may be connected to the second middle pixel connection electrode through a contact hole penetrating the sixth interlayer insulating layer VI6.

In an embodiment and as shown in FIG. 22, the passivation layer PAS may be disposed on the sixth metal layer ML6 described above.

In an embodiment and as shown in FIG. 22, the light emitting element layer EMTL and the encapsulation layer ENC may be disposed on the passivation layer PAS. For a description of the light emitting element layer EMTL and the encapsulation layer ENC of FIG. 22, refer to the description of the light emitting element layer EMTL and the encapsulation layer ENC of FIG. 6.

In an embodiment, the pixel electrode PE of the light emitting element layer EMTL may be connected to the third upper pixel connection electrode PCEccc through a sixty-second contact hole CT62c penetrating the passivation layer PAS.

In an embodiment, the gate electrodes of corresponding transistors of different pixels connected to the same signal line may be disposed so as not to overlap in the first direction DR1. For example, as shown in FIGS. 7 to 22, the first gate line GWL may be connected in common to the second gate electrode G2 of the second transistor T2 provided in the first pixel PXa, the second gate electrode G2 of the second transistor T2 provided in second pixel PXb, and the second gate electrode G2 of the second transistor T2 provided in the third pixel PXc, and thus these second gate electrodes G2 of the first to third pixels PXa, PXb, and PXc, respectively, may be disposed so as not to overlap in the first direction DR1. In addition, the second gate line GRL may be connected in common to the fifth gate electrode G5 of the fifth transistor T5 and the sixth gate electrode G6 of the sixth transistor T6 provided in the first pixel PXa, the fifth gate electrode G5 of the fifth transistor T5 and the sixth gate electrode G6 of the sixth transistor T6 provided in the second pixel PXb, and the fifth gate electrode G5 of the fifth transistor T5 and the sixth gate electrode G6 of the sixth transistor T6 provided in the third pixel PXc, and thus these fifth gate electrodes G5 and sixth gate electrodes G6 of the first to third pixels PXa, PXb, and PXc, respectively, may be disposed so as not to overlap in the first direction DR1. In addition, the third gate line GCL may be connected in common to the third gate electrode G3 of the third transistor T3 provided in the first pixel PXa, the third gate electrode G3 of the third transistor T3 provided in the second pixel PXb, and the third gate electrode G3 of the third transistor T3 provided in the third pixel PXc, and thus these third gate electrodes G3 of the first to third pixels PXa, PXb, and PXc, respectively, may be disposed so as not to overlap in the first direction DR1. In addition, the emission line EML may be connected in common to the fourth gate electrode G4 of the fourth transistor T4 provided in the first pixel PXa, the fourth gate electrode G4 of the fourth transistor T4 provided in the second pixel PXb, and the fourth gate electrode G4 of the fourth transistor T4 provided in the third pixel PXc, and thus these fourth gate electrodes G4 of the first to third pixels PXa, PXb, and PXc, respectively, may be disposed so as not to overlap in the first direction DR1. In other words, all corresponding transistors of different pixels included in one unit pixel disposed to be adjacent in the first direction DR1 may include gate electrodes that do not overlap in the first direction DR1.

In an embodiment, the signal line may have a curved (or bent) shape. For example, at least one of the first gate line GWL, the second gate line GRL, the third gate line GCL, or the emission line EML may have a curved shape.

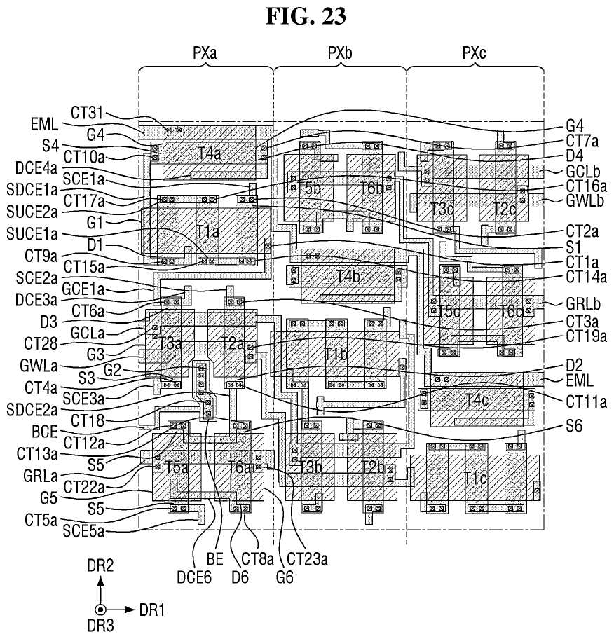

FIG. 23 is a plan view of a display device, according to an embodiment.

In an embodiment, the display device of FIG. 23 differs from the display device of FIGS. 7 to 22 described above in that a body electrode is selectively disposed in only one of a plurality of pixels. This difference will be described in detail below.

In an embodiment and as shown in FIG. 23, a body electrode BE may be disposed only in the first pixel PXa among the three pixels PXa, PXb, and PXc disposed to be adjacent in the first direction DR1. In this case, the body electrode BE may have an area equal to the total area of the first to third body electrodes BEa, BEb, and Bec, respectively, of FIGS. 10 to 12.

In an embodiment, at least a part of the body electrode BE may be disposed between adjacent gate electrodes. For example, as shown in FIG. 23, a part of the body electrode BE may be disposed between the third gate electrode G3 and the second gate electrode G2 disposed to be adjacent in the first direction DR1 in the first pixel PXa. In this case, one side surface of the third gate electrode G3 facing the body electrode BE may have a depressed shape directed toward the opposite side surface of the third gate electrode G3, and one side surface of the second gate electrode G2 facing the body electrode BE may have a depressed shape directed toward the opposite side surface of the second gate electrode G2.

In an embodiment, a body connection electrode BCE may be connected to the body electrode BE through an eighteenth contact hole CT18 penetrating the first interlayer insulating layer VI1.

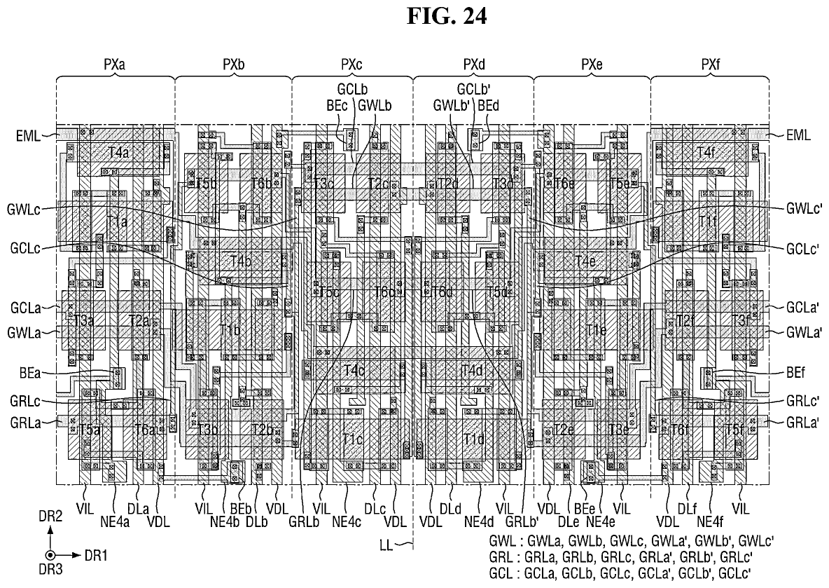

FIG. 24 is a plan view of a display device, according to an embodiment.

In an embodiment, the display device of FIG. 24 differs from the display device of FIGS. 7 to 22 described above in that it further includes fourth to sixth pixels PXd, PXe, and PXf, respectively, having a shape symmetrical to that of the first to third pixels PXa, PXb, and PXc, respectively, in the second direction DR2, and the emission line EML and the gate lines GWL, GRL, and GCL connected to the first to sixth pixels PXa to PXf which extend further in the first direction DR1. This difference will be described in detail below.

In an embodiment, the first to sixth pixels PXa to PXf, respectively, may be connected in common to the first gate line GWL, the second gate line GRL, the third gate line GCL, and the emission line EML.

In an embodiment, the first pixel PXa may be connected to the first data line DLa, the second pixel PXb may be connected to the second data line DLb, the third pixel PXc may be connected to the third data line DLc, the fourth pixel PXd may be connected to the fourth data line DLd, the fifth pixel PXe may be connected to the fifth data line DLe, and the sixth pixel PXf may be connected to the sixth data line DLf.

In an embodiment, since the configurations of the first to third pixels PXa, PXb, and PXc of FIG. 24 are the same as those of the first to third pixels PXa, PXb, and PXc of FIGS. 7 to 22 described above, respectively. For the configurations of the first to third pixels PXa, PXb, and PXc of FIG. 24, respectively, refer to FIGS. 7 to 22 and their related descriptions.

In an embodiment, the first to sixth pixels PXd, PXe, and PXf, respectively, may be arranged adjacently along the first direction DR1. When a virtual line extending along the second direction DR2 between the third pixel PXc and the fourth pixel PXd is defined as a reference line LL, the first to sixth pixels PXa to PXf, respectively, may have a symmetrical shape with respect to the reference line LL.

In an embodiment, the first to third pixels PXa, PXb, and PXc, respectively, disposed adjacent in the first direction DR1 may form a first unit pixel, and the fourth to sixth pixels PXd, PXe, and PXf, respectively, disposed adjacent in the first direction DR1 may form a second unit pixel.

In an embodiment, the fourth to sixth pixels PXd, PXe, and PXf, respectively, arranged adjacently along the first direction DR1 may provide light of different colors (or wavelengths). For example, the fourth pixel PXd may provide light of the first color, the fifth pixel PXe may provide light of the second color, and the sixth pixel PXf may provide light of the third color. Here, the first color may be any one of red, green, and blue, the second color may be any one of the above-described red, green, and blue colors different from the first color, and the third color may be any one of the above-described red, green, and blue colors different from the first color and the second color.

In an embodiment, the fourth pixel PXd disposed adjacent to the third pixel PXc in the first direction DR1 may have a shape that is symmetrical to that of the aforementioned third pixel PXc with respect to the reference line LL. The fourth pixel PXd may have the same configuration as that of the third pixel PXc. For example, first to sixth transistors T1d, T2d, T3d, T4d, T5d, and T6d, respectively, of the fourth pixel PXd may be the same as the first to sixth transistors T1c, T2c, T3c, T4c, T5c, and T6c, respectively, of the third pixel PXc, respectively. In addition, the arrangement positions in the second direction DR2 of the first to sixth transistors T1d, T2d, T3d, T4d, T5d, and Tod, respectively, of the fourth pixel PXd may be the same as the arrangement positions in the second direction DR2 of the first to sixth transistors T1c, T2c, T3c, T4c, T5c, and T6c, respectively, of the third pixel PXc described above, respectively.

In an embodiment, the fifth pixel PXe disposed adjacent to the fourth pixel PXd in the first direction DR1 may have a shape that is symmetrical to that of the aforementioned second pixel PXb with respect to the reference line LL. The fifth pixel PXe may have the same configuration as that of the second pixel PXb. For example, first to sixth transistors T1e, T2e, T3e, T4e, T5e, and T6e, respectively, of the fifth pixel PXe may be the same as the first to sixth transistors T1b, T2b, T3b, T4b, T5b, and T6b, respectively, of the second pixel PXb, respectively. In addition, the arrangement positions in the second direction DR2 of the first to sixth transistors T1e, T2e, T3e, T4e, T5e, and T6e, respectively, of the fifth pixel PXe may be the same as the arrangement positions in the second direction DR2 of the first to sixth transistors T1b, T2b, T3b, T4b, T5b, and T6b, respectively, of the second pixel PXb described above, respectively.

In an embodiment, the sixth pixel PXf disposed adjacent to the fifth pixel PXe in the first direction DR1 may have a shape that is symmetrical to that of the aforementioned first pixel PXa with respect to the reference line LL. The sixth pixel PXf may have the same configuration as that of the first pixel PXa. For example, first to sixth transistors T1f, T2f, T3f, T4f, T5f, and T6f, respectively, of the sixth pixel PXf may be the same as the first to sixth transistors T1a, T2a, T3a, T4a, T5a, and T6a, respectively, of the first pixel PXa, respectively. In addition, the arrangement positions in the second direction DR2 of the first to sixth transistors T1f, T2f, T3f, T4f, T5f, and T6f, respectively, of the sixth pixel PXf may be the same as the arrangement positions in the second direction DR2 of the first to sixth transistors T1a, T2a, T3a, T4a, T5a, and T6a, respectively, of the first pixel PXa described above, respectively.

In an embodiment, the first gate line GWL may include the first-first sub-gate line GWLa, the first-second sub-gate line GWLb, the first-third sub-gate line GWLc, a first-fourth sub-gate line GWLb′, a first-fifth sub-gate line GWLa′, and a first-sixth sub-gate line GWLc′.

In an embodiment, the first-first sub-gate line GWLa, the first-second sub-gate line GWLb, and the first-third sub-gate line GWLc described above may be the same as the first-first sub-gate line GWLa, the first-second sub-gate line GWLb, and the first-third sub-gate line GWLc of FIGS. 7 to 22 described above, respectively.

In an embodiment, the arrangement positions in the second direction DR2 of the first-fourth sub-gate line GWLb′, the first-fifth sub-gate line GWLa′, and the first-sixth sub-gate line GWLc′ may be the same as the arrangement positions in the second direction DR2 of the first-second sub-gate line GWLb, the first-first sub-gate line GWLa, and the first-third sub-gate line GWLc described above, respectively.

In an embodiment, the first-fourth sub-gate line GWLb′ may be connected to the gate electrode of the second transistor T2d provided in the fourth pixel PXd through a contact hole of the first interlayer insulating layer VI1. The first-fourth sub-gate line GWLb′ may have a shape that is symmetrical to that of the aforementioned first-second sub-gate line GWLb with respect to the reference line LL. The first-fourth sub-gate line GWLb′ and the first-second sub-gate line GWLb may be formed integrally.

In an embodiment, the first-fifth sub-gate line GWLa′ may be connected to the gate electrode of the second transistor T2e provided in the fifth pixel PXe and the gate electrode of the second transistor T2f provided in the sixth pixel PXf through contact holes of the first interlayer insulating layer VI1. The first-fifth sub-gate line GWLa′ may have a shape symmetrical to that of the aforementioned first-first sub-gate line GWLa with respect to the reference line LL.

In an embodiment, the first-sixth sub-gate line GWLc′ may be connected to the first-fourth sub-gate line GWLb′ and the first-fifth sub-gate line GWLa′ through contact holes of the second interlayer insulating layer VI2. The first-sixth sub-gate line GWLc′ may have a shape that is symmetrical to that of the aforementioned first-third sub-gate line GWLc with respect to the reference line LL.

In an embodiment, the second gate line GRL may include the second-first sub-gate line GRLa, the second-second sub-gate line GRLb, the second-third sub-gate line GRLc, a second-fourth sub-gate line GRLb′, a second-fifth sub-gate line GRLa′, and a second-sixth sub-gate line GRLc′.

In an embodiment, the second-first sub-gate line GRLa, the second-second sub-gate line GRLb, and the second-third sub-gate line GRLc described above may be the same as the second-first sub-gate line GRLa, the second-second sub-gate line GRLb, and the second-third sub-gate line GRLc of FIGS. 7 to 22 described above, respectively.

In an embodiment, the arrangement positions in the second direction DR2 of the second-fourth sub-gate line GRLb′, the second-fifth sub-gate line GRLa′, and the second-sixth sub-gate line GRLc′ may be the same as the arrangement positions in the second direction DR2 of the second-second sub-gate line GRLb, the second-first sub-gate line GRLa, and the second-third sub-gate line GRLc described above, respectively.

In an embodiment, the second-fourth sub-gate line GRLb′ may be connected to the gate electrode of the fifth transistor T5d provided in the fourth pixel PXd, the gate electrode of the sixth transistor Tod provided in the fourth pixel PXd, the gate electrode of the fifth transistor T5e provided in the fifth pixel PXe, and the gate electrode of the sixth transistor T6e provided in the fifth pixel PXe through contact holes of the first interlayer insulating layer VI1. The second-fourth sub-gate line GRLb′ may have a shape symmetrical to that of the aforementioned second-second sub-gate line GRLb with respect to the reference line LL. The second-fourth sub-gate line GRLb′ and the second-second sub-gate line GRLb may be formed integrally.

In an embodiment, the second-fifth sub-gate line GRLa′ may be connected to the gate electrode of the fifth transistor T5f provided in the sixth pixel PXf and the gate electrode of the sixth transistor T6f provided in the sixth pixel PXf through a contact hole of the first interlayer insulating layer VI1. The second-fifth sub-gate line GRLa′ may have a shape symmetrical to that of the aforementioned second-first sub-gate line GRLa with respect to the reference line LL.

In an embodiment, the second-sixth sub-gate line GRLc′ may be connected to the second-fourth sub-gate line GRLb′ and the second-fifth sub-gate line GRLa′ through contact holes of the second interlayer insulating layer VI2. The second-sixth sub-gate line GRLc′ may have a shape that is symmetrical to that of the aforementioned second-third sub-gate line GRLc with respect to the reference line LL.

In an embodiment, the third gate line GCL may include the third-first sub-gate line GCLa, the third-second sub-gate line GCLb, the third-third sub-gate line GCLc, a third-fourth sub-gate line GCLb′, a third-fifth sub-gate line GCLa′, and a third-sixth sub-gate line GCLc′.

In an embodiment, the third-first sub-gate line GCLa, the third-second sub-gate line GCLb, and the third-third sub-gate line GCLc described above may be the same as the third-first sub-gate line GCLa, the third-second sub-gate line GCLb, and the third-third sub-gate line GCLc of FIGS. 7 to 22 described above, respectively.

In an embodiment, the arrangement positions in the second direction DR2 of the third-fourth sub-gate line GCLb′, the third-fifth sub-gate line GCLa′, and the third-sixth sub-gate line GCLc′ may be the same as the arrangement positions in the second direction DR2 of the third-second gate line, the third-first gate line, and the third-third gate line described above, respectively.

In an embodiment, the third-fourth sub-gate line GCLb′ may be connected to the gate electrode of the third transistor T3d provided in the fourth pixel PXd through a contact hole of the first interlayer insulating layer VI1. The third-fourth sub-gate line GCLb′ may have a shape that is symmetrical to that of the aforementioned third-second sub-gate line GCLb with respect to the reference line LL. The third-fourth sub-gate line GCLb′ and the third-second sub-gate line GCLb may be formed integrally.

In an embodiment, the third-fifth sub-gate line GCLa′ may be connected to the gate electrode of the third transistor T3e provided in the fifth pixel PXe and the gate electrode of the third transistor T3f provided in the sixth pixel PXf through contact holes of the first interlayer insulating layer VI1. The third-fifth sub-gate line GCLa′ may have a shape that is symmetrical to that of the aforementioned third-first sub-gate line GCLa with respect to the reference line LL.

In an embodiment, the third-sixth sub-gate line GCLc′ may be connected to the third-fourth sub-gate line GCLb′ and the third-fifth sub-gate line GCLa′ through contact holes of the second interlayer insulating layer VI2. The third-sixth sub-gate line GCLc′ may have a shape that is symmetrical to that of the aforementioned third-third sub-gate line GCLc with respect to the reference line LL.

In an embodiment, a portion of the emission line EML that overlaps the first to third pixels PXa, PXb, and PXc, respectively, may be the same as that of the emission line EML of FIGS. 7 to 22 described above. The emission line EML may have a symmetrical shape with respect to the reference line LL. A portion of the emission line EML that overlaps the fourth pixel PXd may be connected to the gate electrode of the fourth transistor T4d provided in the fourth pixel PXd, a portion of the emission line EML that overlaps the fifth pixel PXe may be connected to the gate electrode of the fourth transistor T4c provided in the fifth pixel PXc, and a portion of the emission line EML that overlaps the sixth pixel PXf may be connected to the gate electrode of the fourth transistor T4f provided in the sixth pixel PXf.

In an embodiment, with respect to the reference line LL, the shapes of fourth to sixth body electrodes BEd, BEe, and BEf, respectively, of the fourth to sixth pixels PXd, PXe, and PXf, respectively, may be symmetrical to those of the first to third body electrodes BEa, BEb, and Bec, respectively, of the first to third pixels PXa, PXb, and PXc, respectively.

In an embodiment, reference signs NE4d, NE4c, and NE4f in FIG. 24 represent a fourth node electrode NE4d of the fourth pixel PXd, a fourth node electrode NE4e of the fifth pixel PXe, and a fourth node electrode NE4f of the sixth pixel PXf, respectively.

In an embodiment and according to the display device 10 of FIG. 24, the first to sixth transistors T1a to T6a, T1b to T6b, T1c to T6c, respectively, of each of the first to third pixels PXa, PXb, and PXc, respectively, and the first to sixth transistors T1d to Tod, T1e to Toe, T1f to T6f, respectively, of each of the fourth to sixth pixels PXd, PXe, and PXf, respectively, may be arranged symmetrically with respect to the reference line LL, and thus the first gate line GWL, the second gate line GRL, the third gate line GCL, and the emission line EML connected to the first to sixth pixels PXa to PXf, respectively, may have a symmetrical shape with respect to the reference line LL. Accordingly, both ends of the first gate line GWL may be disposed at the same position in the second direction DR2, both ends of the second gate line GRL may be disposed at the same position in the second direction DR2, both ends of the third gate line GCL may be disposed at the same position in the second direction DR2, and both ends of the emission line EML may be disposed at the same position in the second direction DR2. Therefore, when the two gate drivers 610 and the two emission control drivers 620 are respectively disposed on both sides of the non-display area NDA of the display panel 100, the two gate drivers 610 and the two emission control drivers 620 may be arranged symmetrically. As a result, area utilization of the non-display area NDA may be improved.

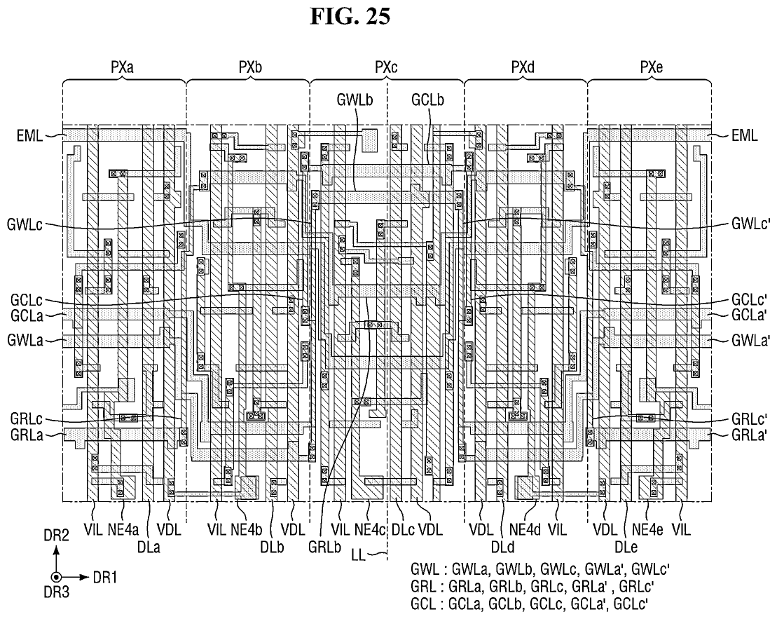

FIG. 25 is a plan view of a display device, according to an embodiment.

In an embodiment, the display device of FIG. 25 differs from the display device of FIGS. 7 to 22 described above in that it further includes the fourth pixel PXd and the fifth pixel PXe having a symmetrical shape in the second direction DR2, and the emission line EML and gate lines connected to the first to fifth pixels PXa to PXe, respectively, extend further in the first direction DR1. This difference will be described in detail below.

In an embodiment, the first to fifth pixels PXa to PXe, respectively, may be connected in common to the first gate line GWL, the second gate line GRL, the third gate line GCL, and the emission line EML.

In an embodiment, the first pixel PXa may be connected to the first data line DLa, the second pixel PXb may be connected to the second data line DLb, the third pixel PXc may be connected to the third data line DLc, the fourth pixel PXd may be connected to the fourth data line DLd, and the fifth pixel PXe may be connected to the fifth data line DLe.

In an embodiment, since the configurations of the first to third pixels PXa, PXb, and PXc, respectively, of FIG. 25 are the same as those of the first to third pixels PXa, PXb, and PXc, respectively, of FIGS. 7 to 22 described above, for the configurations of the first to third pixels PXa, PXb, and PXc, respectively, of FIG. 25, refer to FIGS. 7 to 22 and their related descriptions.

In an embodiment, the first to fifth pixels PXa to PXe, respectively, may be arranged adjacently along the first direction DR1. When a virtual line extending along the second direction DR2 to cross the center of the third pixel PXc is defined as the reference line LL, the first to fifth pixels PXa to PXe may have a symmetrical shape with respect to the reference line LL.

In an embodiment, the first to third pixels PXa, PXb, and PXc, respectively, disposed adjacent in the first direction DR1 may form a unit pixel.

In an embodiment, the fourth pixel PXd disposed adjacent to the third pixel PXc in the first direction DR1 may have a shape that is symmetrical to that of the aforementioned second pixel PXb with respect to the reference line LL. The fourth pixel PXd may have the same configuration as that of the second pixel PXb. For example, the first to sixth transistors of the fourth pixel PXd may be the same as the first to sixth transistors of the second pixel PXb, respectively. In addition, the arrangement positions in the second direction DR2 of the first to sixth transistors of the fourth pixel PXd may be the same as the arrangement positions in the second direction DR2 of the first to sixth transistors of the second pixel PXb described above, respectively.

In an embodiment, the fifth pixel PXe disposed adjacent to the fourth pixel PXd in the first direction DR1 may have a shape that is symmetrical to that of the aforementioned first pixel PXa with respect to the reference line LL. The fifth pixel PXe may have the same configuration as that of the first pixel PXa. For example, the first to sixth transistors of the fifth pixel PXe may be the same as the first to sixth transistors of the first pixel PXa, respectively. In addition, the arrangement positions in the second direction DR2 of the first to sixth transistors of the fifth pixel PXe may be the same as the arrangement positions in the second direction DR2 of the first to sixth transistors of the first pixel PXa described above, respectively.

In an embodiment, the first gate line GWL may include the first-first sub-gate line GWLa, the first-second sub-gate line GWLb, the first-third sub-gate line GWLc, a first-fourth sub-gate line GWLa′, and a first-fifth sub-gate line GWLc′.

In an embodiment, the first-first sub-gate line GWLa, the first-second sub-gate line GWLb, and the first-third sub-gate line GWLc may be the same as the first-first sub-gate line GWLa, the first-second sub-gate line GWLb, and the first-third sub-gate line GWLc of FIGS. 7 to 22 described above, respectively.

In an embodiment, the arrangement positions in the second direction DR2 of the first-fourth sub-gate line GWLa′ and the first-fifth sub-gate line GWLc′ may be the same as the arrangement positions in the second direction DR2 of the first-first sub-gate line GWLa and the first-third sub-gate line GWLc described above, respectively.

In an embodiment, the first-fourth sub-gate line GWLa′ may be connected to the gate electrode of the second transistor provided in the fourth pixel PXd and the gate electrode of the second transistor provided in the fifth pixel PXe through contact holes of the first interlayer insulating layer VI1. The first-fourth sub-gate line GWLa′ may have a shape that is symmetrical to that of the aforementioned first-first sub-gate line GWLa with respect to the reference line LL.

In an embodiment, the first-fifth sub-gate line GWLc′ may be connected to the first-fourth sub-gate line GWLa′ and the first-second sub-gate line GWLb through contact holes of the second interlayer insulating layer VI2. The first-fifth sub-gate line GWLc′ may have a shape that is symmetrical to that of the aforementioned first-third sub-gate line GWLc with respect to the reference line LL.

In an embodiment, the second gate line GRL may include the second-first sub-gate line GRLa, the second-second sub-gate line GRLb, the second-third sub-gate line GRLc, a second-fourth sub-gate line GRLa′, and a second-fifth sub-gate line GRLc′.

In an embodiment, the second-first sub-gate line GRLa and the second-third sub-gate line GRLc described above may be the same as the second-first sub-gate line GRLa and the second-third sub-gate line of FIGS. 7 to 22 described above, respectively.

In an embodiment, the arrangement positions in the second direction DR2 of the second-fourth sub-gate line GRLa′ and the second-fifth sub-gate line GRLc′ may be the same as the arrangement positions in the second direction DR2 of the second-first sub-gate line GRLa and the second-third sub-gate line GRLc described above, respectively.

In an embodiment, the second-second sub-gate line GRLb may have a symmetrical shape with respect to the reference line LL. The second-second sub-gate line GRLb may be connected to the gate electrode of the fifth transistor provided in the second pixel PXb, the gate electrode of the sixth transistor provided in the second pixel PXb, the gate electrode of the fifth transistor provided in the third pixel PXc, the gate electrode of the sixth transistor provided in the third pixel PXc, the gate electrode of the fifth transistor provided in the fourth pixel PXd, and the gate electrode of the sixth transistor provided in the fourth pixel PXd through contact holes of the first interlayer insulating layer VI1.

In an embodiment, the second-fourth sub-gate line GRLa′ may be connected to the gate electrode of the fifth transistor provided in the fifth pixel PXe and the gate electrode of the sixth transistor provided in the fifth pixel PXe through a contact hole of the first interlayer insulating layer VI1. The second-fourth sub-gate line GRLa′ may have a shape that is symmetrical to that of the aforementioned second-first sub-gate line GRLa with respect to the reference line LL.

In an embodiment, the second-fifth sub-gate line GRLc′ may be connected to the second-fourth sub-gate line GRLa′ and the second-second sub-gate line GRLb through contact holes of the second interlayer insulating layer VI2. The second-fifth sub-gate line GRLc′ may have a shape that is symmetrical to that of the aforementioned second-third sub-gate line GRLc with respect to the reference line LL.

In an embodiment, the third gate line GCL may include the third-first sub-gate line GCLa, the third-second sub-gate line GCLb, the third-third sub-gate line GCLc, a third-fourth sub-gate line GCLa′, and a third-fifth sub-gate line GCLc′.

In an embodiment, the third-first sub-gate line GCLa, the third-second sub-gate line GCLb, and the third-third sub-gate line GCLc described above may be the same as the third-first sub-gate line GCLa, the third-second sub-gate line GCLb, and the third-third sub-gate line GCLc of FIGS. 7 to 22 described above, respectively.

In an embodiment, the arrangement positions in the second direction DR2 of the third-fourth sub-gate line GCLa′ and the third-fifth sub-gate line GCLc′ may be the same as arrangement positions in the second direction DR2 of the third-first sub-gate line GCLa and the third-third sub-gate line GCLc described above, respectively.

In an embodiment, the third-fourth sub-gate line GCLa′ may be connected to the gate electrode of the third transistor provided in the fourth pixel PXd through a contact hole of the first interlayer insulating layer VI1. The third-fourth sub-gate line GCLa′ may have a shape that is symmetrical to that of the aforementioned third-first sub-gate line GCLa with respect to the reference line LL.

In an embodiment, the third-fifth sub-gate line GCLc′ may be connected to the third-fourth sub-gate line GCLa′ and the third-second sub-gate line GCLb through contact holes of the second interlayer insulating layer VI2. The third-fifth sub-gate line GCLc′ may have a shape that is symmetrical to that of the aforementioned third-third sub-gate line GCLc with respect to the reference line LL.

In an embodiment, a portion of the emission line EML that overlaps the first to third pixels PXa, PXb, and PXc, respectively, may be the same as that of the emission line EML of FIGS. 7 to 22 described above. The emission line EML may have a symmetrical shape with respect to the reference line LL. A portion of the emission line EML that overlaps the fourth pixel PXd may be connected to the gate electrode of the fourth transistor provided in the fourth pixel PXd, and a portion of the emission line EML that overlaps the fifth pixel PXe may be connected to the gate electrode of the fourth transistor provided in the fifth pixel PXc.

In an embodiment, reference signs NE4d and NE4e in FIG. 25 represent a fourth node electrode NE4d of the fourth pixel PXd and a fourth node electrode NE4e of the fifth pixel PXe, respectively.

In an embodiment and according to the display device 10 of FIG. 25, the first to sixth transistors of each of the first to fifth pixels PXa to PXe, respectfully, may be arranged symmetrically with respect to the reference line LL, and thus the first gate line GWL, the second gate line GRL, the third gate line GCL, and the emission line EML connected to the first to fifth pixels PXa to PXe, respectively, may have a symmetrical shape with respect to the reference line LL. Accordingly, both ends of the first gate line GWL may be disposed at the same position in the second direction DR2, both ends of the second gate line GRL may be disposed at the same position in the second direction DR2, both ends of the third gate line GCL may be disposed at the same position in the second direction DR2, and both ends of the emission line EML may be disposed at the same position in the second direction DR2. Therefore, when the two gate drivers 610 and the two emission control drivers 620 are respectively disposed on both sides of the non-display area NDA of the display panel 100, the two gate drivers 610 and the two emission control drivers 620 may be arranged symmetrically. As a result, area utilization of the non-display area NDA may be improved.

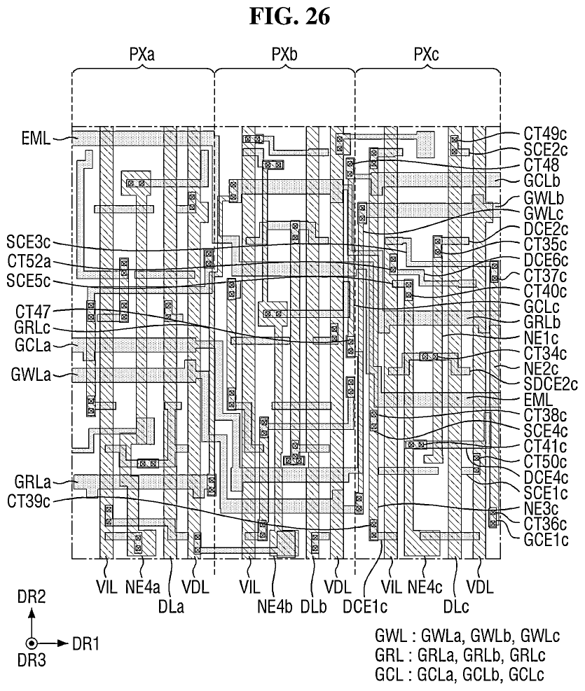

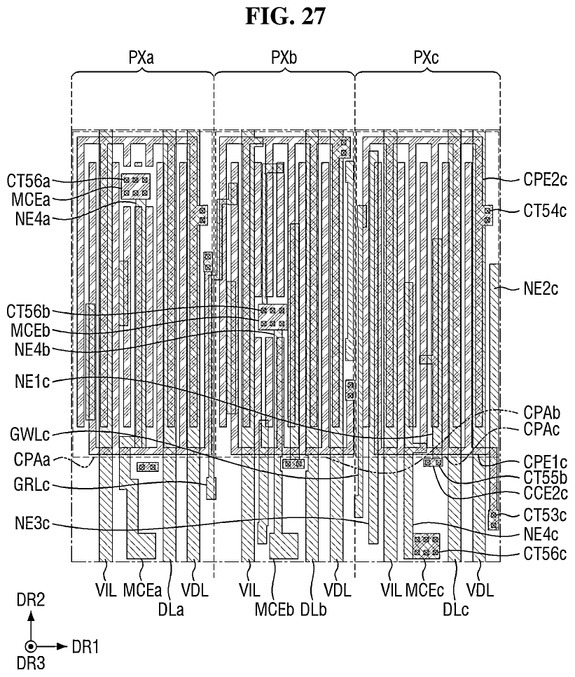

FIGS. 26 and 27 are plan views of a display device, according to an embodiment.

In an embodiment, the display device 10 of FIGS. 26 and 27 differs from the display device 10 of FIGS. 7 to 22 described above in that a connection portion between the fourth node electrode NE4a and the first intermediate connection electrode MCEa of the first pixel PXa, and a connection portion between the fourth node electrode NE4b and the second intermediate connection electrode MCEb of the second pixel PXb are each disposed in a capacitor area of the corresponding pixel. This difference will be described in detail below.

In an embodiment and as shown in FIGS. 26 and 27, the fourth node electrode NE4a and the first intermediate connection electrode MCEa of the first pixel PXa may be connected to each other in a first capacitor area CPAa of the first pixel PXa. In other words, the first intermediate connection electrode MCEa of the first pixel PXa may be disposed in the first capacitor area CPAa of the first pixel PXa, and the first intermediate connection electrode MCEa may be connected to the fourth node electrode NE4a through a fifty-sixth contact hole CT56a of the third interlayer insulating layer VI3.

In another embodiment, as shown in FIGS. 26 and 27, the fourth node electrode NE4b and the second intermediate connection electrode MCEb of the second pixel PXb may be connected to each other in a second capacitor area CPAb of the second pixel PXb. In other words, the second intermediate connection electrode MCEb of the second pixel PXb may be disposed in the second capacitor area CPAb of the second pixel PXb, and the second intermediate connection electrode MCEb may be connected to the fourth node electrode NE4b through the fifty-sixth contact hole CT56b of the third interlayer insulating layer VI3. Meanwhile, the position of the second intermediate connection electrode MCEb of the second pixel PXb may be different from the position of the first intermediate connection electrode MCEa of the first pixel PXa. For example, in the second direction DR2, the second intermediate connection electrode MCEb may be disposed between the first intermediate connection electrode MCEa and the third intermediate connection electrode MCEc.

In an embodiment, although not shown in the drawings, the third intermediate connection electrode MCEc of the third pixel PXc may be disposed in a third capacitor area CPAc of the third pixel PXc.

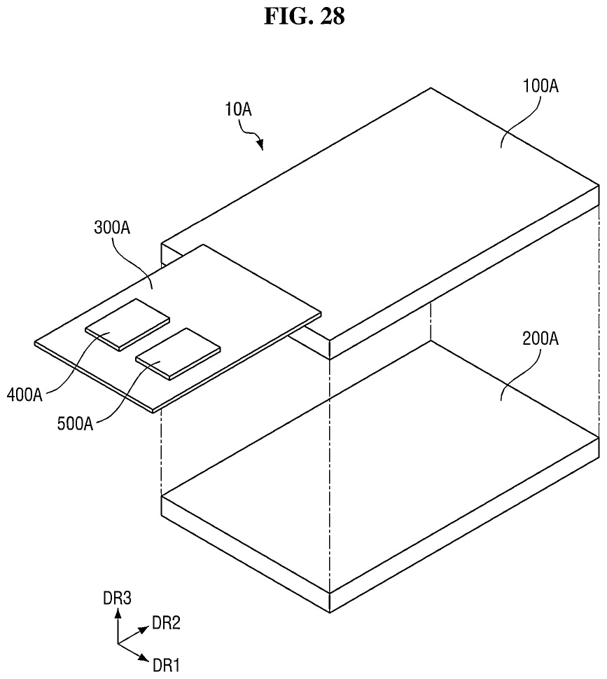

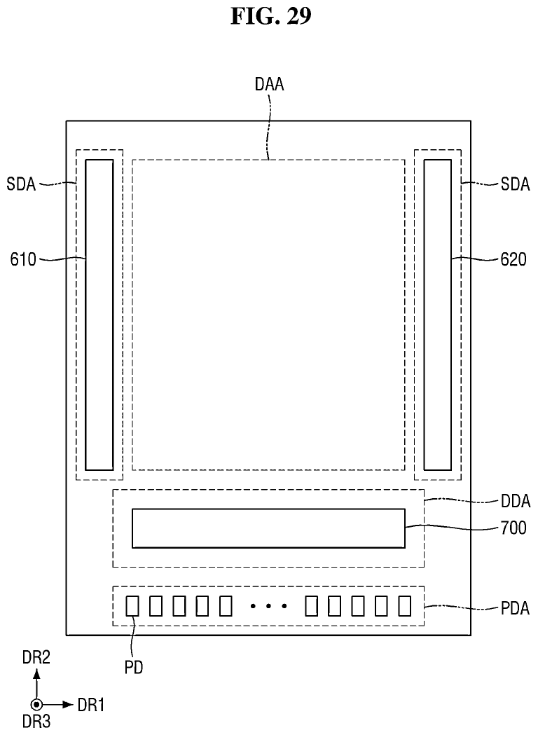

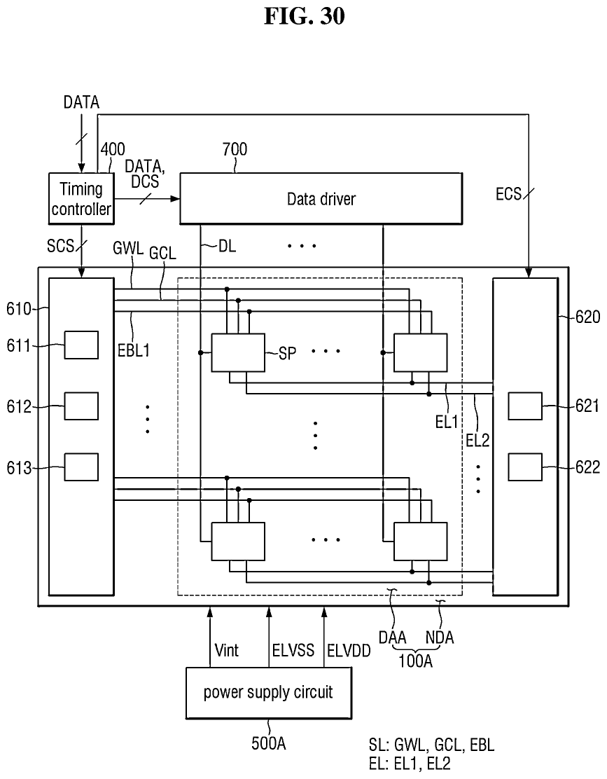

FIG. 28 is an exploded perspective view showing a display device, according to an embodiment. FIG. 29 is a layout view illustrating an example of the display panel shown in FIG. 28, according to an embodiment. FIG. 30 is a block diagram illustrating a display device, according to an embodiment.

Referring to FIGS. 28 and 29, a display device 10A according to an embodiment is a device displaying a moving image or a still image. The display device 10A according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10A may be applied as a display unit of a television, a laptop, a monitor, a billboard, or an Internet-of-Things (IoT) device. In another embodiment, the display device 10A may be applied to a smart watch, a watch phone, a head mounted display (HMD) for implementing virtual reality and augmented reality, and the like.

In an embodiment, the display device 10A includes a display panel 100A, a heat dissipation layer 200A, a circuit board 300A, a timing control circuit 400A, and a power supply circuit 500A.

In an embodiment, the display panel 100A may have a planar shape similar to a quadrilateral shape. For example, the display panel 100A may have a planar shape similar to a quadrilateral shape, having a short side of the first direction DR1 and a long side of the second direction DR2 intersecting the first direction DR1. In the display panel 100A, a corner where a short side in the first direction DR1 and a long side in the second direction DR2 meet may be right-angled or rounded with a predetermined curvature. The planar shape of the display panel 100A is not limited to a rectangular shape, and may be a shape similar to another polygonal shape, a circular shape, or an elliptical shape. The planar shape of the display device 10A may conform to the planar shape of the display panel 100A, but the embodiment of the invention is not limited thereto.

In an embodiment, the display panel 100A includes a display area DAA displaying an image and a non-display area NDA not displaying an image as shown in FIG. 29.

In an embodiment, the display area DAA includes a plurality of pixels PX, a plurality of scan lines SL, a plurality of emission control lines EL, and a plurality of data lines DL.

In an embodiment, each of the plurality of pixels PX includes a light emitting element that emits light. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

In an embodiment, the plurality of scan lines SL include a plurality of write scan lines GWL, a plurality of control scan lines GCL, and a plurality of bias scan lines EBL. The plurality of emission control lines EL include a plurality of first emission control lines EL1 and a plurality of second emission control lines EL2.

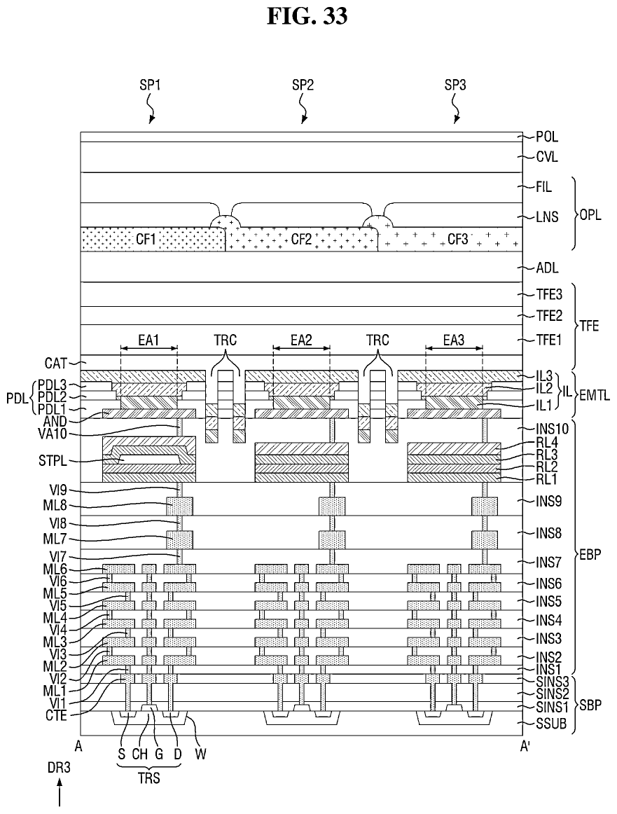

In an embodiment, the plurality of pixels PX (or the aforementioned unit pixels) include a plurality of sub-pixels SP1, SP2, and SP3. The plurality of sub-pixels SP1, SP2, and SP3 may include a plurality of pixel transistors as shown in FIG. 4, and the plurality of pixel transistors may be formed by a semiconductor process and disposed on a semiconductor substrate SSUB (see FIG. 33). For example, the plurality of pixel transistors may be formed of a complementary metal oxide semiconductor (CMOS).

In an embodiment, each of the plurality of sub-pixels SP1, SP2, and SP3 may be connected to any one write scan line GWL among the plurality of write scan lines GWL, any one control scan line GCL among the plurality of control scan lines GCL, any one bias scan line EBL among the plurality of bias scan lines EBL, any one first light emission control line EL1 among the plurality of first light emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light emitting element according to the data voltage.

In an embodiment, the non-display area NDA includes a scan driving area SDA, a data driving area DDA, and a pad area PDA.

In an embodiment, the scan driving area SDA may be an area in which a scan driver 610 and an emission driver 620 are disposed. Although it is illustrated in FIG. 2 that the scan driver 610 is disposed on the left side of the display area DAA and the emission driver 620 is disposed on the right side of the display area DAA, the embodiment of the invention is not limited thereto. For example, the scan driver 610 and the emission driver 620 may be disposed on both the left side and the right side of the display area DAA.

In an embodiment, the scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 33) through a semiconductor process. For example, the plurality of scan transistors and the plurality of light emitting transistors may be formed of a CMOS.

In an embodiment, the scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from a timing control circuit 400A. The write scan signal output unit 611 may generate write scan signals according to the scan timing control signal SCS of the timing control circuit 400A and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines EBL.

In an embodiment, the emission driver 620 includes a first emission control driver 621 and a second emission control driver 622. Each of the first emission control driver 621 and the second emission control driver 622 may receive an emission timing control signal ECS from the timing control circuit 400A. The first emission control driver 621 may generate first emission control signals according to the emission timing control signal ECS and sequentially output them to first emission control lines EL1. The second emission control driver 622 may generate second emission control signals according to the emission timing control signal ECS and sequentially output them to second emission control lines EL2.

In an embodiment, the data driving area DDA may be an area in which a data driver 700 is disposed. The data driver 700 may include a plurality of data transistors, and the plurality of data transistors may be formed on the semiconductor substrate SSUB (see FIG. 33) through a semiconductor process. For example, the plurality of data transistors may be formed of a CMOS.

In an embodiment, the data driver 700 may receive digital video data DATA and data timing control signal DCS from the timing control circuit 400A. The data driver 700 converts the digital video data DATA into analog data voltages according to the data timing control signal DCS and outputs the analog data voltages to the data lines DL. In this case, the sub-pixels SP1, SP2, and SP3 are selected by the write scan signal of the scan driver 610, and data voltages may be supplied to the selected sub-pixels SP1, SP2, and SP3.

In an embodiment, the pad area PDA includes a plurality of pads PD arranged in the first direction DR1. Each of the plurality of pads PD may be exposed without being covered by a cover layer CVL (see FIG. 33) and a polarizing plate POL (see FIG. 33).

In an embodiment, the heat dissipation layer 200A may overlap the display panel 100A in the third direction DR3, which is the thickness direction of the display panel 100A. The heat dissipation layer 200A may be disposed on one surface of the display panel 100A, for example, on the rear surface thereof. The heat dissipation layer 200A serves to dissipate heat generated from the display panel 100A. The heat dissipation layer 200A may include a metal layer such as graphite, silver (Ag), copper (Cu), or aluminum (Al) having high thermal conductivity.

In an embodiment, the circuit board 300A may be electrically connected to a plurality of pads PD in the pad area PDA of the display panel 100A by using a conductive adhesive member such as an anisotropic conductive film. The circuit board 300A may be a flexible printed circuit board with a flexible material, or a flexible film. Although the circuit board 300A is illustrated in FIG. 1 as being unfolded, the circuit board 300A may be bent. In this case, one end of the circuit board 300A may be disposed on the rear surface of the display panel 100A. The one end of the circuit board 300A may be an end disposed opposite to the other end of the circuit board 300A that is connected to the plurality of pads PD of the pad area PDA of the display panel 100A by using a conductive adhesive member.

In an embodiment, the timing control circuit 400A may receive digital video data and timing signals inputted from the outside. The timing control circuit 400A may generate the scan timing control signal SCS, the emission timing control signal ECS, and a data timing control signal DCS for controlling the display panel 100A in response to the timing signals. The timing control circuit 400A may output the scan timing control signal SCS to the scan driver 610, and output the emission timing control signal ECS to the emission driver 620. The timing control circuit 400A may output the digital video data and the data timing control signal DCS to the data driver 700.

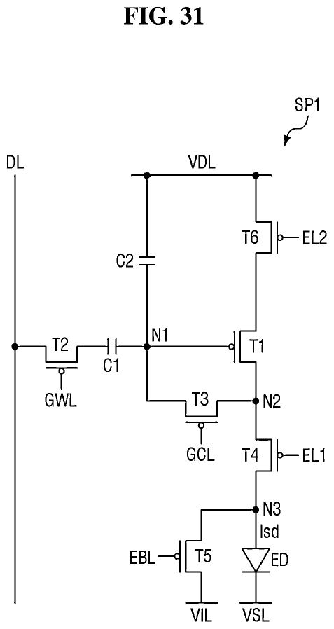

In an embodiment, the power supply circuit 500A may generate a plurality of panel driving voltages according to a power voltage from the outside. For example, the power supply circuit 500A may generate a first driving voltage VSS, a second driving voltage VDD, and a third driving voltage VINT and supply them to the display panel 100A. The first driving voltage VSS, the second driving voltage VDD, and the third driving voltage VINT will be described later in conjunction with FIG. 31.

In an embodiment, each of the timing control circuit 400A and the power supply circuit 500A may be formed as an integrated circuit (IC) and attached to one side of the circuit board 300A. The scan timing control signal SCS, the emission timing control signal ECS, the digital video data DATA, and the data timing control signal DCS of the timing control circuit 400A may be supplied to the display panel 100A through the circuit board 300A. The first driving voltage VSS, the second driving voltage VDD, and the third driving voltage VINT of the power supply circuit 500A may be supplied to the display panel 100A through the circuit board 300A.

FIG. 31 is an equivalent circuit diagram of a first sub-pixel, according to an embodiment.

In an embodiment and referring to FIG. 31, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

In an embodiment, the first sub-pixel SP1 includes a plurality of transistors T1 to T5, a light emitting element LE, a first capacitor C1, and a second capacitor C2.

In an embodiment, the light emitting element LE emits light in response to a driving current Ids flowing through the channel of the first transistor T1. The emission amount of the light emitting element LE may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the invention is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

In an embodiment, the first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 includes a gate electrode connected to the first node N1, a source electrode connected to the drain electrode of the sixth transistor T6, and a drain electrode connected to the second node N2.

In an embodiment, the second transistor T2 may be disposed between one electrode of the first capacitor C1 and the data line DL. The second transistor T2 is turned on by the write scan signal of the write scan line GWL to connect the one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

In an embodiment, the third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

In an embodiment, the fourth transistor T4 may be connected between the second node N2 and a third node N3. The fourth transistor ST4 is turned on by the first emission control signal of the first emission control line EL1 to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

In an embodiment, the fifth transistor T5 may be disposed between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

In an embodiment, the sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

In an embodiment, the first capacitor C1 is formed between the first node N1 and the drain electrode of the second transistor T2. The first capacitor C1 includes one electrode connected to the drain electrode of the second transistor T2 and the other electrode connected to the first node N1.

In an embodiment, the second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

In an embodiment, the first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

In an embodiment, each of the first to sixth transistors T1 to T6, respectively, may be a metal-oxide-semiconductor field effect transistor (MOSFET). For example, each of the first to sixth transistors T1 to T6, respectively, may be a P-type MOSFET, but the embodiment of the invention is not limited thereto. Each of the first to sixth transistors T1 to T6, respectively, may be an N-type MOSFET. In another embodiment, some of the first to sixth transistors T1 to T6, respectively, may be P-type MOSFETs, and each of the remaining transistors may be an N-type MOSFET.

In an embodiment, although it is illustrated in FIG. 31 that the first sub-pixel SP1 includes six transistors T1 to T6 and two capacitors C1 and C2, it should be noted that the equivalent circuit diagram of the first sub-pixel SP1 is not limited to that shown in FIG. 31. For example, the number of transistors and the number of capacitors of the first sub-pixel SP1 are not limited to those shown in FIG. 31.

Further, in an embodiment, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 4. Therefore, the description of the equivalent circuit diagram of the second sub-pixel SP2 and the equivalent circuit diagram of the third sub-pixel SP3 are omitted in the present disclosure.

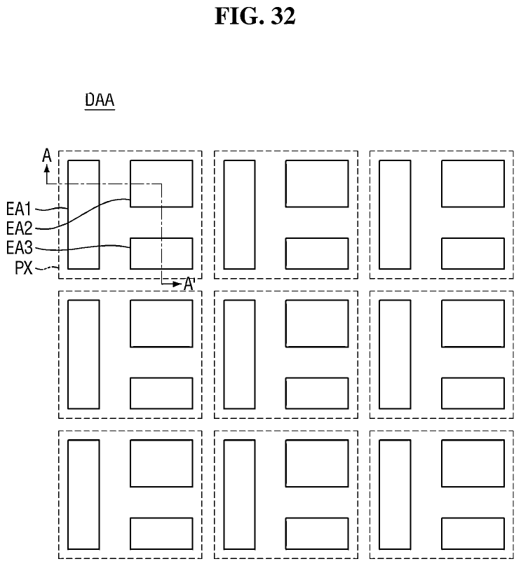

FIG. 32 is a layout view illustrating pixels of a display area, according to an embodiment.

In an embodiment and referring to FIG. 32, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

In an embodiment, each of the first emission area EA1, the second emission area EA2, and the third emission area EA3 may have, in a plan view, a quadrilateral shape such as a rectangle, a square, or a diamond. For example, the first emission area EA1 may have a rectangular shape, in a plan view, having a short side in the first direction DR1 and a long side in the second direction DR2. In addition, each of the second emission area EA2 and the third emission area EA3 may have a rectangular shape, in a plan view, having a long side in the first direction DR1 and a short side in the second direction DR2.

In an embodiment, the length of the first emission area EA1 in the first direction DR1 may be smaller than the length of the second emission area EA2 in the first direction DR1, and may be smaller than the length of the third emission area EA3 in the first direction DR1. The length of the second emission area EA2 in the first direction DR1 and the length of the third emission area EA3 in the first direction DR1 may be substantially the same.

In an embodiment, the length of the first emission area EA1 in the second direction DR2 may be larger than the sum of the length of the second emission area EA2 in the second direction DR2 and the length of the third emission area EA3 in the second direction DR2. The length of the second emission area EA2 in the second direction DR2 may be smaller than the length of the third emission area EA3 in the second direction DR2.

In an embodiment, although it is illustrated in FIG. 32 that each of the first emission area EA1, the second emission area EA2, and the third emission area EA3 has a rectangular shape in a plan view, the embodiment of the invention is not limited thereto. For example, each of the first emission area EA1, the second emission area EA2, and the third emission area EA3 may have a polygonal shape other than a quadrilateral shape, a circular shape, or an elliptical shape in a plan view.

In an embodiment, in each of the plurality of pixels PX, the first emission area EA1 and the second emission area EA2 may be disposed adjacent to each other in the first direction DR1. Further, the first emission area EA1 and the third emission area EA3 may be disposed adjacent to each other in the first direction DR1. In addition, the second emission area EA2 and the third emission area EA3 may be disposed adjacent to each other in the second direction DR2. The area of the first emission area EA1, the area of the second emission area EA2, and the area of the third emission area EA3 may be different.

In an embodiment, the first emission area EA1 may emit light of the first color, the second emission area EA2 may emit light of the second color, and the third emission area EA3 may emit light of the third color. Here, the first color light may be light of a blue wavelength band, the second color light may be light of a green wavelength band, and the third color light may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

In an embodiment, although it is illustrated in FIG. 32 that each of the plurality of pixels PX includes the three emission areas EA1, EA2, and EA3, the embodiment of the invention is not limited thereto. That is, each of the plurality of pixels PX may include four emission areas.

In addition, the layout of the emission areas of the plurality of pixels PX is not limited to that shown in FIG. 32. For example, in an embodiment, the emission areas of the plurality of pixels PX may be arranged in a stripe structure in which the emission areas are arranged in the first direction DR1, a PenTile® structure in which the emission areas are arranged in a diamond shape, or a hexagonal structure in which the emission areas having, in a plan view, a hexagonal shape are arranged side by side.

FIG. 33 is a cross-sectional view illustrating an example of a display device taken along line A-A′ of FIG. 32, according to an embodiment.

In an embodiment and referring to FIG. 33, the display panel 100A includes a semiconductor backplane SBP, a light emitting element backplane EBP, a light emitting element layer EMTL, an encapsulation layer TFE, an optical layer OPL, the cover layer CVL, and the polarizing plate POL.

In an embodiment, the semiconductor backplane SBP includes the semiconductor substrate SSUB including a plurality of pixel transistors TRS, a plurality of semiconductor insulating layers covering the plurality of pixel transistors TRS, and a plurality of contact terminals CTE electrically connected to the plurality of pixel transistors TRS, respectively. The plurality of pixel transistors TRS may be the first to sixth transistors T1 to T6, respectively, described with reference to FIG. 4.

In an embodiment, the semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. In another embodiment, when the first type impurity is an n-type impurity, the second type impurity may be a p-type impurity.

In an embodiment, each of the plurality of well regions WA includes a source region SA corresponding to the source electrode of the pixel transistor TRS, a drain region DA corresponding to the drain electrode thereof, and a channel region CH disposed between the source region SA and the drain region DA.

In an embodiment, each of the source region SA and the drain region DA may be a region doped with the first type impurity. A gate electrode GE of the pixel transistor TRS may overlap the well region WA in the third direction DR3. The channel region CH may overlap the gate electrode GE in the third direction DR3. The source region SA may be disposed on one side of the gate electrode GE, and the drain region SA may be disposed on the other side of the gate electrode GE.

In an embodiment, each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than that of the source region SA. The second low-concentration impurity region LDD2 may be a region having an impurity concentration lower than that of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors TRS may increase, so that punch-through and hot carrier phenomena that might be caused by a short channel may be prevented.

In an embodiment, a first semiconductor insulating layer SINS1 may be disposed on the semiconductor substrate SSUB. The first semiconductor insulating layer SINS1 may be formed of silicon carbonitride (SiCN) or a silicon oxide (SiOx)-based inorganic layer, but the embodiment of the present specification is not limited thereto.

In an embodiment, a second semiconductor insulating layer SINS2 may be disposed on the first semiconductor insulating layer SINS1. The second semiconductor insulating layer SINS2 may be formed of a silicon oxide (SiOx)-based inorganic layer, but the invention is not limited thereto.

The plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors TRS through holes penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, a third semiconductor insulating layer SINS3 may be disposed on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the invention is not limited thereto.

In an embodiment, the semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that may be bent or curved.

In an embodiment, the light emitting element backplane EBP includes first to eighth metal layers ML1 to ML8, respectively, reflective metal layers RL1 to RLA, respectively, a plurality of vias VI1 to VI10, respectively, and a step layer STPL. In addition, the light emitting element backplane EBP includes a plurality of interlayer insulating layers INS1 to INS10 disposed between the first to sixth metal layers ML1 to ML6.

In an embodiment, the first to eighth metal layers ML1 to ML8, respectively, serve to connect the plurality of contact terminals CTE exposed from the semiconductor backplane SBP to thereby implement the circuit of the first sub-pixel SP1 shown in FIG. 4. That is, the first to sixth transistors T1 to T6, respectively, are merely formed on the semiconductor backplane SBP, and the connection of the first to sixth transistors T1 to T6, respectively, and the first capacitor C1 and the second capacitor C2 is accomplished through the first to eighth metal layers ML1 to ML8, respectively. In addition, the connection between the drain region corresponding to the drain electrode of the fourth transistor T4, the source region corresponding to the source electrode of the fifth transistor T5, and the first electrode of the light emitting element LE is also accomplished through the first to eighth metal layers ML1 to ML8, respectively.

In an embodiment, the first interlayer insulating layer INS1 may be disposed on the semiconductor backplane SBP. Each of the first vias VI1 may penetrate the first interlayer insulating layer INS1 to be connected to the contact terminal CTE exposed from the semiconductor backplane SBP. Each of the first metal layers ML1 may be disposed on the first interlayer insulating layer INS1 and may be connected to the first via VI1.

In an embodiment, the second interlayer insulating layer INS2 may be disposed on the first interlayer insulating layer INS1 and the first metal layers ML1. Each of the second vias VI2 may penetrate the second interlayer insulating layer INS2 and be connected to the exposed first metal layer ML1. Each of the second metal layers ML2 may be disposed on the second interlayer insulating layer INS2 and may be connected to the second via VI2.

In an embodiment, the third interlayer insulating layer INS3 may be disposed on the second interlayer insulating layer INS2 and the second metal layers ML2. Each of the third vias VI3 may penetrate the third interlayer insulating layer INS3 and be connected to the exposed second metal layer ML2. Each of the third metal layers ML3 may be disposed on the third interlayer insulating layer INS3 and may be connected to the third via VI3.

In an embodiment, a fourth interlayer insulating layer INS4 may be disposed on the third interlayer insulating layer INS3 and the third metal layers ML3. Each of the fourth vias VI4 may penetrate the fourth interlayer insulating layer INS4 and be connected to the exposed third metal layer ML3. Each of the fourth metal layers ML4 may be disposed on the fourth interlayer insulating layer INS4 and may be connected to the fourth via VI4.

In an embodiment, a fifth interlayer insulating layer INS5 may be disposed on the fourth interlayer insulating layer INS4 and the fourth metal layers ML4. Each of the fifth vias VI5 may penetrate the fifth interlayer insulating layer INS5 and be connected to the exposed fourth metal layer ML4. Each of the fifth metal layers ML5 may be disposed on the fifth interlayer insulating layer INS5 and may be connected to the fifth via VI5.

In an embodiment, a sixth interlayer insulating layer INS6 may be disposed on the fifth interlayer insulating layer INS5 and the fifth metal layers ML5. Each of the sixth vias VI6 may penetrate the sixth interlayer insulating layer INS6 and be connected to the exposed fifth metal layer ML5. Each of the sixth metal layers ML6 may be disposed on the sixth interlayer insulating layer INS6 and may be connected to the sixth via VI6.

In an embodiment, a seventh interlayer insulating layer INS7 may be disposed on the sixth interlayer insulating layer INS6 and the sixth metal layers ML6. Each of the seventh vias VI7 may penetrate the seventh interlayer insulating layer INS7 and be connected to the exposed sixth metal layer ML6. Each of the seventh metal layers ML7 may be disposed on the seventh interlayer insulating layer INS7 and may be connected to the seventh via VI7.

In an embodiment, an eighth interlayer insulating layer INS8 may be disposed on the seventh interlayer insulating layer INS7 and the seventh metal layers ML7. Each of the eighth vias VI8 may penetrate the eighth interlayer insulating layer INS8 and be connected to the exposed seventh metal layer ML7. Each of the eighth metal layers ML8 may be disposed on the eighth interlayer insulating layer INS8 and may be connected to the eighth via VI8.

In an embodiment, the first to eighth metal layers ML1 to ML8, respectively, and the first to eighth vias VI1 to VI8, respectively, may be formed of substantially the same material. The first to eighth metal layers ML1 to ML8, respectively, and the first to eighth vias VI1 to VI8, respectively, may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VI1 to VI8, respectively, may be made of substantially the same material. First to eighth interlayer insulating layers INS1 to INS8, respectively, may be formed of a silicon oxide (SiOx)-based inorganic layer, but the invention is not limited thereto.

In an embodiment, the thicknesses of the first metal layer ML1, the second metal layer ML2, the third metal layer ML3, the fourth metal layer ML4, the fifth metal layer ML5, and the sixth metal layer ML6 may be larger than the thicknesses of the first via VI1, the second via VI2, the third via VI3, the fourth via VI4, the fifth via VI5, and the sixth via VI6, respectively. The thickness of each of the second metal layer ML2, the third metal layer ML3, the fourth metal layer ML4, the fifth metal layer ML5, and the sixth metal layer ML6 may be larger than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be about 1360 Å, the thickness of each of the second metal layer ML2, the third metal layer ML3, the fourth metal layer ML4, the fifth metal layer ML5, and the sixth metal layer ML6 may be about 1440 Å, and the thickness of each of the first via VI1, the second via VI2, the third via VI3, the fourth via VI4, the fifth via VI5, and the sixth via VI6 may be about 1150 Å.

In an embodiment, the thickness of each of the seventh metal layer ML7 and the eighth metal layer ML8 may be larger than the thickness of the first metal layer ML1, the thickness of the second metal layer ML2, the thickness of the third metal layer ML3, the thickness of the fourth metal layer ML4, the thickness of the fifth metal layer ML5, and the sixth metal layer ML6. The thickness of the seventh metal layer ML7 and the thickness of the eighth metal layer ML8 may be larger than the thickness of the seventh via VI7 and the thickness of the eighth via VI8, respectively. The thickness of each of the seventh via VI7 and the eighth via VI8 may be larger than the thickness of the first via VI1, the thickness of the second via VI2, the thickness of the third via VI3, the thickness of the fourth via VI4, the thickness of the fifth via VI5, and the thickness of the sixth via VI6. The thickness of the seventh metal layer ML7 and the thickness of the eighth metal layer ML8 may be substantially the same. For example, the thickness of each of the seventh metal layer ML7 and the eighth metal layer ML8 may be about 9000 Å. The thickness of each of the seventh via VI7 and the eighth via VI8 may be about 6000 Å.

In an embodiment, a ninth interlayer insulating layer INS9 may be disposed on the eighth interlayer insulating layer INS8 and the eighth metal layers ML8. The ninth insulating layer INS9 may be formed of a silicon oxide (SiOx)-based inorganic layer, but the invention is not limited thereto.

In an embodiment, each of the ninth vias VI9 may penetrate the ninth interlayer insulating layer INS9 and be connected to the exposed eighth metal layer ML8. The ninth vias VI9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VI9 may be about 16500 Å.

In an embodiment, each of the first reflective electrodes RL1 may be disposed on the ninth interlayer insulating layer INS9, and may be connected to the ninth via VI9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may be made of titanium nitride (TiN).

In an embodiment and in the first sub-pixel SP1, the step layer STPL may be disposed on the second reflective electrode RL2. The step layer STPL may not be disposed in each of the second sub-pixel SP2 and the third sub-pixel SP3. In order to advantageously reflect the light of the first color emitted from a first light emitting layer EML1 of the first sub-pixel SP1, the thickness of the step layer STPL may be set in consideration of the wavelength of the light of the first color and the distance from the first light emitting layer EML1 to the fourth reflective electrode RL4. The step layer STPL may be formed of silicon carbonitride (SiCN) or a silicon oxide (SiOx)-based inorganic layer, but the invention is not limited thereto. The thickness of the step layer STPL may be about 400 Å.

In an embodiment and in the first sub-pixel SP1, the third reflective electrode RL3 may be disposed on the second reflective electrode RL2 and the step layer STPL. In the second sub-pixel SP2 and the third sub-pixel SP3, the third reflective electrode RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, at least one of the first reflective electrode RL1, the second reflective electrode RL2, or the third reflective electrode RL3 may be omitted.

In an embodiment, the fourth reflective electrodes RL4 may be respectively disposed on the third reflective electrodes RL3. The fourth reflective electrodes RL4 may reflect light from first to third intermediate layers EML1, EML2, and EML3, respectively. The fourth reflective electrodes RL4 may include a metal having high reflectivity to advantageously reflect the light. The fourth reflective electrodes RL4 may be formed of aluminum (Al), a stacked structure (Ti/Al/Ti) of aluminum and titanium, a stacked structure (ITO/AI/ITO) of aluminum and ITO, an APC alloy, which is an alloy of silver (Ag), palladium (Pd), and copper (Cu), and a stacked structure (ITO/APC/ITO) of the APC alloy and ITO, but the invention is not limited thereto. Each of the fourth reflective electrodes RL4 may have a thickness of about 850 Å.

In an embodiment, a tenth interlayer insulating layer INS10 may be disposed on the ninth interlayer insulating layer INS9 and the fourth reflective electrodes RL4. The tenth insulating layer INS10 may be formed of a silicon oxide (SiOx)-based inorganic layer, but the invention is not limited thereto.

In an embodiment, each of the tenth vias VI10 may penetrate the tenth interlayer insulating layer INS10 and be connected to an exposed ninth metal layer ML9. The tenth vias VI10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. Due to the presence of the step layer STPL, the thickness of the tenth via VI10 in the first sub-pixel SP1 may be less than the thickness of the tenth via VI10 in each of the second sub-pixel SP2 and the third sub-pixel SP3. For example, the thickness of the tenth via VI10 in the first sub-pixel SP1 may be about 800 Å, and the thickness of the tenth via VI10 in each of the second sub-pixel SP2 and the third sub-pixel SP3 may be about 1200 Å.

In an embodiment, the light emitting element layer EMTL may be disposed on the light emitting element backplane EBP. The light emitting element layer EMTL may include the light emitting elements LE each having a first electrode AND, an intermediate layer IL, and a second electrode CAT, a pixel defining layer PDL, and a plurality of trenches TRC.

In an embodiment, the first electrode AND of each of the light emitting elements LE may be disposed on the tenth interlayer insulating layer INS10 and connected to the tenth via VI10. The first electrode AND of each of the light emitting elements LE may be connected to the drain region DA or source region SA of the pixel transistor TRS through the tenth via VI10, the first to fourth reflective electrodes RL1 to RL4, respectively, the first to ninth vias VI1 to VI9, respectively, the first to eighth metal layers ML1 to ML8, respectively, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

In an embodiment, the pixel defining layer PDL may be disposed on a part of the first electrode AND of each of the light emitting elements LE. The pixel defining layer PDL may cover the edge of the first electrode AND of each of the light emitting elements LE. The pixel defining layer PDL may serve to partition the first emission areas EA1, the second emission areas EA2, and the third emission areas EA3.

In an embodiment, the first emission area EA1 may be defined as an area in which the first electrode AND, the intermediate layer IL, and the second electrode CAT are sequentially stacked in the first sub-pixel SP1 to emit light. The second emission area EA2 may be defined as an area in which the first electrode AND, the intermediate layer IL, and the second electrode CAT are sequentially stacked in the second sub-pixel SP2 to emit light. The third emission area EA3 may be defined as an area in which the first electrode AND, the intermediate layer IL, and the second electrode CAT are sequentially stacked in the third sub-pixel SP3 to emit light.

In an embodiment, the pixel defining layer PDL may include first to third pixel defining layers PDL1, PDL2, and PDL3. The first pixel defining layer PDL1 may be disposed on the edge of the first electrode AND of each of the light emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOₓ)-based inorganic layer, but the invention is not limited thereto. The first pixel defining layer PDL1, the second pixel defining layer PDL2, and the third pixel defining layer PDL3 may each have a thickness of about 500 Å.

In an embodiment, each of the plurality of trenches TRC may penetrate the first pixel defining layer PDL1, the second pixel defining layer PDL2, and the third pixel defining layer PDL3. The tenth interlayer insulating layer INS10 may be partially recessed at each of the plurality of trenches TRC.

In an embodiment, at least one trench TRC may be disposed between adjacent sub-pixels SP1, SP2, and SP3. Although FIG. 33 illustrates that two trenches TRC are disposed between adjacent sub-pixels SP1, SP2, and SP3, the invention is not limited thereto.

In an embodiment, the intermediate layer IL may include a first intermediate layer IL1, a second intermediate layer IL2, and a third intermediate layer IL3.

In an embodiment, the intermediate layer IL may have a tandem structure including the plurality of intermediate layers IL1, IL2, and IL3 that emit different lights. For example, the intermediate layer IL may include the first intermediate layer IL1 that emits light of the first color, the second intermediate layer IL2 that emits light of the third color, and the third intermediate layer IL2 that emits light of the second color. The first intermediate layer IL1, the second intermediate layer IL2, and the third intermediate layer IL3 may be sequentially stacked.

In an embodiment, the first intermediate layer IL1 may have a structure in which a first hole transport layer, a first organic light emitting layer that emits light of the first color, and a first electron transport layer are sequentially stacked. The second intermediate layer IL2 may have a structure in which a second hole transport layer, a second organic light emitting layer that emits light of the third color, and a second electron transport layer are sequentially stacked. The third intermediate layer IL3 may have a structure in which a third hole transport layer, a third organic light emitting layer that emits light of the second color, and a third electron transport layer are sequentially stacked.

In an embodiment, a first charge generation layer for supplying charges to the second intermediate layer IL2 and supplying electrons to the first intermediate layer IL1 may be disposed between the first intermediate layer IL1 and the second intermediate layer IL2. A second charge generation layer for supplying charges to the third intermediate layer IL3 and supplying electrons to the second intermediate layer IL2 may be disposed between the second intermediate layer IL2 and the third intermediate layer IL3.

In an embodiment, the first intermediate layer IL1 may be disposed on the first electrodes AND and the pixel defining layer PDL, and may be disposed on the bottom surface of each trench TRC. Due to the trench TRC, the first intermediate layer IL1 may be separated between adjacent sub-pixels SP1, SP2, and SP3. The second intermediate layer IL2 may be disposed on the first intermediate layer IL1. Due to the trench TRC, the second intermediate layer IL2 may be separated between adjacent sub-pixels SP1, SP2, and SP3. The third intermediate layer IL3 may be disposed on the second intermediate layer IL2. Due to the trench TRC, the third intermediate layer IL3 may be separated between adjacent sub-pixels SP1, SP2, and SP3. That is, each of the plurality of trenches TRC may be a structure for separating the first to third intermediate layers IL1, IL2, and IL3, respectively, of the light emitting element layer EMTL between adjacent sub-pixels SP1, SP2, and SP3.

In an embodiment, in order to stably separate the first to third intermediate layers IL1, IL2, and IL3, respectively, of the light emitting element layer EMTL between adjacent sub-pixels SP1, SP2, and SP3, the height of each of the plurality of trenches TRC may be greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3.

In an embodiment, in order to cut off the first to third intermediate layers IL1, IL2, and IL3, respectively, of the light emitting element layer EMTL between the neighboring sub-pixels SP1, SP2, and SP3, another structure may exist instead of the trench TRC. For example, instead of the trench TRC, a reverse tapered partition wall may be disposed on the pixel defining layer PDL.

In an embodiment, the number of the intermediate layers IL1, IL2, and IL3 that emit different lights is not limited to that shown in FIG. 33. For example, the intermediate layer IL may include two intermediate layers. In this case, one of the two intermediate layers may be substantially the same as the first intermediate layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In addition, in an embodiment, FIG. 33 illustrates that the first to third intermediate layers IL1, IL2, and IL3, respectively, are all disposed in the first emission area EA1, the second emission area EA2, and the third emission area EA3, but the invention is not limited thereto. For example, the first intermediate layer IL1 may be disposed in the first emission area EA1 and may not be disposed in the second emission area EA2 and the third emission area EA3. Furthermore, the second intermediate layer IL2 may be disposed in the second emission area EA2 and may not be disposed in the first emission area EA1 and the third emission area EA3. Further, the third intermediate layer IL3 may be disposed in the third emission area EA3 and may not be disposed in the first emission area EA1 and the second emission area EA2. In this case, first to third color filters CF1, CF2, and CF3, respectively, of the optical layer OPL may be omitted.

In an embodiment, the second electrode CAT may be disposed on the third intermediate layer IL3. The second electrode CAT may be disposed on the third intermediate layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3, respectively, due to a micro-cavity effect.

In an embodiment, the encapsulation layer ENC may be disposed on the light emitting element layer EMTL. The encapsulation layer ENC may include at least one inorganic layer TFE1 and TFE2 to prevent oxygen or moisture from permeating into the light emitting element layer EMTL. In addition, the encapsulation layer ENC may include at least one organic layer to protect the light emitting element layer EMTL from foreign substances such as dust. For example, the encapsulation layer ENC may include a first encapsulation inorganic layer TFE1, an encapsulation organic layer TFE2, and a second encapsulation inorganic layer TFE3.

In an embodiment, the first encapsulation inorganic layer TFE1 may be disposed on the second electrode CAT, the encapsulation organic layer TFE2 may be disposed on the first encapsulation inorganic layer TFE1, and the second encapsulation inorganic layer TFE3 may be disposed on the encapsulation organic layer TFE2. The first encapsulation inorganic layer TFE1 and the second encapsulation inorganic layer TFE3 may be formed of multiple layers in which one or more inorganic layers of silicon nitride (SiNₓ), silicon oxynitride (SiON), silicon oxide (SiOₓ), titanium oxide (TiOₓ), and aluminum oxide (AlOₓ) layers are alternately stacked. The encapsulation organic layer TFE2 may be a monomer. In another embodiment, the encapsulation organic layer TFE2 may be an organic layer such as acryl resin, epoxy resin, phenolic resin, polyamide resin, polyimide resin or the like.

In an embodiment, an adhesive layer ADL may be a layer for bonding the encapsulation layer ENC to the optical layer OPL. The adhesive layer ADL may be a double-sided adhesive member. In addition, the adhesive layer ADL may be a transparent adhesive member such as a transparent adhesive or a transparent adhesive resin.

In an embodiment, the optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3, respectively. The first to third color filters CF1, CF2, and CF3, respectively, may be disposed on the adhesive layer ADL.

In an embodiment, the first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

In an embodiment, the second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

In an embodiment, the third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

In an embodiment, the plurality of lenses LNS may be disposed on the first color filter CF1, the second color filter CF2, and the third color filter CF3. Each of the plurality of lenses LNS may be a structure for increasing a ratio of light directed to the front of the display device 10A. Each of the plurality of lenses LNS may have a cross-sectional shape that is convex in an upward direction.

In an embodiment, the filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic layer such as acrylic resin, epoxy resin, phenolic resin, polyamide resin, or polyimide resin.

In an embodiment, the cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

In an embodiment, the polarizing plate may be disposed on one surface of the cover layer CVL. The polarizing plate may be a structure for preventing visibility degradation caused by reflection of external light. The polarizing plate may include a linear polarizing plate and a phase retardation film. For example, the phase retardation film may be a λ/4 plate (quarter-wave plate), but the invention is not limited thereto. However, when visibility degradation caused by reflection of external light is sufficiently overcome by the first to third color filters CF1, CF2, and CF3, respectively, the polarizing plate may be omitted.

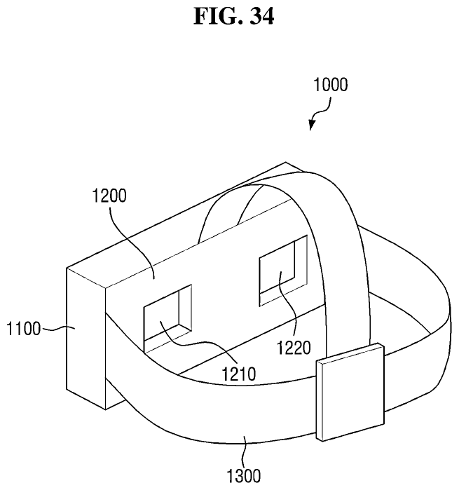

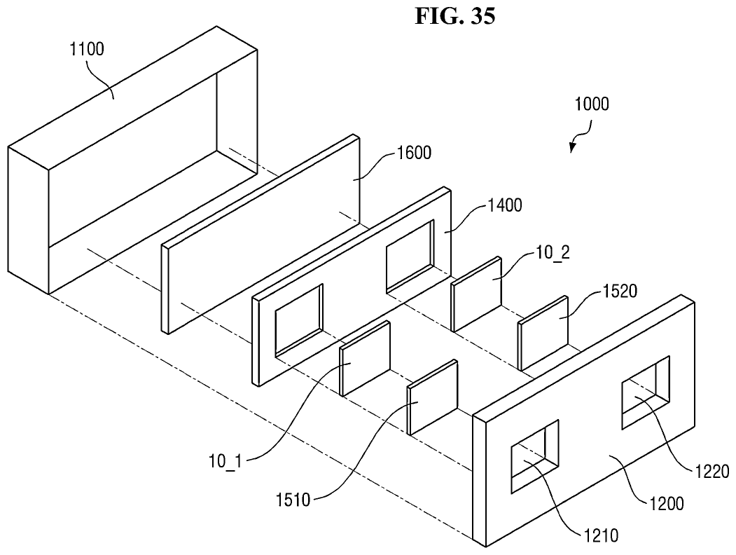

FIG. 34 is a perspective view illustrating a head mounted display device, according to an embodiment. FIG. 35 is an exploded perspective view illustrating an example of the head mounted display device of FIG. 34, according to an embodiment.

In an embodiment and referring to FIGS. 34 and 35, a head mounted display device 1000 includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, a control circuit board 1600, and a connector 1610.

In an embodiment, the first display device 10_1 provides an image to the user's left eye, and the second display device 10_2 provides an image to the user's right eye. Since each of the first display device 10_1 and the second display device 10_2 is substantially the same as the display device 10A described in conjunction with FIGS. 28 to 33, the description of the first display device 10_1 and the second display device 10_2 will be omitted.

In an embodiment, the first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

In an embodiment, the middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

In an embodiment, the control circuit board 1600 may be disposed between the middle frame 1400 and the display device housing 1100. The control circuit board 1600 may be connected to the first display device 10_1 and the second display device 10_2 through the connector 1610. The control circuit board 1600 may convert an image source inputted from the outside into digital video data DATA, and transmit the digital video data DATA to the first display device 10_1 and the second display device 10_2 through the connector 1610.

In an embodiment, the control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In another embodiment, the control circuit board 1600 may transmit the same digital video data DATA to the first display device 10_1 and the second display device 10_2.

In an embodiment, the display device housing 1100 serves to accommodate the first display device 10_1, the second display device 10_2, the middle frame 1400, the first optical member 1510, the second optical member 1520, the control circuit board 1600, and the connector 1610. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 34 and 35 illustrate that the first eyepiece 1210 and the second eyepiece 1220 are disposed separately, but the invention is not limited thereto. The first eyepiece 1210 and the second eyepiece 1220 may be combined into one.

In an embodiment, the first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

In an embodiment, the head mounted band 1300 serves to secure the display device housing 1100 to the user's head such that the first eyepiece 1210 and the second eyepiece 1220 of the housing cover 1200 remain aligned with and disposed proximate the user's left and right eyes, respectively. When the display device housing 1200 is implemented to be lightweight and compact, the head mounted display device 1000 may be provided with, as shown in FIG. 9, an eyeglass frame instead of a head mounted band 800.

In an embodiment, in addition, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

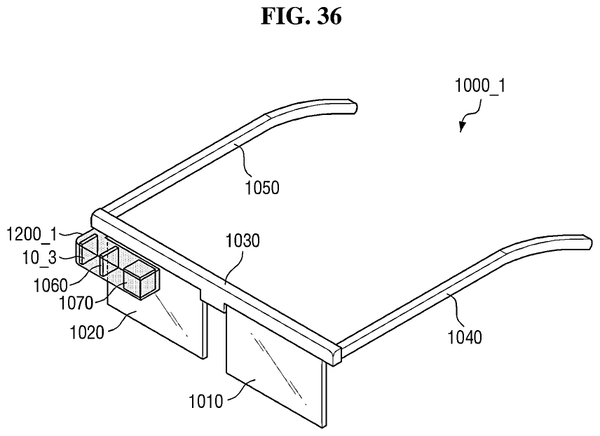

FIG. 36 is a perspective view illustrating a head mounted display device, according to an embodiment.

In an embodiment and referring to FIG. 36, a head mounted display device 1000_1 may be an eyeglasses-type display device in which a display device housing 1200_1 is implemented in a lightweight and compact manner. The head mounted display device 1000_1 according to an embodiment may include a display device 10_3, a left eye lens 1010, a right eye lens 1020, a support frame 1030, temples 1040 and 1050, an optical member 1060, an optical path conversion member 1070, and the display device housing 1200_1.

In an embodiment, the display device housing 1200_1 may include the display device 10_3, the optical member 1060, and the optical path conversion member 1070. The image displayed on the display device 10_3 may be magnified by the optical member 1060, and may be provided to the user's right eye through the right eye lens 1020 after the optical path thereof is converted by the optical path conversion member 1070. As a result, the user may view an augmented reality image, through the right eye, in which a virtual image displayed on the display device 10_3 and a real image seen through the right eye lens 1020 are combined.

In an embodiment, FIG. 36 illustrates that the display device housing 1200_1 is disposed at the end on the right side of the support frame 1030, but the invention is not limited thereto. For example, the display device housing 1200_1 may be disposed on the left end of the support frame 1030, and in this case, the image of the display device 10_3 may be provided to the user's left eye. In another embodiment, the display device housing 1200_1 may be disposed on both the left and right ends of the support frame 1030, and in this case, the user may view the image displayed on the display device 10_3 through both the left and right eyes.

It will be able to be understood by one of ordinary skill in the art to which the invention belongs that the invention may be implemented in other forms without changing the technical spirit or essential features of the invention. Therefore, it is to be understood that the embodiments described above are illustrative rather than being restrictive in all aspects.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims. Moreover, the embodiments or parts of the embodiments may be combined in whole or in part without departing from the scope of the invention.

What is claimed is:

1. A display device comprising:
a plurality of pixels arranged adjacently along a first direction;
a plurality of transistors disposed in each pixel; and
a light emitting element disposed in each pixel, and connected to at least one of the plurality of transistors in each pixel,
wherein gate electrodes of corresponding transistors of the plurality of transistors of different pixels of the plurality of pixels, which are connected to a same signal line, are disposed so as not to overlap in the first direction.

2. The display device of claim 1, wherein the plurality of transistors in each pixel comprise a first transistor connected to the light emitting element in each pixel, and
wherein a channel length of a channel region of the first transistor extends along a second direction intersecting the first direction.

3. The display device of claim 2, wherein the first transistor comprises a plurality of channel regions disposed along the first direction.

4. The display device of claim 2, wherein the plurality of transistors in each pixel comprise a second transistor connected between the first transistor and the light emitting element, and
wherein a channel length of a channel region of the second transistor extends along the first direction.

5. The display device of claim 4, wherein among the transistors of the plurality of transistors disposed in a same pixel, excluding the second transistor, the channel length of the channel region extends along the second direction.

6. The display device of claim 1, wherein gate electrodes of the plurality of transistors disposed in different adjacent pixels do not overlap in the first direction.

7. The display device of claim 1, wherein the signal line has a curved shape.

8. The display device of claim 7, wherein the signal line has a symmetrical shape with respect to a second direction which intersects the first direction.

9. The display device of claim 1, wherein the signal line comprises a gate line and an emission line.

10. The display device of claim 9, wherein the gate line comprises a plurality of sub-gate lines connected to each other.

11. The display device of claim 10, wherein at least two sub-gate lines of the plurality of sub-gate lines are disposed on different layers, and
wherein the two sub-gate lines are connected through contact holes of an insulating layer.

12. The display device of claim 11, wherein a sub-gate line disposed on an upper side extends in a second direction intersecting the first direction.

13. The display device of claim 12, wherein a sub-gate line disposed on a lower side extends in the first direction.

14. The display device of claim 13, wherein a sub-gate line disposed on the lower side extends further in the second direction than in the first direction.

15. The display device of claim 1, wherein each of the plurality of pixels further comprises a body electrode.

16. The display device of claim 1, wherein body electrodes of respective pixels are disposed in the respective pixels so as not to overlap in the first direction.

17. The display device of claim 1, wherein a body electrode is disposed in one of the plurality of pixels.

18. The display device of claim 17, wherein a part of the body electrode is disposed between gate electrodes of transistors disposed adjacent in the first direction in the one pixel.

19. The display device of claim 18, wherein one side surface of each of the gate electrodes facing the body electrode has a depressed shape directed toward an opposite side surface of each gate electrode.

20. The display device of claim 1, further comprising an intermediate connection electrode disposed in each pixel and connected to an anode electrode of the light emitting element of each pixel.

21. The display device of claim 20, wherein intermediate connection electrodes of respective pixels are disposed in the respective pixels so as not to overlap in the first direction.

22. The display device of claim 20, wherein the intermediate connection electrode of at least one pixel is disposed in a capacitor area of the pixel.
